(19) United States
(12) Patent Application Publication
(10) Pub. No.: US 2026/0212604 A1
(43) Pub. Date: Jul. 23, 2026

(54) UNIQUE MESH GENERATION FOR ENHANCING TERRAIN DETAIL IN SIMULATION SYSTEMS AND APPLICATIONS

(71) Applicant: NVIDIA Corporation, Santa Clara, CA (US)

(72) Inventor: Kim Goossens, Antwerp (BE)

(21) Appl. No.: 19/033,299

(22) Filed: Jan. 21, 2025

Related U.S. Application Data
(63) Continuation of application No. 19/033,247, filed on Jan. 21, 2025.

(51) Int. Cl. G06T 17/20; G06T 7/60; G06T 17/05

(52) U.S. Cl. CPC G06T 17/205; G06T 7/60; G06T 17/05; G06T 2200/04

(57) ABSTRACT

In various examples, unique meshes may be generated and used to replace various portions of instanced mesh tiles representative of three-dimensional (3D) terrain in a simulation environment. For instance, portions (e.g., polygons) of the instanced mesh tiles may be hidden during rendering based on the portions being located within a threshold proximity of features to be rendered in the simulation environment. The systems and methods of the present disclosure may determine a geometry of the hidden portions and generate unique meshes having the same or similar geometry for replacing the hidden portions and defining attributes or structure of the features. The systems may use the unique meshes along with the visible (e.g., non-hidden) portions of the mesh tiles to render the 3D terrain and ensure seamless transitions between the 3D terrain and the features, without having to create additional, mesh tile variants.

### CROSS-REFERENCE TO RELATED APPLICATIONS

This application is a continuation of U.S. patent application Ser. No. 19/033,247, filed Jan. 21, 2025, which is hereby incorporated by reference in its entirety.

### BACKGROUND

In many computer-generated graphical environments—such as virtual driving environments and/or open-world video games—three-dimensional (3D) terrain may be generated using a combination of height maps, procedural generation, and/or texture mapping to create detailed and expansive landscapes that can be dynamically adjusted and rendered in real-time. In some instances, to reduce draw calls, lower memory usage, and/or simplify asset management, mesh tiles and instancing may be used to efficiently manage and display expansive and detailed landscapes in 3D environments. These approaches typically involve dividing the 3D terrain into modular mesh tiles, which are reusable geometric units representing various terrain features, and then using instancing to render multiple copies of these mesh tiles with a single draw call-significantly reducing computational loads and enhancing performance.

While instancing may be effective for improving rendering performance, these techniques also limit the variety of terrain features that can be rendered in a 3D environment, thereby leading to repetitive terrain appearances. However, adding unique features to mesh tiles to create more robust 3D environments can be challenging. For instance, ensuring seamless transitions between instanced tiles and unique tiles can be difficult, and, if not carefully designed, visible seams or mismatches may occur between tiles. Additionally, adding unique features often requires creating additional tile variants, which can increase the complexity of the rendering system and may negatively affect performance. As such, if the aim is to boost rendering performance, then adding unique features to mesh tiles to create more detailed 3D environments may undermine the advantages of using mesh tiles and instancing.

### SUMMARY

Embodiments of the present disclosure relate to mesh modification for simulation environment systems and applications. Systems and methods are disclosed that may modify instanced mesh tiles representative of three-dimensional (3D) terrain in a simulation environment based on locations of features (e.g., unique or high-resolution features) to be rendered in the simulation environment as part of the 3D terrain. For instance, the systems and methods of the present disclosure may identify portions (e.g., one or more polygons, etc.) of the mesh tiles that are located within a threshold distance of the features and cause those portions to be hidden from the mesh tiles at least during a rendering of the 3D terrain. In some examples, a replacement mesh may be generated based on the hidden portions of the mesh tiles, and the replacement mesh may be used along with the visible portions of the mesh tiles to render the 3D terrain.

In contrast to conventional systems, the systems of the present disclosure, in some embodiments, ensure seamless transitions between an original 3D terrain—rendered using instanced mesh tiles—and unique features added to the 3D terrain, without having to create additional, mesh tile variants. For instance, instead of creating additional, unique mesh tiles for areas of the environment that include the added features, the systems of the present disclosure may alter parameters associated with the original mesh tiles to hide one or more portions of the mesh tiles that are located within a threshold proximity of the features. In this way, the hidden portions of the mesh tiles may be omitted during rendering of the 3D terrain, and the systems may continue to use the original mesh tiles. Additionally, the systems may generate a unique mesh to replace the hidden portions of the mesh tiles. In some instances, the unique mesh may have a higher level of detail or represent different types of 3D topology than the hidden portions of the original mesh tiles. For instance, the unique mesh may be generated to have edges (e.g., polygon edges) that correspond to edges of the added features, thereby ensuring seamless transitions between the original, 3D terrain and the added features. The systems may, in some examples, combine the unique mesh with the visible portions of the instanced mesh tiles, and render the 3D terrain using the combined meshes.

### BRIEF DESCRIPTION OF THE DRAWINGS

The present systems and methods for mesh modification for simulation environment systems and applications are described in detail below with reference to the attached drawing figures, wherein:

FIG. 1 is a data flow diagram illustrating an example of a process for modifying a terrain mesh based on feature locations, in accordance with some embodiments of the present disclosure;

FIG. 2 illustrates an example of a mesh data structure including a plurality of instanced mesh tiles having varying levels of detail, in accordance with some embodiments of the present disclosure;

FIGS. 3A-3E illustrate examples of various stages associated with modifying a terrain mesh, in accordance with some embodiments of the present disclosure;

FIGS. 4A and 4B collectively illustrate an example of using priorities associated with features to determine how features should be rendered in a virtual environment, in accordance with some embodiments of the present disclosure;

FIGS. 5, 6, and 7 are diagrams illustrating example terrain surface renderings using modified mesh tiles based on feature locations, in accordance with some embodiments of the present disclosure;

FIG. 8 illustrates an example of a system that may perform one or more of the processes described herein, in accordance with some embodiments of the present disclosure;

FIG. 9 is a flow diagram illustrating an example of a method for hiding portions of mesh tiles based on feature proximity, in accordance with some embodiments of the present disclosure;

FIG. 10 is a flow diagram illustrating an example of a method for updating mesh tiles to suppress portions of the mesh tiles determined to be within a threshold distance of features to be rendered in a simulation environment, in accordance with some embodiments of the present disclosure;

FIG. 11 is a flow diagram illustrating an example of a method for generating one or more replacement meshes based on geometries of omitted portions of mesh tiles, in accordance with some embodiments of the present disclosure;

FIG. 12 is a flow diagram illustrating an example of a method for rendering a texture elevation mesh using a combination of different mesh data structures, in accordance with some embodiments of the present disclosure;

FIGS. 13A-13F are example illustrations of a simulation system, in accordance with some embodiments of the present disclosure;

FIG. 14A is an example illustration of a simulation system at runtime, in accordance with some embodiments of the present disclosure;

FIG. 14B includes a cloud-based architecture for a simulation system, in accordance with some embodiments of the present disclosure;

FIG. 15A is an illustration of an example autonomous vehicle, in accordance with some embodiments of the present disclosure;

FIG. 15B is an example of camera locations and fields of view for the example autonomous vehicle of FIG. 15A, in accordance with some embodiments of the present disclosure;

FIG. 15C is a block diagram of an example system architecture for the example autonomous vehicle of FIG. 15A, in accordance with some embodiments of the present disclosure;

FIG. 15D is a system diagram for communication between cloud-based server(s) and the example autonomous vehicle of FIG. 15A, in accordance with some embodiments of the present disclosure;

FIG. 16 is a block diagram of an example computing device suitable for use in implementing at least some embodiments of the present disclosure; and

FIG. 17 is a block diagram of an example data center suitable for use in implementing at least some embodiments of the present disclosure.

### DETAILED DESCRIPTION

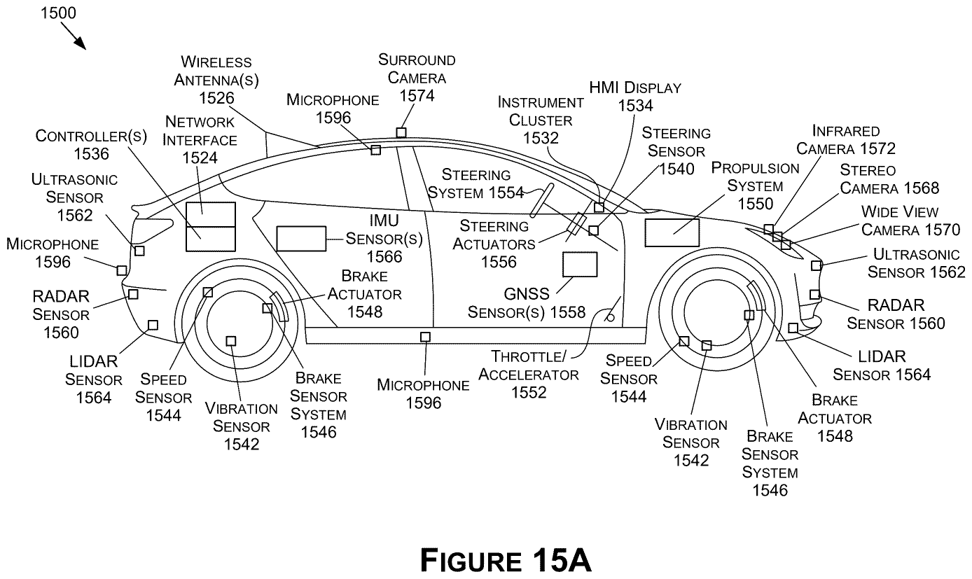

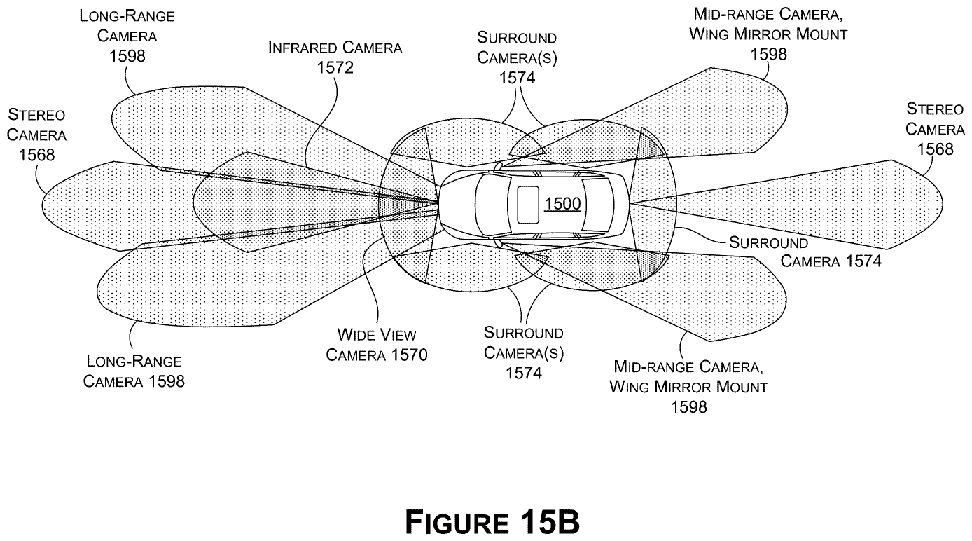

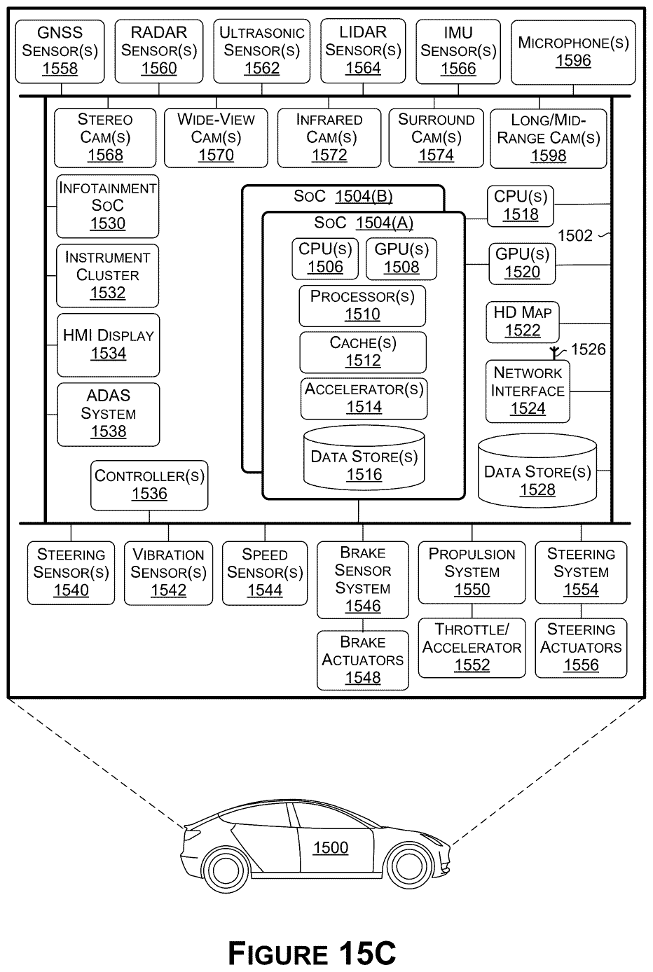

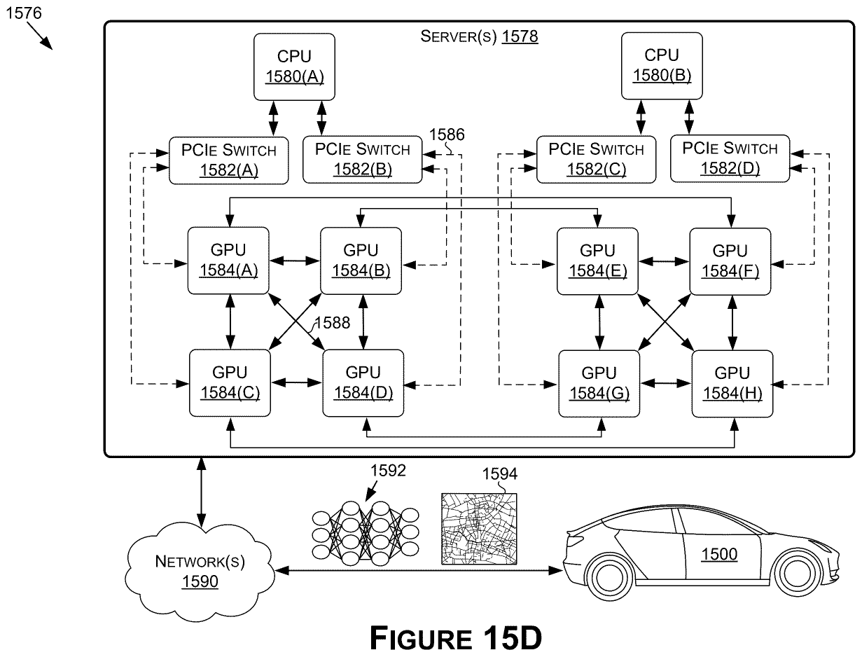

Systems and methods are disclosed related to mesh modification for simulation environment systems and applications. Although the present disclosure may be described with respect to example simulated environments for an autonomous or semi-autonomous vehicle or machine 1500 (alternatively referred to herein as “vehicle 1500” or “ego machine 1500,” an example of which is described with respect to FIGS. 15A-15D), this is not intended to be limiting. For example, the systems and methods described herein may be used by, without limitation, non-autonomous vehicles or machines, semi-autonomous vehicles or machines (e.g., in one or more advanced driver assistance systems (ADAS)), autonomous vehicles or machines, piloted and un-piloted robots or robotic platforms, warehouse vehicles, off-road vehicles, vehicles coupled to one or more trailers, flying vessels, boats, shuttles, emergency response vehicles, motorcycles, electric or motorized bicycles, aircraft, construction vehicles, trains, underwater craft, remotely operated vehicles such as drones, and/or other vehicle types. In addition, although the present disclosure may be described with respect to terrain building for simulated driving environments, this is not intended to be limiting, and the systems and methods described herein may be used in augmented reality, virtual reality, mixed reality, robotics, security and surveillance, autonomous or semi-autonomous machine applications, and/or any other technology spaces where computer-generated visualizations within simulated environments may be used.

For instance, a system(s) may obtain a mesh data structure that includes a plurality of instanced mesh tiles. In some examples, the mesh data structure and/or the plurality of mesh tiles may be representative of a terrain (or other) surface for rendering in a simulation environment or any other virtual environment. That is, the plurality of mesh tiles may include one or more vertices, edges, faces, polygons, surfaces, etc. defining 3D geometry of the (e.g., terrain) surface. Because the mesh tiles may be instanced, the mesh tiles may share a same base mesh or base geometry (e.g., same number of polygons, same dimensions, same attributes, etc.). For instance, multiple tiles in the terrain may be based on the same base mesh but may be adjusted or customized for their specific locations. For example, tiles may use the same base mesh for a flat grassland but may have different heights or textures applied between tiles to show changes in elevations throughout a scene. In some examples, one or more (e.g., each) mesh tile of the plurality of mesh tiles may correspond to a specific portion/region of the terrain surface and/or the virtual environment. For instance, a first tile of the mesh tiles may correspond to a first portion of the terrain surface and/or first region of the virtual environment, a second tile of the mesh tiles may correspond to a second portion of the terrain surface and/or second region of the virtual environment, and so forth. While the examples provided focus on terrain surfaces, disclosed approaches apply more generally to any types of surfaces, examples of which include terrain surfaces.

In some examples, the level of detail or resolution of the mesh tiles may vary from one tile to another tile of the mesh data structure. For example, the mesh data structure may include or correspond to a quadtree structure that instantiates quadtree mesh tiles at levels of the quadtree structure determined based on a function of distance from pathway structures corresponding to one or more navigable pathways (e.g., a pathway edge). At distances closest to the pathway structures, the quadtree structure may comprise root-level quadtree mesh tiles. For distances on the terrain surface that are farther than a first distance from the pathway structures, a second level of the quadtree structure may be instanced, comprising larger quadtree mesh tiles. The quadtree mesh tiles at the second level of the quadtree structure may have dimensions that are proportionately scaled, e.g., double (or some other coefficient) the size of those of the root-level quadtree mesh tiles. For distances on the terrain surface that are farther than a second distance from the pathway structure, a third level of the quadtree structure may be instanced, comprising still larger quadtree mesh tiles, which have dimensions that are proportionately scaled to (e.g., double) those of the second-level quadtree mesh tiles. Successive levels of the quadtree structure after the second level may be similarly instanced, each following a quadtree pattern of having tiles of similar relative scaling (e.g., doubled) dimensions. Additional details regarding using quadtree mesh tiles to represent a terrain surface can be found in U.S. patent application Ser. No. 18/769,738, filed on Jul. 11, 2024, the entire contents of which is hereby incorporated by reference herein in its entirety and for all purposes.

Additionally, the system(s) may, in some examples, obtain or determine locations corresponding to features that are to be rendered in the simulation environment. The features may include one or more unique features or objects (e.g., pathways, sidewalks, driving surfaces, etc.) to be added to, or “cut out” of, the terrain surface. For example, in the context of generating a simulation environment for testing autonomous vehicles, the features may include driving surfaces, sidewalks, curbs, or any other pathway-related features. In some instances, the features may be represented using two-dimensional (2D) lines and/or shapes, and the 2D lines/shapes may be positioned on the mesh data structure/mesh tiles at locations where the features are to be rendered within the 3D simulation environment. For example, a sidewalk may be represented using a number of 2D lines to define a shape of the sidewalk, edges where the sidewalk abuts base terrain surfaces (e.g., of the mesh tiles), edges where the sidewalk abouts a road surface, locations of the sidewalk with respect to the simulation environment, etc.

In some examples, the system(s) may determine portions (e.g., polygons) of the mesh tiles that are located within a threshold proximity of the features. For example, the 2D lines defining the features may be overlaid on the terrain mesh tiles, and the system(s) may identify the portions of the mesh tiles that are located within a threshold proximity of the 2D lines. As a first example, the system(s) may identify polygons of the mesh tiles that the 2D lines pass through or intersect with. As a second example, the system(s) may identify polygons of the mesh tiles whose center points or edges are less than a threshold distance (e.g., 2D Euclidian distance, 3D Euclidian distance, etc.) from the 2D lines.

In some examples, the threshold distance may vary based on the level of detail associated with a given mesh tile. For instance, and for a first mesh tile having a relatively higher level of detail or resolution (e.g., small polygons), the threshold distance may be smaller or shorter than for a second mesh tile having a relatively lower level of detail or resolution (e.g., large polygons). In other words, the system(s) may determine whether one or more first portions of one or more first mesh tiles associated with a first level of detail are located within a first threshold distance of the one or more features, determine whether one or more second portions of one or more second mesh tiles associated with second level of detail are located within a second threshold distance of the one or more features, and so forth. In such an example, a difference between the first threshold distance and the second threshold distance (and/or any other successive thresholds) may be based at least on differences in levels of detail between the one or more first mesh tiles and the one or more second mesh tiles. In at least one example, if a first mesh tile has a first level of detail/resolution that is two times greater than a second mesh tile that has a second level of detail/resolution (e.g., individual polygons of the second mesh tile may be twice the size of the first mesh tile), then the threshold distance may be two times longer between the features and the portions of the second mesh tile than the first mesh tile.

In some examples, the system(s) may update one or more of the mesh tiles to hide or suppress the portions that are located within the threshold distance of the features to prevent the portions from being rendered. For instance, the system(s) may update one or more attributes or parameters associated with the mesh tiles to hide the portions. In some examples, to hide the portions of the mesh tiles, the system(s) may apply a shader(s) to the portions of the mesh tiles. For instance, the shader(s) may be used to exclude or modify the portions dynamically, ensuring efficient control over visibility without altering the underlying mesh geometry. By hiding the portions of the mesh tiles, the system(s) may cause the terrain surface to be rendered in the virtual environment without rendering the portions of the mesh tiles that are located within the threshold distance of the features. In other words, when the terrain surface is rendered, the terrain surface is rendered using the visible or non-hidden portions of the mesh tiles that are distinguishable from the hidden portions. For instance, by using the shader(s) to hide portions (e.g., polygons) of the mesh tiles, the system(s) may have the ability to, among other things, form tunnels and/or other features in the terrain mesh and/or seamlessly connect other meshes to the terrain that may go underneath the terrain. In such instances, the terrain may be continuous, and the shader(s) may create a hole (and/or other feature) by hiding some of the polygons/portions without having to alter the topology associated with the instanced mesh tile(s).

In some examples, the system(s) may generate one or more replacement meshes for replacing the hidden portions of the mesh tiles. For instance, the system(s) may generate the replacement meshes, and the terrain surface and/or features may be rendered in the simulation environment using the replacement meshes in place of the hidden portions of the mesh tiles. In some examples, to generate the replacement meshes, the system(s) may determine geometries associated with the hidden portions of the instanced mesh tiles, and use the geometries to generate the replacement meshes such that the replacement meshes have the same or similar geometries. For instance, the system(s) may determine a bounding shape of the hidden portions (e.g., an overall shape of the hidden polygons) of the mesh tiles so that the replacement meshes may be generated to have the same or similar shape in order to be combined or integrated with the non-hidden portions of the mesh tiles.

In some examples, the replacement meshes may be generated to include vertices, edges, polygons, faces, etc. that correspond to the features. That is, while the overall bounding shape of the replacement meshes may correspond to the hidden portions of the mesh tiles, the individual polygon shapes within the replacement meshes may define the 3D structure of the features being added to, cut out of, or rendered on top of the terrain surface base. As such, the replacement meshes may, in some instances, be associated with a relatively higher level of detail than the mesh tiles and/or their hidden portions. For instance, the mesh tiles, because of their uniform base meshes, may not include enough detail (e.g., polygons, etc.) to be capable of accurately defining edges of the features with high visual quality. In other words, to realistically define the 3D structure of the unique features in the virtual environment, the system(s) may generate the replacement meshes to replace the hidden portions of the mesh tiles that the features are located next to, and the replacement meshes may include a greater number of, or more strategically placed, vertices, edges, polygons, etc. than the mesh tiles for the base terrain layer.

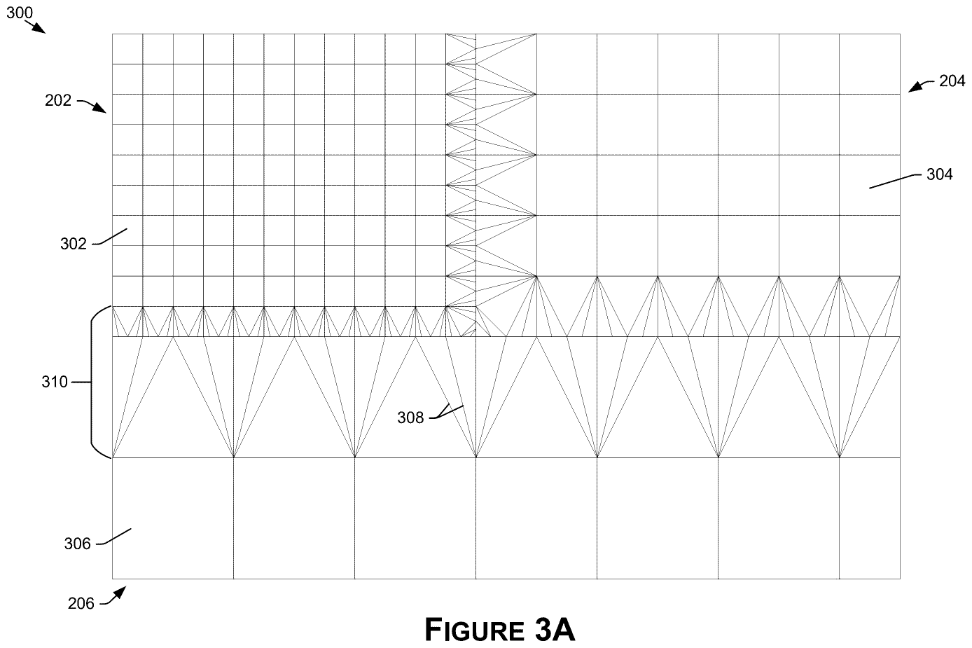

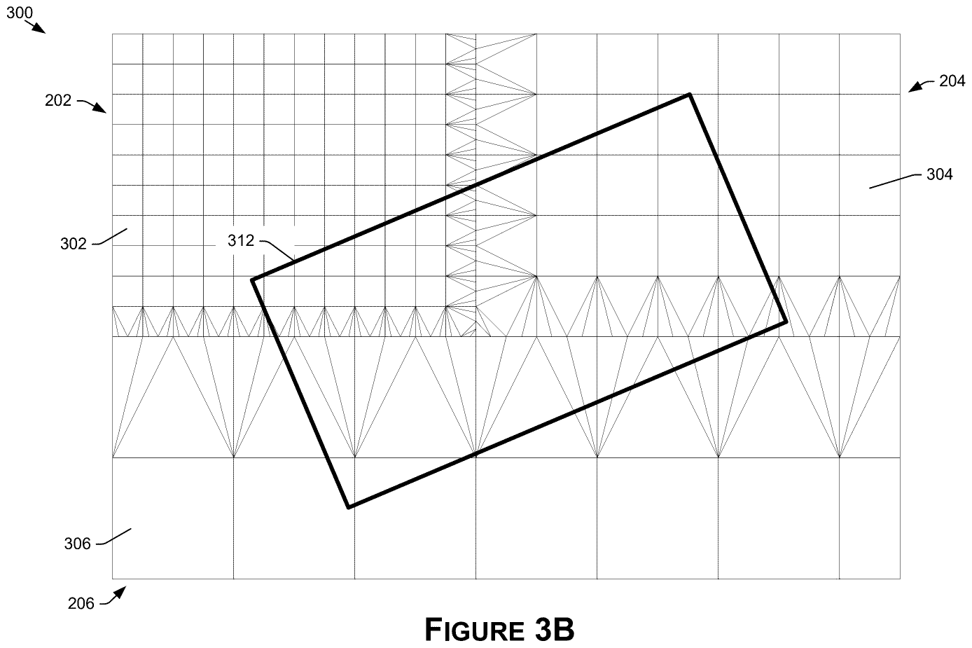

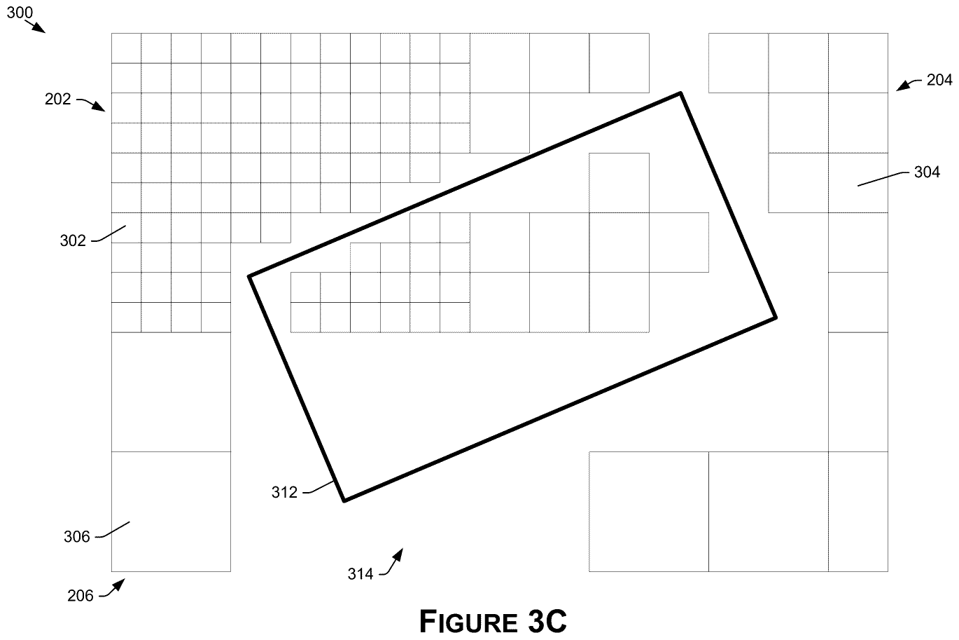

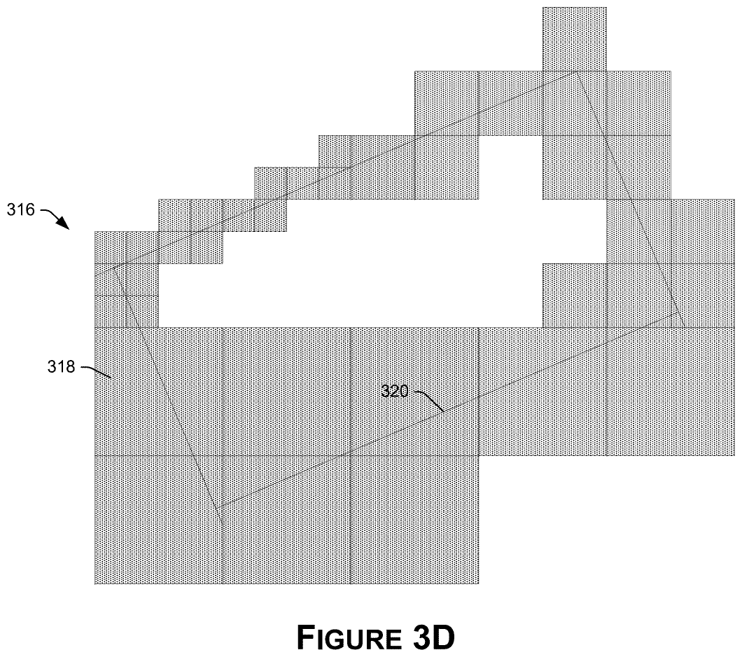

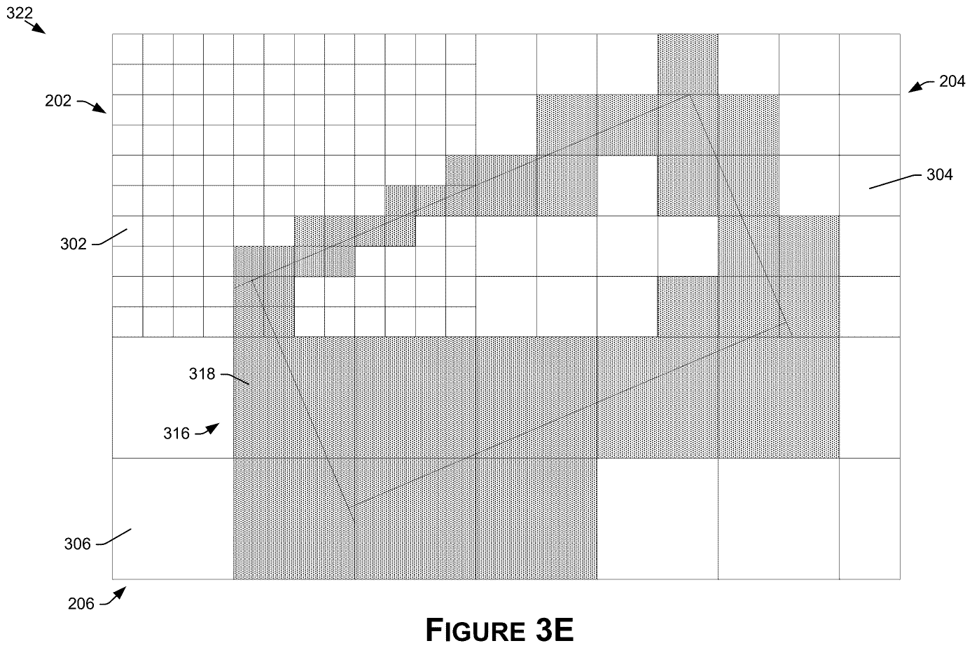

In some examples, the system(s) may combine the visible or non-hidden portions of the mesh tiles with the replacement meshes. For instance, the system(s) may merge the visible portions of the mesh tiles with the replacement meshes based at least on the geometries of the replacement meshes being the same as or similar to the geometries of the hidden portions of the mesh tiles. In some instances, the system(s) may modify the visible portions of the mesh tiles and/or the replacement meshes to include skirting to ensure seamless transitions between the mesh tile portions and the replacement mesh portions. Skirting may include, in some examples, adding one or more additional edges between one or more vertices of the mesh tiles and/or replacement meshes. Additional detail about skirting is described and shown in further detail herein with respect to FIG. 3A.

As described herein, the system(s) may, in some examples, render a texture elevation mesh of the terrain surface in the simulation environment using the combination of mesh data structures. For instance, the system(s) may render one or more first portions of the terrain surface using the visible, non-hidden portions of the mesh tiles, and render one or more second portions of the terrain surface using the replacement meshes. In some examples, the first portion(s) of the terrain surface may include a base layer of the terrain surface, and the second portion(s) of the terrain surface may include one or more additional layers on top of, or cut out of, the base layer. For instance, the second portion(s) may include one or more hardtop surfaces rendered in the virtual environment, such as sidewalks, pavement, driving surfaces, or any other pathways. Additionally, or alternatively, the second portion(s) may include any features or object to be rendered in the virtual environment where a greater level of detail than the mesh tiles may be necessary.

In some examples, to render the texture elevation mesh, the system(s) may apply one or more texture images to one or more texture nodes of the visible portions of the mesh tiles and/or the replacement meshes. For instance, the texture of the terrain surfaces or any other 3D terrain in the simulation environment may be rendered by applying texture images from one or more layers of a mipmap to the texture nodes. In some examples, different tiles of the mesh tiles may have different levels of detail/resolutions, as described herein, and may be mapped to different levels of the mipmaps. For example, a root-level quadtree mesh tile may include a single texture node mapped to a first level of the mipmap, a second-level quadtree mesh tile may include four texture nodes mapped to a simplified texture image from a second level of the mipmap, a third-level quadtree mesh tile may include sixteen nodes mapped to a simplified texture image from a third level of the mipmap, and so forth for each subsequent level of the mesh data structure.

In some embodiments, operating ego agents within a simulation environment may be used to generate synthetic sensor data used for training and/or testing machine learning models and/or other components of ego machines such as autonomous and semi-autonomous vehicles. For example, in some embodiments, renderings of drivable pathway surfaces across a terrain may be rendered in a computer vision simulation environment and used to generate synthetic sensor data. A simulation platform may process the computer vision simulation environment to generate synthetic image data for one or more cameras or other virtualized image sensors of an ego vehicle that is using the computer vision simulation environment as a simulated driving environment for training and/or testing components of the ego vehicle. Image data corresponding to one or more virtualized image sensors may include renderings generated as described herein. Distinct channels of such virtualized image sensor data may be generated to correspond to different sensors having different views of an environment around an ego vehicle and used as input into a computer simulation of an ego vehicle, or substituted for actual data channels as input to test a physical ego vehicle. In some embodiments, a simulated or actual ego vehicle may produce a computer vision representation of an environment around the ego vehicle that includes drivable pathway surfaces and surrounding non-drivable surfaces.

One or more aspects of the simulation platform may be executed at least in part on one or more graphics processing units that may operate in conjunction with software executed on a central processing unit coupled to a memory. In some embodiments, the various functions performed to render surface textures may at least be executed using functions from a computer graphics 3D animation software library. The graphics processing units may be programmed to execute kernels to implement one or more of the features and functions of the simulation platform described herein. In some embodiments, aspects of the simulation platform may be executed in parallel on different GPUs. In some embodiments, some features and functions of the simulation platform may be distributed and performed by a combination of processors and cloud computing resources. For example, in some embodiments, one or more simulation platform functions to render surface textures may be implemented at least in part as a virtual function on a cloud computing environment and/or implemented as a component of a virtualized machine learning model.

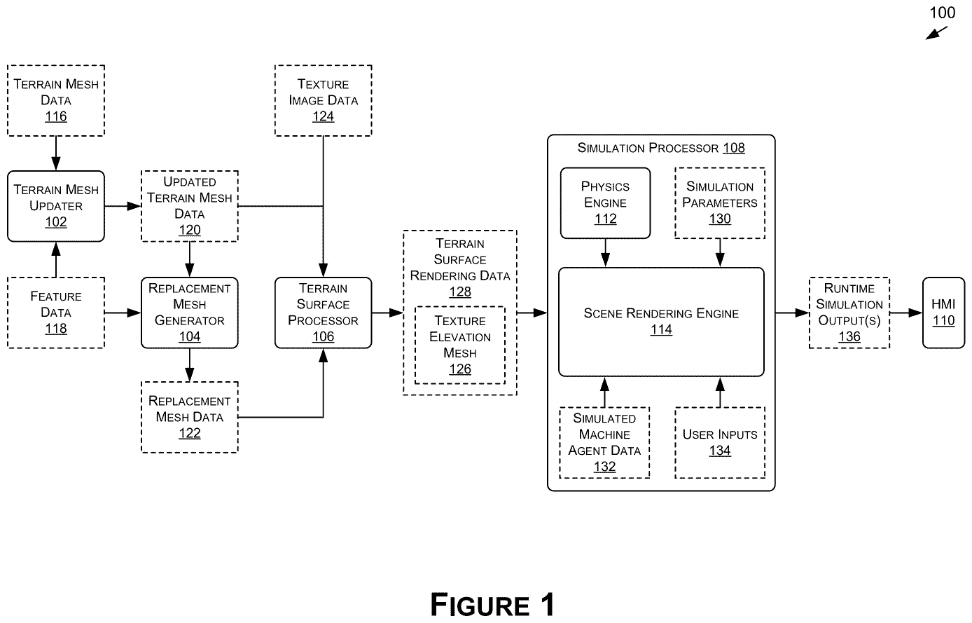

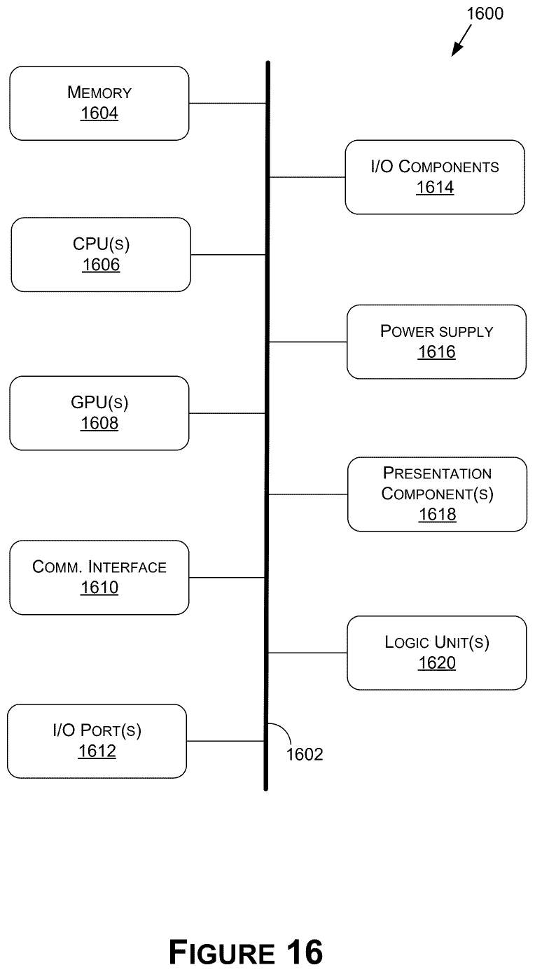

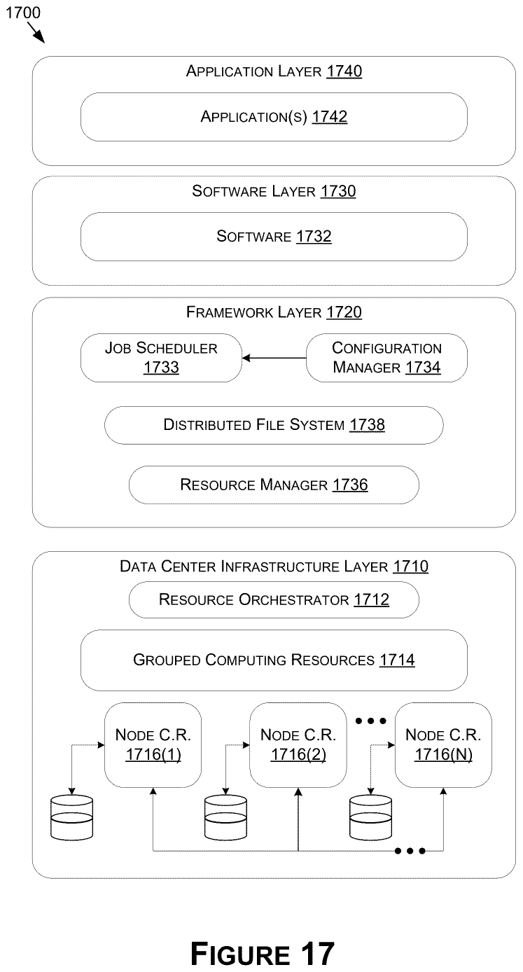

With reference to FIG. 1, FIG. 1 is a data flow diagram illustrating an example of a process 100 for modifying a terrain mesh based on feature locations, in accordance with some embodiments of the present disclosure. It should be understood that this and other arrangements described herein are set forth only as examples. Other arrangements and elements (e.g., machines, interfaces, functions, orders, groupings of functions, etc.) may be used in addition to or instead of those shown, and some elements may be omitted altogether. Further, many of the elements described herein are functional entities that may be implemented as discrete or distributed components or in conjunction with other components, and in any suitable combination and location. Various functions described herein as being performed by entities may be carried out by hardware, firmware, and/or software. For instance, various functions may be carried out using one or more processor executing instructions stored in one or more memories. For example, in some embodiments, the system and methods described herein may be implemented using one or more generative language models (e.g., as described in FIGS. 15A-15C), one or more computing devices or components thereof (e.g., as described in FIG. 16), and/or one or more data centers or components thereof (e.g., as described in FIG. 17).

The process 100 may be implemented using, amongst additional or alternative components, a terrain mesh updater 102, a replacement mesh generator 104, a terrain surface processor 106, a simulation processor 108, and a human-machine interface (HMI) 110. The simulation processor 108 may include a physics engine 112 and a scene rendering engine 114. As a brief overview, the terrain mesh updater 102 may obtain and use terrain mesh data 116 and feature data 118 to generate updated terrain mesh data 120. The replacement mesh generator 104 may obtain and use the feature data 118 and the updated terrain mesh data 120 to generate replacement mesh data 122. The terrain surface processor 106 may obtain and use the updated terrain mesh data 120, the replacement mesh data 122, and/or texture image data 124 to generate a texture elevation mesh 126 which may be included in terrain surface rendering data 128 for rendering a terrain surface in a simulation environment. The physics engine 112 and/or the scene rendering engine 114 may use the terrain surface rendering data 128, as well as simulation parameters 130, simulated machine agent data 132, and/or user inputs 134 to generate one or more runtime simulation outputs 136 which may be sent to the HMI 110.

In some examples, the terrain mesh data 116 received by the terrain mesh updater 102 may include a mesh data structure that is representative of a terrain surface for rendering in a simulation environment or any other virtual environment. That is, the terrain mesh data 116 may include one or more vertices, edges, faces, polygons, surfaces, etc. defining 3D geometry of the terrain surface. In some instances, terrain mesh data 116 may include a plurality of instanced mesh tiles that may share a common base mesh and may be adjusted or customized for their specific locations. For example, the mesh tiles may use the same base mesh for a flat prairie or grassland, but may have different heights or textures applied between tiles to show changes in elevations throughout a scene. In some examples, at least one (e.g., each) mesh tile of the plurality of mesh tiles may correspond to a specific portion/region of the terrain surface and/or the virtual environment. For instance, a first tile of the mesh tiles may correspond to a first portion of the terrain surface and/or first region of the virtual environment, a second tile of the mesh tiles may correspond to a second portion of the terrain surface and/or second region of the virtual environment, and so forth.

In some examples, the level of detail or resolution of the mesh tiles may vary from one tile to another tile of the terrain mesh data 116. For example, the terrain mesh data 116 may include or correspond to a quadtree structure that instantiates quadtree mesh tiles at levels of the quadtree structure determined based on a function of distance from pathway structures corresponding to one or more navigable pathways (e.g., a pathway edge). At distances closest to the pathway structures, the quadtree structure may comprise root-level quadtree mesh tiles. For distances on the terrain surface that are farther than a first distance from the pathway structures, a second level of the quadtree structure may be instanced, comprising larger quadtree mesh tiles. The quadtree mesh tiles at the second level of the quadtree structure may have dimensions that are proportionately scaled (e.g., double) those of the root-level quadtree mesh tiles. For distances on the terrain surface that are farther than a second distance from the pathway structure, a third level of the quadtree structure may be instanced, comprising still larger quadtree mesh tiles, which have dimensions that are also proportionately scaled (e.g., double) those of the second-level quadtree mesh tiles. Successive levels of the quadtree structure after the second level may be similarly instanced, with a level following a quadtree pattern of having tiles of proportionately scaled (e.g., doubled) dimensions.

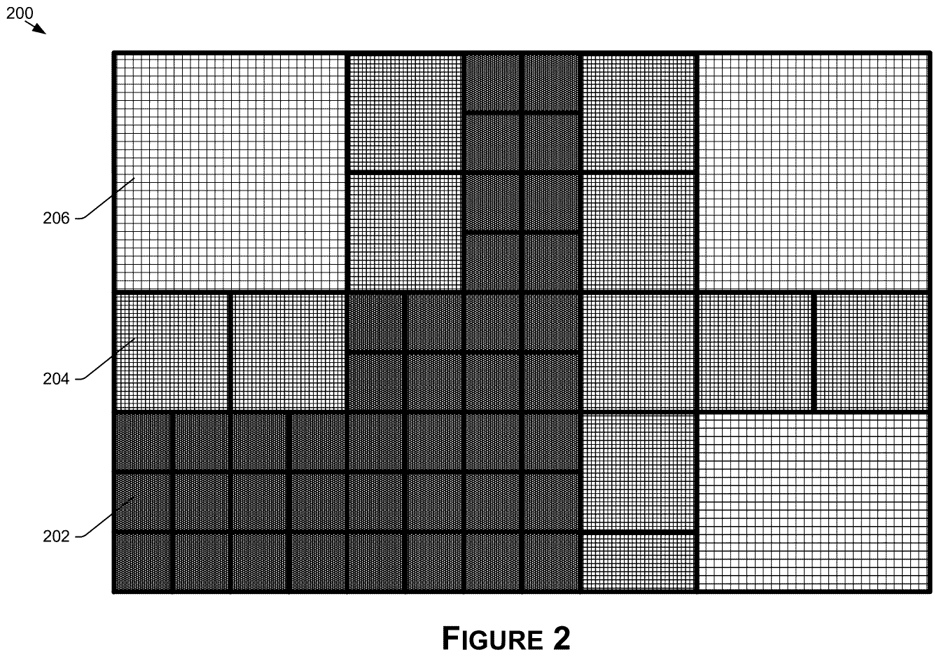

For instance, FIG. 2 illustrates an example of a mesh data structure 200 including a plurality of instanced mesh tiles having varying levels of detail, in accordance with some embodiments of the present disclosure. In the example of FIG. 2, the mesh data structure 200 is depicted from a top-down, or birds-eye-view. In some examples, the mesh data structure 200 may correspond to the terrain mesh data 116. That is, the terrain mesh data 116 may, in some examples, include data similar to the mesh data structure 200 for representing a 3D terrain. The mesh data structure 200 in the example of FIG. 2 includes a plurality of first mesh tiles 202 associated with a first level of detail, a plurality of second mesh tiles 204 associated with a second level of detail, and a plurality of third mesh tiles 206 associated with a third level of detail. In some examples, the first mesh tiles 202 may include the most or highest level of detail, while the third mesh tiles 206 may include the least or lowest level of detail. As described herein, the first mesh tiles 202 may, in some examples, be instantiated at locations in the virtual environment closest to a pathway (e.g., simulated roads, etc.) for a machine. For instance, in the context of vehicle simulations, it may be advantageous to have the highest level of detail close to driving surfaces where the vehicles are operating, while portions of the 3D terrain farther away from the driving surfaces may be represented in less detail. Additional details regarding instantiating mesh tiles having varying levels of detail at optimal locations in a simulation environment are described in U.S. patent application Ser. No. 18/769,738, which, as noted above, is hereby incorporated by reference herein in its entirety and for all purposes.

Additionally, FIG. 3A illustrates example detail associated with mesh tiles and edges of the mesh tiles, which may be included in the terrain mesh data 116. The mesh 300 depicted in the example of FIG. 3A includes a portion of a first mesh tile 202 including a plurality of first polygons 302, a portion of a second mesh tile 204 including a plurality of second polygons 304, and a portion of a third mesh tile 206 including a plurality of third polygons 306. The first mesh tile 202 may correspond to one of the first mesh tiles 202 in the example of FIG. 2, the second mesh tile 204 may correspond to one of the second mesh tiles 204 in the example of FIG. 2, and the third mesh tile 206 may correspond to one of the third mesh tiles 206 in the example of FIG. 2. As such, the first mesh tile 202 and the first polygons 302 may be associated with a first level of detail (e.g., highest level), the second mesh tile 204 and the second polygons 304 may be associated with a second level of detail, and the third mesh tile 206 and the third polygons 306 may be associated with a third level of detail (e.g., lowest level). The mesh 300 may also include “skirting” as shown at 308, to smooth transition areas 310 between adjacent mesh tiles of two different mipmap levels to avoid visible seams. The skirting 308 may allow for the same instanced mesh used to generate the terrain surface to have seamless connections with meshes of varying levels of detail.

Referring back to the example of FIG. 1, the terrain mesh updater 102 may also receive the feature data 118, which may include or indicate information associated with various features to be rendered in the virtual environment and/or added to the 3D terrain. In some examples, the features may include one or more unique (e.g., non-instanced) features or objects (e.g., pathways, sidewalks, driving surfaces, etc.) to be added to, or “cut out” of, the terrain surface. For example, in the context of generating a simulation environment for testing autonomous vehicles, the features may include driving surfaces, sidewalks, curbs, or any other pathway-related features. In some examples, the features may correspond to actual features in a real-world environment, and the system(s) may render a digital twin of the real-world environment in the simulation environment.

In some instances, the feature data 118 may include two-dimensional (2D) lines and/or shapes representing the features, and the 2D lines/shapes may be positioned on the mesh data structure/mesh tiles at locations where the features are to be rendered within the 3D simulation environment. For example, a sidewalk may be represented using a number of 2D lines to, among other things, define a shape of the sidewalk, define edges where the sidewalk abuts base terrain surfaces (e.g., of the mesh tiles), define edges where the sidewalk abouts a road surface, define locations of the sidewalk with respect to the simulation environment, etc.

For instance, FIG. 3B illustrates an example representation of a feature 312, which may be included in the feature data 118. As described above, a geometry of the feature 312 may be represented using a 2D shape/lines. The feature 312 and the mesh 300 in the examples of FIGS. 3A-3E are represented as being viewed from a top-down perspective, also referred to as a birds-eye-view. The 2D shape/lines associated with the feature 312 may define the edges of the feature 312 there the feature 312 abuts the terrain surface represented using the mesh 300. The feature 312, or the 2D shape representing the feature 312, may be positioned on the mesh 300 at the location where the feature 312 is to be rendered in the virtual environment. For instance, the mesh 300 illustrated in the example of FIG. 3B may correspond to a specific portion of the terrain mesh associated with a specific region/area in the virtual environment, and the feature 312 may be rendered in the virtual environment within that specific region/are and at the position, location, and/or orientation shown.

Referring back to the example of FIG. 1, the terrain mesh updater 102 may use the feature data 118 to determine portions of the terrain mesh data 116 that are located within a threshold proximity of the features. For example, the 2D lines defining the features may be overlaid on the terrain mesh tiles as shown in the example of FIG. 3B, and the terrain mesh updater 102 may identify the portions of the mesh tiles that are located within a threshold proximity of the 2D lines. As a first example, the terrain mesh updater 102 may identify polygons of the mesh tiles that the 2D lines pass through or intersect with. As a second example, the terrain mesh updater 102 may identify polygons of the mesh tiles whose center point's or edges are less than a threshold distance (e.g., 2D Euclidian distance, 3D Euclidian distance, etc.) from the 2D lines.

In some examples, the threshold distance may vary based on the level of detail associated with a given mesh tile. For instance, and for a first mesh tile having a relatively higher level of detail or resolution (e.g., small polygons), the threshold distance may be smaller or shorter than for a second mesh tile having a relatively lower level of detail or resolution (e.g., large polygons). In other words, the terrain mesh updater 102 may determine whether one or more first portions of one or more first mesh tiles associated with a first level of detail are located within a first threshold distance of the one or more features, determine whether one or more second portions of one or more second mesh tiles associated with second level of detail are located within a second threshold distance of the one or more features, and so forth. In such an example, a difference between the first threshold distance and the second threshold distance (and/or any other successive thresholds) may be based at least on differences in levels of detail between the one or more first mesh tiles and the one or more second mesh tiles.

In some examples, the terrain mesh updater 102 may generate the updated terrain mesh data 120 by updating one or more of the mesh tiles of the terrain mesh data 116 to hide the portions that are located within the threshold distance of the features. For instance, the terrain mesh updater 102 may update one or more attributes or parameters associated with the mesh tiles to hide the portions. As an example, each polygon of each mesh tile may have a corresponding set of attributes or parameters, and the terrain mesh updater 102 may, for each polygon that is to be hidden, alter an attribute or parameter that causes those polygons to be hidden. In some examples, to hide the portions of the mesh tiles, the terrain mesh updater 102 may apply a shader function(s) to the portions of the mesh tiles. By hiding the portions of the mesh tiles, the terrain mesh updater 102 may cause the terrain surface to be rendered in the virtual environment without rendering the portions of the mesh tiles that are located within the threshold distance of the features. In other words, when the terrain surface is rendered, the terrain surface is rendered using the visible or non-hidden portions of the mesh tiles that are distinguishable from the hidden portions.

For instance, FIG. 3C illustrates an example in which a plurality of portions of mesh tiles have been hidden, in accordance with some embodiments of the present disclosure. In the example of FIG. 3C, the mesh 300 may be updated by the terrain mesh updater 102 such that the mesh 300 includes hidden portions 314. For example, a first plurality of the first polygons 302 of the first mesh tile 202, a second plurality of the second polygons 304 of the second mesh tile 204, and a third plurality of the third polygons 306 of the third mesh tile 206 may be hidden from the mesh by the terrain mesh updater 102. That is, as opposed to actually altering the geometry of the mesh tiles and removing the polygons, the terrain mesh updater 102 may update the parameters of the mesh tiles to hide the polygons included in the hidden portions 314. By hiding the portions of the mesh tiles, the polygons of the mesh tiles within a threshold distance of the edges of the feature 312 may be hidden, as shown in the example of FIG. 3C.

As illustrated in the example of FIG. 3C, larger portions of the mesh tiles may be hidden based on the level of detail associated with those tiles. For instance, for the first mesh tile 202, distances between the edges of the feature 312 and the visible, first polygons 302 may be greater than the distances between the edges of the feature 312 and the visible, second polygons 304 of the second mesh tile 204. Similarly, for the second mesh tile 204, distances between the edges of the feature 312 and the visible, second polygons 304 may be greater than the distances between the edges of the feature 312 and the visible, third polygons 306 of the third mesh tile 206. In some examples, the threshold distance between a feature and a portion of a mesh tile may be based on a function of the level of detail of the mesh tile and/or sizes of polygons. For instance, the threshold distance between feature edges and tile portions may be a distance that is equal to one-half, three-fourths, etc. the length of a polygon edge of the mesh tile. While these are just a couple of examples, in additional or alternative examples, any number of methods may be used by the terrain mesh updater 102 to determine or set the threshold distance for determining which portions of the mesh tiles to hide.

Referring back to the example of FIG. 1, the process 100 may also include the replacement mesh generator 104 using the feature data 118 and/or the updated terrain mesh data 120 to generate the replacement mesh data 122, which may represent one or more replacement meshes for replacing the hidden portions of the updated terrain mesh data 120. In some examples, to generate the replacement mesh data 122, the replacement mesh generator 104 may determine geometries associated with the hidden portions of the updated terrain mesh data 120, and use the geometries to generate the replacement mesh data 122 such that the replacement meshes have the same or similar geometries. For instance, the replacement mesh generator 104 may determine a shape of the hidden portions (e.g., an overall shape of the hidden polygons) of the mesh tiles of the updated terrain mesh data 120 so that the replacement meshes may be generated to have the same or similar shape in order to be combined with the non-hidden portions of the mesh tiles.

In some examples, the replacement meshes of the replacement mesh data 122 may be generated to include vertices, edges, polygons, faces, etc. that correspond to the features. That is, while the overall shape or geometry of the replacement meshes may correspond to the hidden portions of the mesh tiles, the individual polygon shapes within the replacement meshes may define the 3D structure of the features that are being added to, cut out of, or rendered on top of the terrain surface base. As such, the replacement meshes may, in some instances, be associated with a relatively higher level of detail than the mesh tiles and/or their hidden portions. For instance, the mesh tiles, because of their uniform base meshes, may not include enough detail (e.g., polygons, etc.) to be capable of accurately defining edges of the features with high visual quality. In other words, to realistically define the 3D structure of the unique features in the virtual environment, the replacement mesh generator 104 may generate the replacement meshes to replace the hidden portions of the mesh tiles that the features are located next to, and the replacement meshes may include a greater number of, or more strategically placed, vertices, edges, polygons, etc. than the mesh tiles for the base terrain layer.

For instance, FIG. 3D illustrates an example of a replacement mesh 316 that may be generated for replacing the hidden portions 314 of the mesh 300 described in the example of FIG. 3C. As shown, the replacement mesh 316 may include a plurality of polygons, and the polygons may follow the same or similar resolution as the first, second, and third polygons 302-306 of the mesh 300. Additionally, in some examples, the replacement mesh 316 may include a plurality of edges 320 that correspond to edges of the feature 312 described in the example of FIG. 3C. As described herein, the geometry of the replacement mesh may correspond to the geometry of the hidden portions 314 of the mesh 300. Additionally, the replacement mesh 316 may be associated with a higher level of detail than the hidden portions 314 of the mesh 300, or represent different types of 3D topologies than the hidden portions 314 of the mesh 300 (e.g., the replacement mesh 316 may represent topology of a sidewalk, outcropping, etc., while the hidden portions 314 of the mesh 300 may represent a base terrain layer). For instance, the replacement mesh 316 may include the edges 320 for the features, and these edges 320 may increase the level of detail/resolution of the replacement mesh 316 with respect to the original mesh 300 by increasing the number of polygons 318.

Referring back to the example of FIG. 1, the process 100 may also include the terrain surface processor 106 combining the updated terrain mesh data 120 and the replacement mesh data 122. For instance, as part of the terrain surface processor 106 generating the texture elevation mesh 126, the terrain surface processor 106 may merge the updated terrain mesh data 120 and the replacement mesh data 122 to generate a combination of the mesh data structures. The terrain surface processor 106 may merge the meshes based at least on the geometries of the replacement mesh data 122 corresponding to the geometries of the portions of the terrain mesh data 116 that are hidden in the updated terrain mesh data 120. In some examples, the terrain surface processor 106 may apply skirting to the edge portions (e.g., edge polygons) of the updated terrain mesh data 120 and/or the replacement mesh data 122 to ensure seamless transitions between the meshes. By way of example, and not limitation, FIG. 3E illustrates an example of a combined mesh 322 that includes the non-hidden portions of the mesh tiles 202-206 and the replacement mesh 316. As shown, the replacement mesh 316 may be seamlessly merged with the non-hidden portions of the mesh tiles based on the geometry of the replacement mesh 316 corresponding to (e.g., matching) that of the hidden portions of the mesh 300.

In some examples, the terrain surface processor 106 may use the texture image data 124 and the combined meshes (e.g., the updated terrain mesh data 120 and the replacement mesh data 122) to generate the texture elevation mesh 126. For instance, the terrain surface processor 106 may apply the texture image data 124 to one or more texture nodes of the combined meshes to generate the texture elevation mesh 126. The texture elevation mesh 126 may be representative of the 3D terrain with textures applied to the 3D terrain. In some examples, the resolution of the texture images applied to the texture nodes may vary based on the level of detail associated with the mesh tile the texture nodes correspond to. For instance, lower resolution images/textures may be applied to texture nodes of larger mesh tiles (e.g., lower level of detail tiles) while higher resolution images/textures may be applied to texture nodes of smaller tiles (e.g., higher level of detail tiles).

In some examples, the terrain surface processor 106 may determine how certain features will operate on the terrain mesh and on hardtop surfaces, such as pedestrian walkways, based on metadata and/or user-defined data associated with the features. For instance, this data may provide cutout priorities, surface operations, and/or hardtop removal. In some instances, the terrain surface processor 106 may use the data to resolve overlaps and conflicts between features. The terrain surface processor 106 may use the cutout priorities to cut shapes with higher priority out of shapes with lower priority. The terrain surface processor 106 may also, in some examples, use the surface operation data to determines if a cutout shape will slice, and assign materials on either the terrain or the hardtop surfaces.

Take, for example, a sidewalk that is to be rendered as part of the 3D terrain in a simulation environment. The location, geometry, edges, etc. of the sidewalk within the simulation environment may be defined from a top-down perspective using 2D lines and/or shapes. Additionally, the sidewalk may include details that are to be cut out of the sidewalk, such as planters for trees. In such an example, the planters and/or other details may also be defined from the top-down perspective using 2D lines/shapes. However, it may be difficult to determine which features are to appear in which order in the simulation environment. By using the feature priority, the terrain surface processor 106 may be able to determine that the sidewalk has a lower cutout priority than the planter, and the terrain surface processor 106 may remove, or cut out, the geometry of the planter from the sidewalk based on the priority.

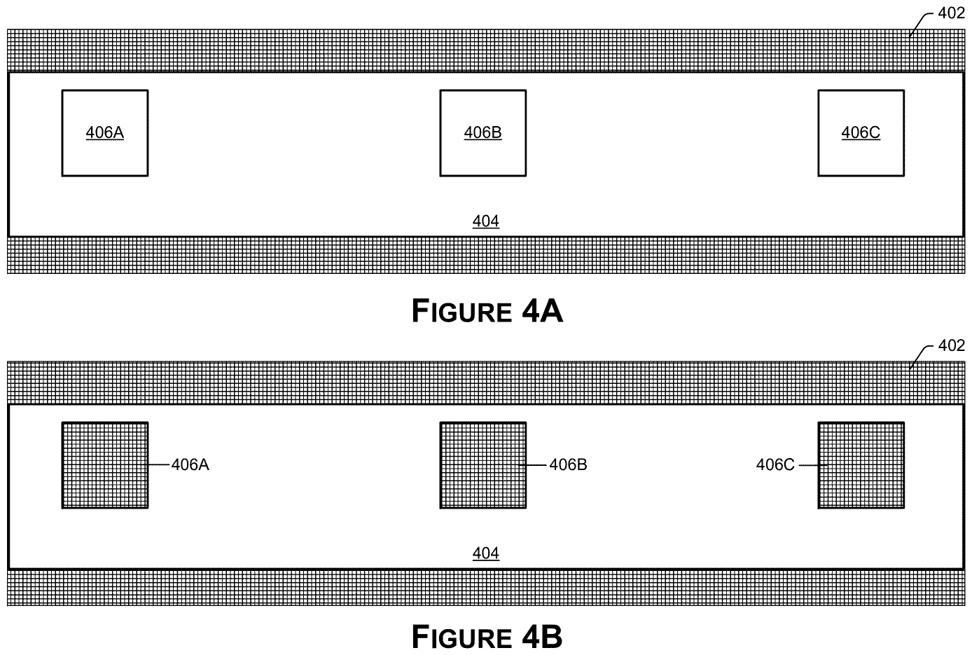

For instance, FIGS. 4A and 4B collectively illustrate an example of using priorities associated with features to determine how features should be rendered in a virtual environment, in accordance with some embodiments of the present disclosure. In the example of FIG. 2, a mesh 402 corresponding to a terrain surface may be modified to include a sidewalk 404, and the sidewalk 404 may include planters 406A-406C. As shown in FIG. 4A, the sidewalk 404 and planters 406A-406C may be defined from a top-down perspective using 2D lines. The sidewalk 404 may be assigned a first cutout priority level, and the planters 406A-406C may be assigned a second cutout priority level. As such, and as shown in the example of FIG. 4B, the planters 406A-406C may be cut out of the sidewalk 404 when rendered in the virtual environment.

Referring back to the example of FIG. 1, the process 100 may further include the simulation processor 108 using the scene rendering engine 114 to execute and/or render a simulated driving environment within which one or more simulated machine agents may simulate travel across one or more roadway surfaces defined, at least in part, based on the terrain surface rendering data 128 and/or texture elevation mesh 126 produced by the terrain surface processor 106. In some embodiments, the terrain surface processor 106 may be a component at least in part integrated with the simulation processor 108, or may be a distinct component separate from the simulation processor 108.

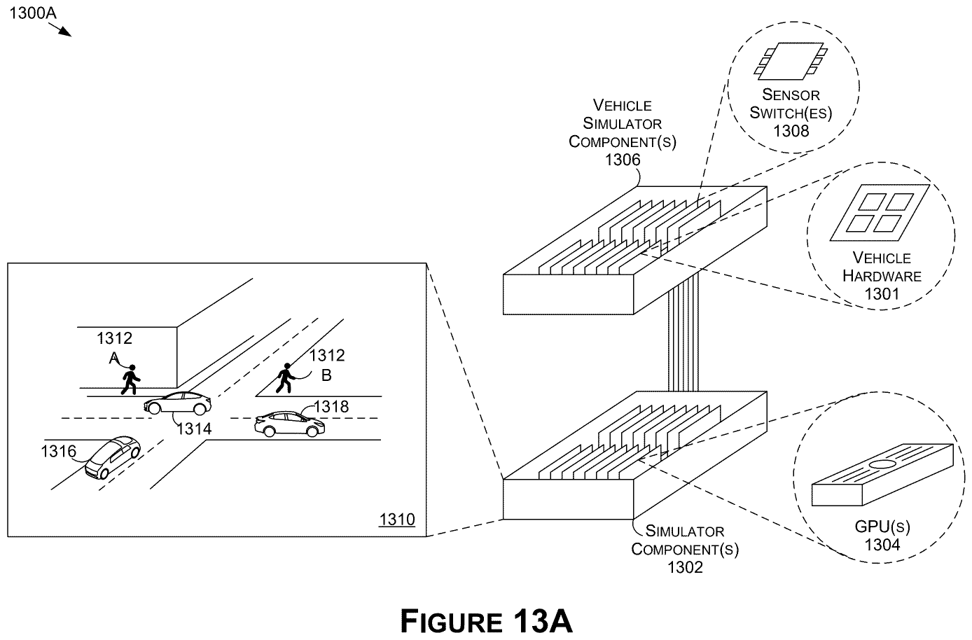

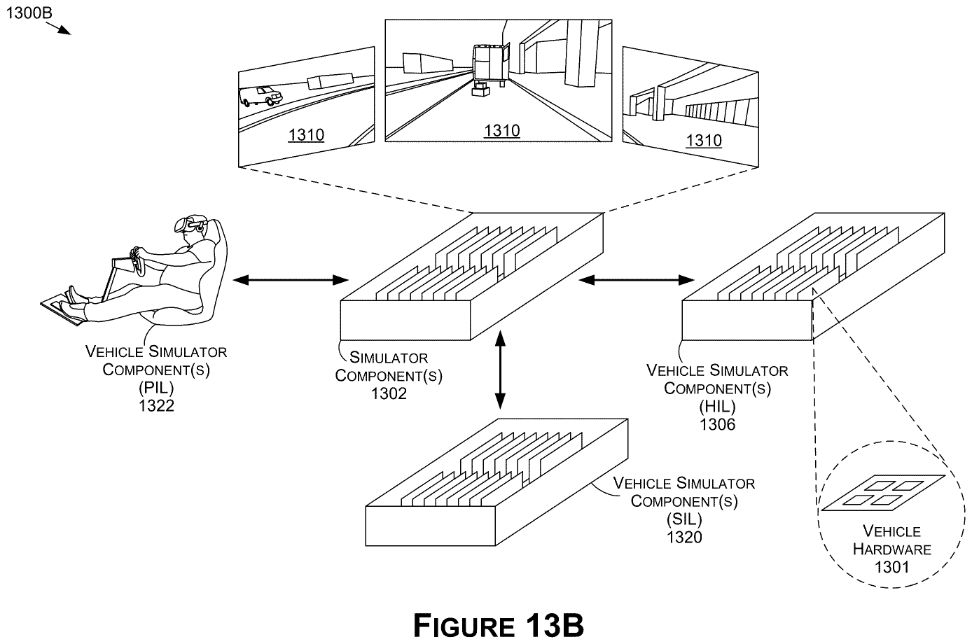

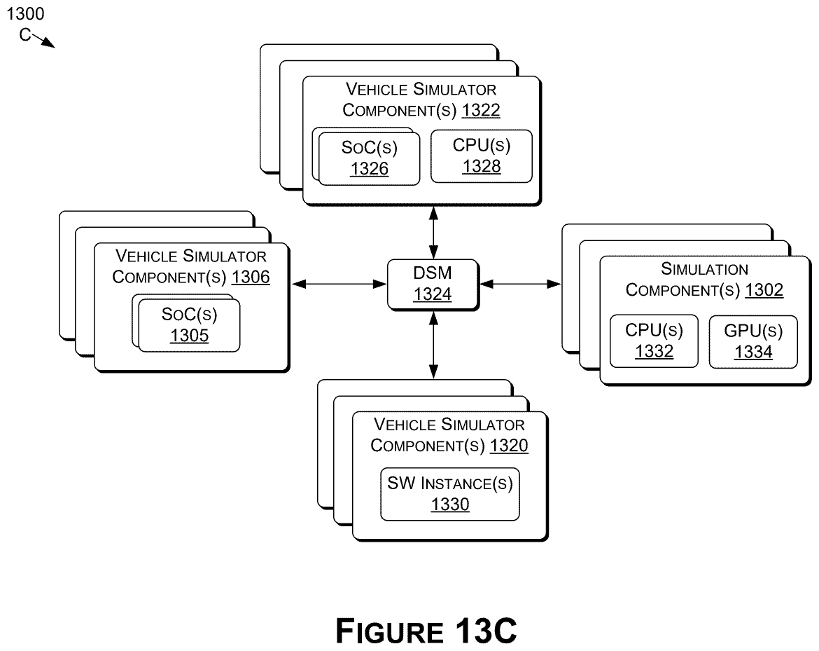

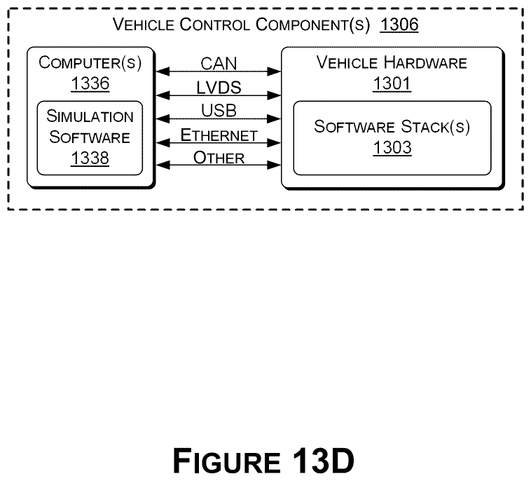

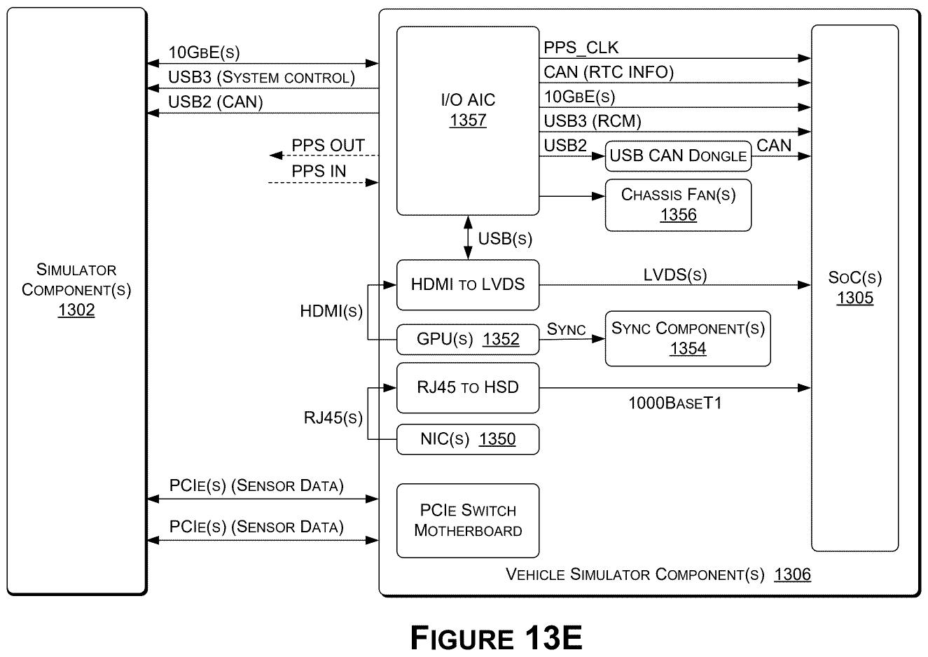

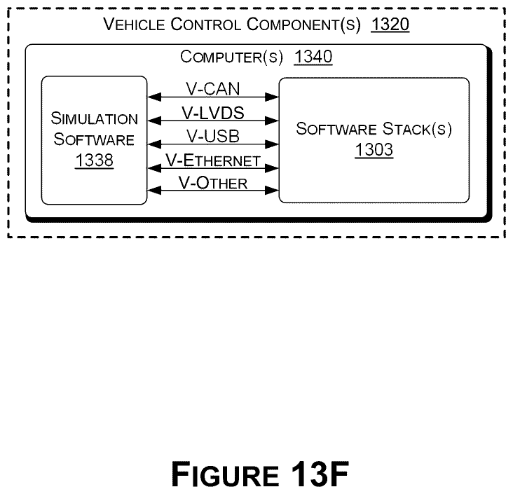

The scene rendering engine 114 may include one or more algorithms executed at least in part on one or more graphics processing units (GPUs) (or other parallel processing circuitry, such as a parallel processing unit (PPU), a deep learning accelerator (DLA), a vector processing unit (VPU), a programmable vision accelerator (PVA), etc.) that may operate in conjunction with software executed on a central processing unit(s) (CPU(s)) coupled to memory - such as described with respect to any of FIGS. 13A-13F and/or 14A-14B. The GPUs may be programmed to execute kernels to implement one or more of the features and functions of the terrain surface processor 106 and/or the scene rendering engine 114. In some embodiments, some features and functions of the terrain surface processor 106 and/or the scene rendering engine 114 may be distributed and performed by a combination of processors and/or cloud computing resources - such as described with respect to FIG. 16.

Input channels to the scene rendering engine 114 may include the terrain surface rendering data 128, a physics engine 112, simulation parameters 130, and/or simulated machine agent data 132. In some embodiments, input channels to the scene rendering engine 114 may include real-time user inputs 134. Simulation parameters 130 may include operating parameters relevant to structuring and performing a driving simulation, such as simulation duration and frame rendering frequency. In some embodiments, simulated machine agent data 132 may define characteristics of one or more simulated vehicles within the driving environment (e.g., size, weight, or other characteristics). The physics engine 112 may provide data regarding interactions between the simulated machine agents and the simulated roadway surfaces according to real-life physics (e.g., to perform a simulation of the simulated vehicle sitting on, and/or driving across, the simulated drivable surface). Real-time user inputs 134 may include, for example, user interactions to control the speed and/or direction of one or more of the machine agents within the simulation.

Based at least on one or more of the input channels, the scene rendering engine 114 may generate one or more runtime simulation outputs 136, which may comprise a visual rendering of a scene and/or results of physical simulations of interactions between rigid bodies within the simulated driving environment. The runtime simulation output(s) 136 may be displayed to the human-machine interface (HMI) 110 (e.g., a display screen) and/or stored for subsequent streaming, such as to the HMI 110. In one or more embodiments, the runtime simulation output(s) 136 generated by the simulation processor 108 based at least on the terrain surface rendering data 128 may be used for other purposes. For example, such runtime simulation output(s) 136 from simulated driving environments may be used in the process of training and/or validating machine learning models that are used to operate ego machines such as, but not limited to, autonomous and semi-autonomous vehicles. In some embodiments, the runtime simulation output(s) 136 includes renderings of drivable surfaces together with the texture elevation mesh 126 that may be used to generate synthetic sensor data for training and/or testing machine learning models and/or other components of ego machines such as autonomous and semi-autonomous vehicles. For example, the simulation processor 108 may generate the runtime simulation output(s) 136 in the form of synthetic image data for one or more cameras or other virtualized image sensors of an ego vehicle (such as ego machine 1500 described with respect to FIG. 15A-15D) that is using the simulated driving platform to provide a simulated driving environment for training and/or testing components of the ego vehicle.

In some examples, the simulation processor 108 may map and re-project a top-down view of the texture elevation mesh 126 into one or more first-person perspective views based on the fields of view for each sensor of an ego agent's set of sensors. The sensors of each ego agent may, therefore, be able to capture high-fidelity surface data from terrain surfaces in close proximity to their respective sensor(s) in order to accurately perceive their immediate surroundings—while lower-density, less-detailed surface texture renderings are generated for surfaces of the texture elevation mesh at increasingly farther distances from the sensor (where it is more acceptable that fewer surface details are perceptible at distant surfaces as compared to surfaces that are close). Additionally, because the texture elevation mesh 126 may be based on a hybrid structure in which portions of mesh tiles are replaced with unique meshes at locations corresponding to (e.g., within a threshold distance of) unique features to be included as part of the 3D terrain, the sensors of the ego agents may be able to capture high-fidelity sensor data corresponding to those unique features, such as driving surfaces, sidewalks, etc.

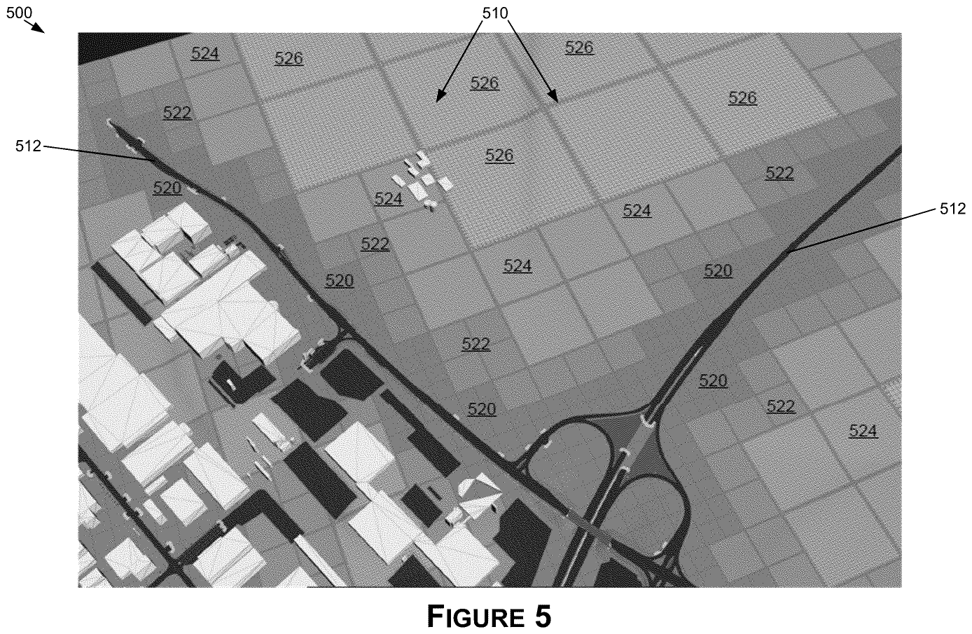

FIGS. 5, 6, and 7 are diagrams illustrating example terrain surface renderings using modified mesh tiles based on feature locations, in accordance with some embodiments of the present disclosure. Each of the FIGS. 5, 6, and 7 represent renderings that may be computed by the simulation processor 108 and output as runtime simulation output(s) 136 (e.g., for display on an HMI 110).

FIG. 5 illustrates an example top-down rendering of a simulation environment 500 depicting where the terrain 510 extending from one or more navigable pathways 512 comprises image tiles that are structured based on a pathway anchored quadtree structure, and assigned texture images based on mipmap surface texture image data 124. For example, image tiles 520 correlate to root-level mesh tiles, image tiles 522 correlate to second-level mesh tiles, image tiles 524 correlate to third-level mesh tiles, and image tiles 526 correlate to fourth-level mesh tiles, where their assigned levels are based at least in part on a distance of the respective tile from the one or more navigable pathways 512. Additionally, the navigable pathways 512 may be rendered based at least on the terrain mesh updater 102 generating the updated terrain mesh data 120 to hide one or more portions of the mesh tiles located within a threshold proximity of the navigable pathways 512, and the replacement mesh generator 104 generating the replacement mesh data 122 to be combined with the updated terrain mesh data 120 (e.g., the non-hidden portions of the terrain mesh data 116).

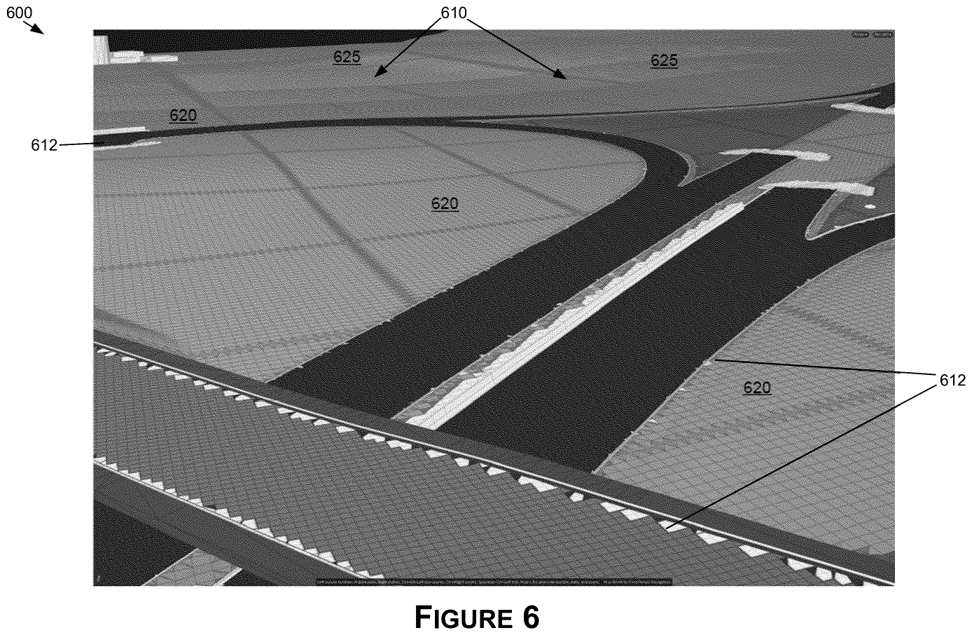

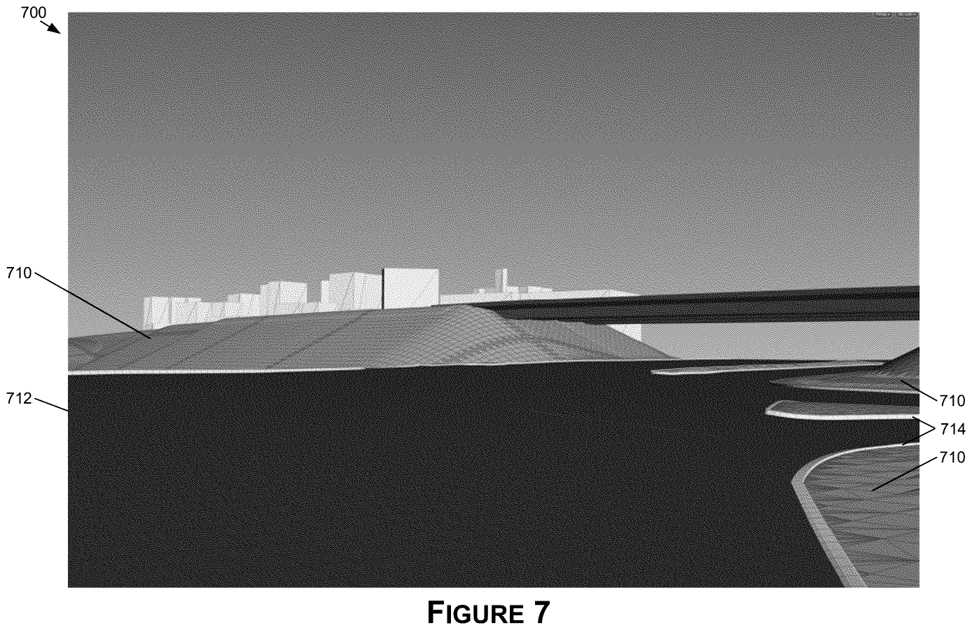

FIG. 6 illustrates an example perspective view rendering of a simulation environment 600 depicting where the terrain 610 extending from one or more navigable pathways 612 comprises image tiles that are structured based on a pathway anchored quadtree structure, and assigned texture images based on mipmap surface texture image data. When the sensors of an ego agent traveling on the one or more navigable pathways 612 capture the scene of the terrain 610, the sensors may, from their perspective, observe higher fidelity surface textures at those surface areas of the texture elevation mesh defined by root-level quadtree mesh tiles 620 and unique, replacement meshes for the terrain—while lower-density, less-detailed surface texture renderings are generated for surfaces of the texture elevation mesh (shown at 625) farther distanced from the sensor, where it may be more acceptable that fewer surface details are perceptible. As an example, FIG. 7 illustrates an example ground-perspective view 700 of a portion of the terrain 710 as it may be observed from the vantage point of a sensor of an ego agent traveling on navigable pathways 712 within a simulated driving environment. In the example of FIG. 7, the navigable pathways 712 and/or the curbs 714 of the 3D terrain may be generated and/or defined using the unique, replacement mesh data structures described herein.

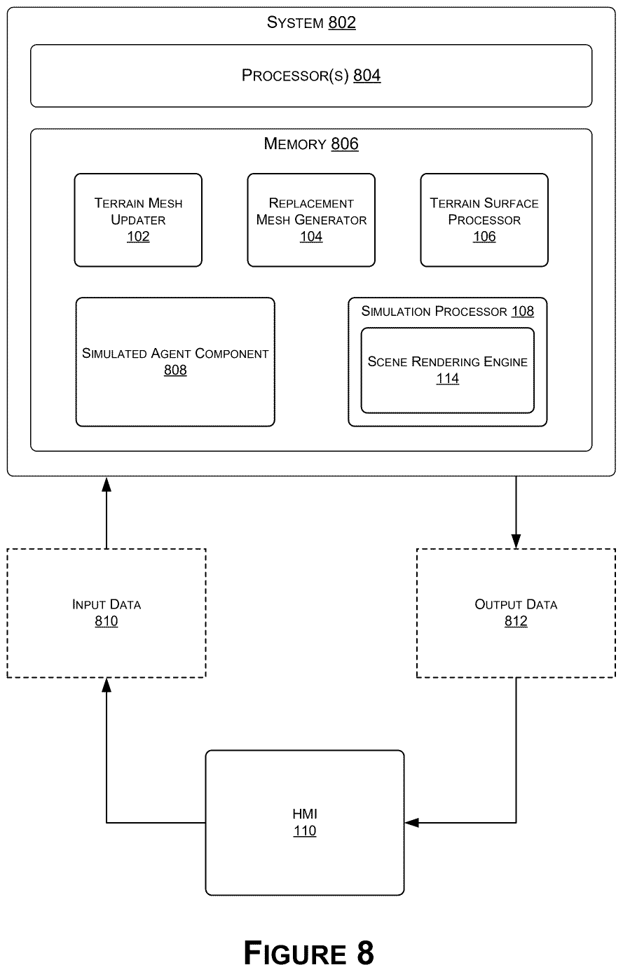

Referring now to FIG. 8, an example of a system that may perform one or more of the processes described herein is illustrated in FIG. 8, in accordance with some embodiments of the present disclosure. As shown, the system 802 (which may represent, and/or include, the example computing device(s) 1600 and/or the example data center 1700) may include one or more processors 804 (which may be similar to, and/or include, the CPUs 1606 and/or the GPUs 1608) and memory 806 (which may be similar to, and/or include, the memory 1604). For instance, the memory 806 may store one or more of the terrain mesh updater 102, the replacement mesh generator 104, the terrain surface processor 106, the simulation processor 108, and/or a simulated agent component 808. Additionally, the processor(s) 804 may execute one or more of the terrain mesh updater 102, the replacement mesh generator 104, the terrain surface processor 106, the simulation processor 108, and/or the simulated agent component 808 to perform one or more of the processes described herein. In some examples, the simulated agent component 808 may control behaviors of simulated agents in the simulation environment.

In some examples, the system 802 may receive input data 810 from the HMI 110. The input data 810 may include one or more of the simulation parameters 130, the user inputs 134, and/or any other input data described herein. The system 802 may then process and evaluate the input data 810 in order to run the simulation, update the simulation, etc. The system 802 may send output data 812, which may include the runtime simulation output(s) 136 and/or any other output data described herein. The HMI 110 may use the output data 812 to display data associated with the simulation, such as one or more views of the simulation environment, data associated with the simulated agents, or any other simulation-related data. Although depicted as being separate systems, the system 802 and the HMI 110 may, in some examples, be the same or different systems.

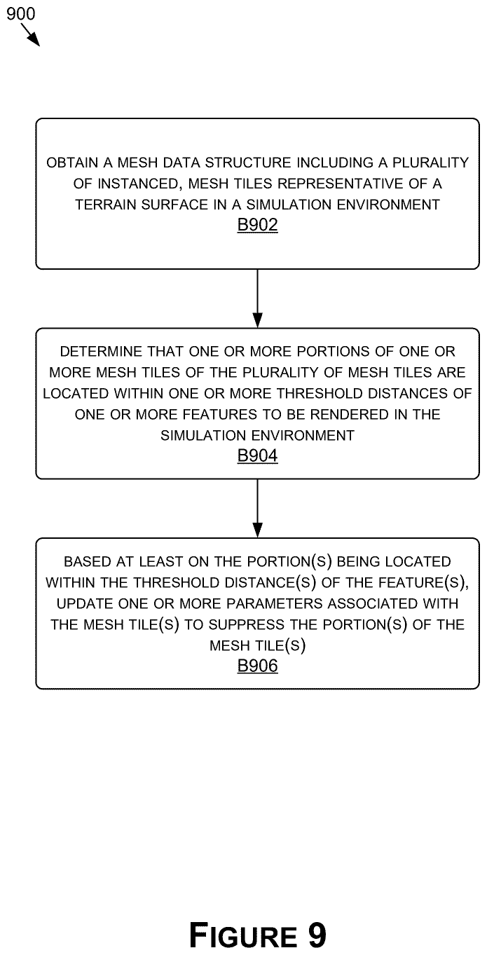

Now referring to FIGS. 9-12, each block of methods 900, 1000, 1100, and 1200, described herein, comprises a computing process that may be performed using any combination of hardware, firmware, and/or software. For instance, various functions may be carried out using one or more processors executing instructions stored in one or more memories. The methods may also be embodied as computer-usable instructions stored on computer storage media. The methods may be provided by a standalone application, a service or hosted service (standalone or in combination with another hosted service), as a microservice via an application programming interface (API) or a plug-in to another product, to name a few. In addition, methods 900, 1000, 1100, and 1200 are described, by way of example, with respect to the system of FIG. 1. However, these methods may additionally or alternatively be executed by any one system, or any combination of systems, including, but not limited to, those described herein.

FIG. 9 is a flow diagram illustrating an example of a method 900 for hiding portions of mesh tiles based on feature proximity, in accordance with some embodiments of the present disclosure. The method 900, at block B902, includes obtaining a mesh data structure including a plurality of instanced mesh tiles representative of a terrain surface in a simulation environment. For instance, the terrain mesh updater 102 may obtain the terrain mesh data 116, which may include the plurality of instanced mesh tiles representative of the terrain surface.

The method 900, at block B904, includes determining that one or more portions of one or more mesh tiles of the plurality of mesh tiles are located within one or more threshold distances of one or more features to be rendered in the simulation environment. In some examples, the terrain mesh updater 102 may analyze the terrain mesh data 116 with respect to the feature data 118 to determine the portion(s) of the mesh tile(s) of the plurality of mesh tiles that are located within the threshold distance(s) of the feature(s) to be rendered in the simulation environment.

The method 900, at block B906, includes based at least on the portion(s) being located within the threshold distance(s) of the feature(s), update one or more parameters associated with the mesh tile(s) to suppress the portion(s) of the mesh tile(s). For example, the terrain mesh updater 102 may generate the updated terrain mesh data 120 by updating the parameter(s) associated with the mesh tile(s) of the terrain mesh data 116 to suppress the portion(s) of the mesh tile(s) located within the threshold distance(s) of the feature(s).

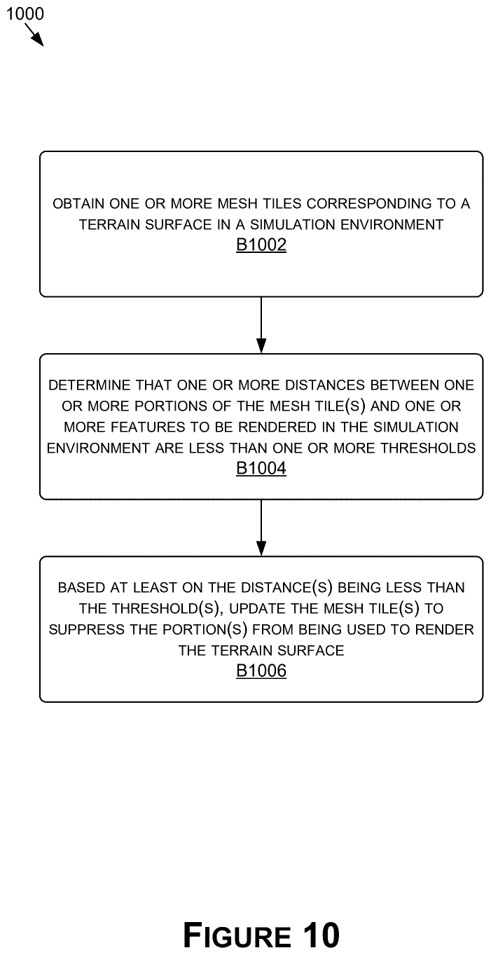

FIG. 10 is a flow diagram illustrating an example of a method 1000 for updating mesh tiles to suppress portions of the mesh tiles determined to be within a threshold distance of features to be rendered in a simulation environment, in accordance with some embodiments of the present disclosure. The method 1000, at block B1002, includes obtaining one or more mesh tiles corresponding to a terrain surface in a simulation environment. For instance, the terrain mesh updater 102 may obtain the terrain mesh data 116, which may include the mesh tiles corresponding to the terrain surface.

The method 1000, at block B1004, includes determining that one or more distances between one or more portions of the mesh tile(s) and one or more features to be rendered in the simulation environment are less than one or more thresholds. In some examples, the terrain mesh updater 102 may compare the terrain mesh data 116 and the feature data 118 to determine that the distance(s) between the portion(s) of the mesh tile(s) and the feature(s) to be rendered in the simulation environment are less than the threshold(s).

The method 1000, at block B1006, includes based at least on the distance(s) being less than the threshold(s), update the mesh tile(s) to suppress the portion(s) from being used to render the terrain surface. For example, the terrain mesh updater 102 may generate the updated terrain mesh data 120 based at least on the distance(s) being less than the threshold(s). In some instances, by updating the mesh tile(s), the terrain mesh updater 102 may suppress the portion(s) of the mesh tile(s) located within the threshold distance(s) from being used to render the terrain surface. For instance, the terrain mesh updater 102 may update one or more parameters associated with the mesh tile(s) or the portion(s) to hide the portion(s) from the mesh tile(s).

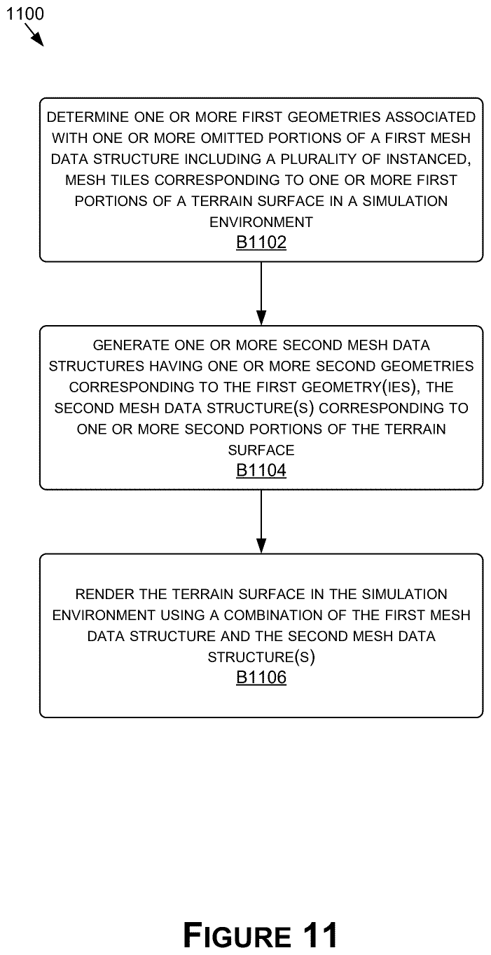

FIG. 11 is a flow diagram illustrating an example of a method 1100 for generating one or more replacement meshes based on geometries of omitted portions of mesh tiles, in accordance with some embodiments of the present disclosure. The method 1100, at block B1102, includes determine one or more first geometries associated with one or more omitted portions of a first mesh data structure including a plurality of instanced mesh tiles corresponding to one or more first portions of a terrain surface in a simulation environment. For instance, the replacement mesh generator 104 may analyze the updated terrain mesh data 120 to determine the first geometry(ies) associated with the omitted portion(s) of the terrain mesh data 116, which may correspond to the first mesh data structure.

The method 1100, at block B1104, includes generate one or more second mesh data structures having one or more second geometries corresponding to the first geometry(ies), the second mesh data structure(s) corresponding to one or more second portions of the terrain surface. For instance, the replacement mesh generator 104 may generate the replacement mesh data 122, which may correspond to the second mesh data structure(s) that have the second geometry(ies) corresponding to the first geometry(ies).

The method 1100, at block B1106, includes render the terrain surface in the simulation environment using a combination of the first mesh data structure and the second mesh data structure(s). For instance, the terrain surface processor 106 may generate the texture elevation mesh 126, which may correspond to the combination of the updated terrain mesh data 120 and the replacement mesh data 122. Additionally, in some examples, the scene rendering engine 114 may use the texture elevation mesh 126 to render the terrain surface as part of the runtime simulation output(s) 136.

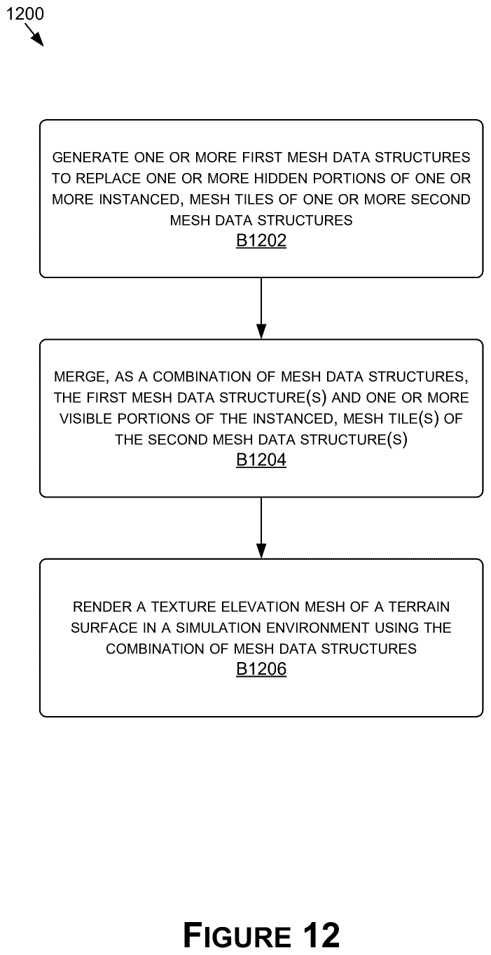

FIG. 12 is a flow diagram illustrating an example of a method 1200 for rendering a texture elevation mesh using a combination of different mesh data structures, in accordance with some embodiments of the present disclosure. The method 1200, at block B1202, includes generating one or more first mesh data structures to replace one or more hidden portions of one or more instanced mesh tiles of one or more second mesh data structures. For instance, the replacement mesh generator 104 may generate the replacement mesh data 122 to replace the hidden portion(s) of the terrain mesh data 116.

The method 1200, at block B1204, includes merging, as a combination of mesh data structures, the first mesh data structure(s) and one or more visible portions of the instanced, mesh tile(s) of the second mesh data structure(s). In some examples, the terrain surface processor 106 may merge the replacement mesh data 122 and the updated terrain mesh data 120 as part of the texture elevation mesh 126. In such examples, the replacement mesh data 122 may correspond to the first mesh data structure(s), the updated terrain mesh data 120 may correspond to the second mesh data structure(s), and the texture elevation mesh 126 may correspond to the combination. In some examples, the combination of the mesh data structures may also include the texture image data 124 applied to one or more texture nodes of the combination.

The method 1200, at block B1206, includes rendering a texture elevation mesh of a terrain surface in a simulation environment using the combination of mesh data structures. For example, the scene rendering engine 114 may render the texture elevation mesh 126 in the simulation environment as part of the runtime simulation output(s) 136. Additionally, or alternatively, the terrain surface processor 106 may render the texture elevation mesh 126 in the simulation environment.

The systems and methods described herein may be used for a variety of purposes, by way of example and without limitation, for machine (e.g., robot, vehicle, construction machinery, warehouse vehicles/machines, autonomous, semi-autonomous, and/or other machine types) control, machine locomotion, machine driving, synthetic data generation, model training (e.g., using real, augmented, and/or synthetic data, such as synthetic data generated using a simulation platform or system, synthetic data generation techniques such as but not limited to those described herein, etc.), perception, augmented reality (AR), virtual reality (VR), mixed reality (MR), robotics, security and surveillance (e.g., in a smart cities implementation), autonomous or semi-autonomous machine applications, deep learning, environment simulation, object or actor simulation and/or digital twinning, data center processing, conversational AI, light transport simulation (e.g., ray-tracing, path tracing, etc.), distributed or collaborative content creation for 3D assets (e.g., using universal scene descriptor (USD) data, such as OpenUSD, and/or other data types), cloud computing, generative artificial intelligence (e.g., using one or more diffusion models, transformer models, etc.), and/or any other suitable applications.

Disclosed embodiments may be comprised in a variety of different systems such as automotive systems (e.g., a control system for an autonomous or semi-autonomous machine, a perception system for an autonomous or semi-autonomous machine), systems implemented using a robot or robotic platform, aerial systems, medial systems, boating systems, smart area monitoring systems, systems for performing deep learning operations, systems for performing simulation operations (e.g., in a driving or vehicle simulation, in a robotics simulation, in a smart cities or surveillance simulation, etc.), systems for performing digital twin operations (e.g., in conjunction with a collaborative content creation platform or system, such as, without limitation, NVIDIA's OMNIVERSE and/or another platform, system, or service that uses USD or OpenUSD data types), systems implemented using an edge device, systems incorporating one or more virtual machines (VMs), systems for performing synthetic data generation operations (e.g., using one or more neural rendering fields (NERFs), gaussian splat techniques, diffusion models, transformer models, etc.), systems implemented at least partially in a data center, systems for performing conversational AI operations, systems implementing one or more language models - such as one or more large language models (LLMs), one or more vision language models (VLMs), one or more multi-modal language models, etc., systems for performing light transport simulation, systems for performing collaborative content creation for 3D assets (e.g., using universal scene descriptor (USD) data, such as OpenUSD, computer aided design (CAD) data, 2D and/or 3D graphics or design data, and/or other data types), systems implemented at least partially using cloud computing resources, and/or other types of systems.

In some examples, the machine learning model(s) (e.g., deep neural networks, language models, LLMs, VLMs, multi-modal language models, perception models, tracking models, fusion models, transformer models, diffusion models, encoder-only models, decoder-only models, encoder-decoder models, neural rendering field (NERF) models, etc.) described herein may be packaged as a microservice—such an inference microservice (e.g., NVIDIA NIMs)—which may include a container (e.g., an operating system (OS)-level virtualization package) that may include an application programming interface (API) layer, a server layer, a runtime layer, and/or at least one model “engine.” For example, the inference microservice may include the container itself and the model(s) (e.g., weights and biases). In some instances, such as where the machine learning model(s) is small enough (e.g., has a small enough number of parameters), the model(s) may be included within the container itself. In other examples—such as where the model(s) is large—the model(s) may be hosted/stored in the cloud (e.g., in a data center) and/or may be hosted on-premises and/or at the edge (e.g., on a local server or computing device, but outside of the container). In such embodiments, the model(s) may be accessible via one or more APIs-such as REST APIs. As such, and in some embodiments, the machine learning model(s) described herein may be deployed as an inference microservice to accelerate deployment of a model(s) on any cloud, data center, or edge computing system, while ensuring the data is secure. For example, the inference microservice may include one or more APIs, a pre-configured container for simplified deployment, an optimized inference engine (e.g., built using a standardized AI model deployment an execution software, such as NVIDIA's Triton Inference Server, and/or one or more APIs for high performance deep learning inference, which may include an inference runtime and model optimizations that deliver low latency and high throughput for production applications - such as NVIDIA's TensorRT), and/or enterprise management data for telemetry (e.g., including identity, metrics, health checks, and/or monitoring).

The machine learning model(s) described herein may be included as part of the microservice along with an accelerated infrastructure with the ability to deploy with a single command and/or orchestrate and auto-scale with a container orchestration system on accelerated infrastructure (e.g., on a single device up to data center scale). As such, the inference microservice may include the machine learning model(s) (e.g., that has been optimized for high performance inference), an inference runtime software to execute the machine learning model(s) and provide outputs/responses to inputs (e.g., user queries, prompts, etc.), and enterprise management software to provide health checks, identity, and/or other monitoring. In some embodiments, the inference microservice may include software to perform in-place replacement and/or updating to the machine learning model(s). When replacing or updating, the software that performs the replacement/updating may maintain user configurations of the inference runtime software and enterprise management software.

### Example Simulation System

In some embodiments, various aspects of the present disclosure may be used in a simulated environment to test one or more autonomous or semi-autonomous driving software stacks. For example, the simulation system 1300—e.g., represented by simulation systems 1300A, 1300B, 1300C, and 1300D in FIGS. 13A-13D, and described in more detail below—may generate a global simulation that simulates a virtual world or environment (e.g., a simulated environment) that may include artificial intelligence (AI) vehicles or other objects (e.g., pedestrians, animals, etc.), hardware-in-the-loop (HIL) vehicles or other objects, software-in-the-loop (SIL) vehicles or other objects, and/or person-in-the-loop (PIL) vehicles or other objects. The simulated driving platform system 140 may be implemented at least in part based on simulation systems 1300. The global simulation may be maintained within an engine (e.g., a game engine), or other software-development environment, that may include a rendering engine (e.g., for 2D and/or 3D graphics), a physics engine (e.g., for collision detection, collision response, etc.), sound, scripting, animation, AI, networking, streaming, memory management, threading, localization support, scene graphs, cinematics, and/or other features. In some examples, as described herein, one or more vehicles or objects within the simulation system 1300 (e.g., HIL objects, SIL objects, PIL objects, AI objects, etc.) may be maintained within their own instance of the engine. In such examples, a virtual sensor for each virtual object may include its own instance of the engine (e.g., an instance for a virtual camera, a second instance for a virtual LIDAR sensor, a third instance for another virtual LIDAR sensor, etc.). As such, an instance of the engine may be used for processing sensor data for each virtual sensor with respect to the virtual sensor's perception of the global simulation. As such, for a virtual camera, the instance may be used for processing image data with respect to the virtual camera's field of view in the simulated environment. As another example, for an virtual IMU sensor, the instance may be used for processing IMU data (e.g., representative of orientation) for the object in the simulated environment.

AI controlled agents (e.g., one or more independent ego agents discussed herein) or other objects within a simulation may include pedestrians, animals, third-party vehicles, vehicles, and/or other object types. The agents executed within the simulated environment may be controlled using artificial intelligence (e.g., machine learning such as neural networks, rules-based control, a combination thereof, etc.) in a way that simulates, or emulates, how corresponding real-world objects would behave. In some examples, the rules, or actions, for agents may be learned from one or more HIL objects, SIL objects, and/or PIL objects. In an example where an agent in the simulated environment corresponds to a pedestrian, the bot may be trained to act like a pedestrian in any of a number of different situations or environments (e.g., running, walking, jogging, not paying attention, on the phone, raining, snowing, in a city, in a suburban area, in a rural community, etc.). As such, when the simulated environment is used for testing vehicle performance (e.g., for HIL or SIL embodiments), the bot (e.g., the pedestrian) may behave as a real-world pedestrian would (e.g., by jaywalking in rainy or dark conditions, failing to heed stop signs or traffic lights, etc.), in order to more accurately simulate a real-world environment. This method may be used for any agent in the simulated environment, such as vehicles, bicyclists, or motorcycles, whose agents may also be trained to behave as real-world objects would (e.g., weaving in and out of traffic, swerving, changing lanes with no signal or suddenly, braking unexpectedly, etc.).

The AI objects that may be distant from the vehicle of interest (e.g., the ego-vehicle in the simulated environment) may be represented in a simplified form—such as a radial distance function, or list of points at known positions in a plane, with associated instantaneous motion vectors. As such, the AI objects may be modeled similarly to how AI agents may be modeled in videogame engines.

HIL vehicles or objects may use hardware that is used in the physical vehicles or objects to at least assist in some of the control of the HIL vehicles or objects in the simulated environment. For example, a vehicle controlled in a HIL environment may use one or more SoCs 1144 (FIG. 11C), CPU(s) 1118, GPU(s) 1120, etc., in a data flow loop for controlling the vehicle in the simulated environment. In some examples, the hardware from the vehicles may be an NVIDIA DRIVE AGX Pegasus™ compute platform and/or an NVIDIA DRIVE PX Xavier™ compute platform. For example, the vehicle hardware (e.g., vehicle hardware 1301) may include some or all of the components and/or functionality described in U.S. Non-Provisional application Ser. No. 16/186,473, filed on Nov. 13, 2018, which is hereby incorporated by reference in its entirety. In such examples, at least some of the control decisions may be generated using the hardware that is configured for installation within a real-world autonomous vehicle (e.g., the vehicle 1140) to execute at least a portion of a software stack(s) 1303 (e.g., an autonomous driving software stack).

SIL vehicles or objects may use software to simulate or emulate the hardware from the HIL vehicles or objects. For example, instead of using the actual hardware that may be configured for use in physical vehicles (e.g., the vehicle 1140), software, hardware, or a combination thereof may be used to simulate or emulate the actual hardware (e.g., simulate the SoC(s) 1144).

PIL vehicles or objects may use one or more hardware components that allow a remote operator (e.g., a human, a robot, etc.) to control the PIL vehicle or object within the simulated environment. For example, a person or robot may control the PIL vehicle using a remote control system (e.g., including one or more pedals, a steering wheel, a VR system, etc.), such as the remote control system described in U.S. Non-Provisional application Ser. No. 16/366,506, filed on Mar. 27, 20113, and hereby incorporated by reference in its entirety. In some examples, the remote operator may control autonomous driving level 0, 1, or 2 (e.g., according to the Society of Automotive Engineers document J3016) virtual vehicles using a VR headset and a CPU(s) (e.g., an X86 processor), a GPU(s), or a combination thereof. In other examples, the remote operator may control advanced AI-assisted level 2, 3, or 4 vehicles modeled using one or more advanced SoC platforms. In some examples, the PIL vehicles or objects may be recorded and/or tracked, and the recordings and/or tracking data may be used to train or otherwise at least partially contribute to the control of AI objects, such as those described herein.

Now referring to FIG. 13A, FIG. 13A is an example illustration of a simulation system 1300A, in accordance with some embodiments of the present disclosure. The simulation system 1300A may generate a simulated environment 1310 (e.g., a simulated driving environment as discussed herein) that may include agents such as AI objects 1312 (e.g., AI objects 1312A and 1312B), HIL objects 1314, SIL objects 1316, PIL objects 1318, and/or other object types. The simulated environment 1310 may include features of a driving environment, such as roads, bridges, tunnels, street signs, stop lights, crosswalks, buildings, trees and foliage, the sun, the moon, reflections, shadows, etc., in an effort to simulate a real-world environment accurately within the simulated environment 1310. In some examples, the features of the driving environment within the simulated environment 1310 may be more true-to-life by including chips, paint, graffiti, wear and tear, damage, etc. Although described with respect to a driving environment, this is not intended to be limiting, and the simulated environment may include an indoor environment (e.g., for a robot, a drone, etc.), an aerial environment (e.g., for a UAV, a drone, an airplane, etc.), an aquatic environment (e.g., for a boat, a ship, a submarine, etc.), and/or another environment type.

The simulated environment 1310 may be generated using virtual data, real-world data, or a combination thereof. For example, the simulated environment may include real-world data augmented or changed using virtual data to generate combined data that may be used to simulate certain scenarios or situations with different and/or added elements (e.g., additional AI objects, environmental features, weather conditions, etc.). For example, pre-recorded video may be augmented or changed to include additional pedestrians, obstacles, and/or the like, such that the virtual objects (e.g., executing the software stack(s) 1303 as HIL objects and/or SIL objects) may be tested against variations in the real-world data. In some embodiments, the simulated environment 1310 may comprise a terrain surface generated at least in part using terrain surface rendering data 128 and/or texture elevation mesh 126 generated by the terrain surface processor 106.

The simulated environment may be generated using rasterization, ray-tracing, using DNNs such as generative adversarial networks (GANs), another rendering technique, and/or a combination thereof. For example, in order to create more true-to-life, realistic lighting conditions (e.g., shadows, reflections, glare, global illumination, ambient occlusion, etc.), the simulation system 1300A may use real-time ray-tracing. In one or more embodiments, one or more hardware accelerators may be used by the simulation system 1300A to perform real-time ray-tracing. The ray-tracing may be used to simulate LIDAR sensor for accurate generation of LIDAR data. For example, ray casting may be used in an effort to simulate LIDAR reflectivity. In another example, virtual LIDAR data may be generated using a learned sensor model, as described in more detail above. In any example, ray-tracing techniques used by the simulation system 1300A may include one or more techniques described in U.S. Provisional Patent Application No. 62/644,385, filed Mar. 17, 2018, U.S. Provisional Patent Application No. 62/644,386, filed Mar. 17, 2018, U.S. Provisional Application No. 62/644,601, filed Mar. 13, 2018, and U.S. Provisional Application No. 62/644,806, filed Mar. 13, 2018, U.S. Non-Provisional patent application Ser. No. 16/354,1383, filed on Mar. 15, 2013, and/or U.S. Non-Provisional Ser. No. 16/355,214, filed on Mar. 15, 2013, each of which is hereby incorporated by reference in its entirety.

In some examples, a simulated environment as described herein (e.g., by simulated driving platform system 140) may be rendered, at least in part, using one or more DNNs, such as generative adversarial neural networks (GANs). For example, real-world data may be collected, such as real-world data captured by autonomous vehicles (e.g., camera(s), LIDAR sensor(s), RADAR sensor(s), etc.), robots, and/or other objects, as well as real-world data that may be captured by any sensors (e.g., images or video pulled from data stores, online resources such as search engines, etc.). The real-world data may then be segmented, classified, and/or categorized, such as by labeling differing portions of the real-world data based on class (e.g., for an image of a landscape, portions of the image - such as pixels or groups of pixels—may be labeled as car, sky, tree, road, building, water, waterfall, vehicle, bus, truck, sedan, etc.). A GAN (or other DNN or machine learning model) may then be trained using the segmented, classified, and/or categorized data to generate new versions of the different types of objects, landscapes, and/or other features as graphics within the simulated environment.

The simulator component(s) 1302 of the simulation system 1300 may communicate with vehicle simulator component(s) 1306 over a wired and/or wireless connection. In some examples, the connection may be a wired connection using one or more sensor switches 1308, where the sensor switches may provide low-voltage differential signaling (LVDS) output. For example, the sensor data (e.g., image data) may be transmitted over an HDMI to LVDS connection between the simulator component(s) 1302 and the vehicle simulator component(s) 1306. The simulator component(s) 1302 may include any number of compute nodes (e.g., computers, servers, etc.) interconnected in order to ensure synchronization of the world state. In some examples, as described herein, the communication between each of the compute nodes (e.g., the vehicle simulator component(s) compute nodes and the simulator component(s) compute nodes) may be managed by a distributed shared memory (DSM) system (e.g., DSM 1324 of FIG. 13C) using a distributed shared memory protocol (e.g., a coherence protocol). The DSM may include a combination of hardware (cache coherence circuits, network interfaces, etc.) and software. This shared memory architecture may separate memory into shared parts distributed among nodes and main memory, or distributing all memory between all nodes. In some examples, InfiniBand (IB) interfaces and associated communications standards may be used. For example, the communication between and among different nodes of the simulation system 1300 (and/or 1400) may use IB.

The simulator component(s) 1302 may include one or more GPUs 1304. The virtual vehicle being simulated may include any number of sensors (e.g., virtual or simulated sensors) that may correspond to one or more of the sensors described herein at least with respect to FIG. 15A-15C. Any or all of the sensors of the simulator component(s) 1302 may be implemented using a corresponding learned sensor model, as described in more detail above. In some examples, each sensor of the vehicle may correspond to, or be hosted by, one of the GPUs 1304. For example, processing for a LIDAR sensor may be executed on a first GPU 1304, processing for a wide-view camera may be executed on a second GPU 1304, processing for a RADAR sensor may be executed on a third GPU, and so on. As such, the processing of each sensor with respect to the simulated environment may be capable of executing in parallel with each other sensor using a plurality of GPUs 1304 to enable real-time simulation. In other examples, two or more sensors may correspond to, or be hosted by, one of the GPUs 1304. In such examples, the two or more sensors may be processed by separate threads on the GPU 1304 and may be processed in parallel. In other examples, the processing for a single sensor may be distributed across more than one GPU. In addition to, or alternatively from, the GPU(s) 1304, one or more TPUs, CPUs, and/or other processor types may be used for processing the sensor data.

Vehicle simulator component(s) 1306 may include a compute node of the simulation system 1300A that corresponds to a single vehicle represented in the simulated environment 1310. Each other vehicle (e.g., 1314, 1318, 1316, etc.) may include a respective node of the simulation system. As a result, the simulation system 1300A may be scalable to any number of vehicles or objects as each vehicle or object may be hosted by, or managed by, its own node in the system 1300A. In the illustration of FIG. 13A, the vehicle simulator component(s) 1306 may correspond to a HIL vehicle (e.g., because the vehicle hardware 1301 is used). However, this is not intended to be limiting and, as illustrated in FIGS. 13B and 13C, the simulation system 1300 may include SIL vehicles, HIL vehicles, PIL vehicles, and/or AI vehicles. The simulator component(s) 1302 (e.g., simulator host device) may include one or more compute nodes of the simulation system 1300A, and may host the simulation of the environment with respect to each actor (e.g., with respect to each HIL, SIL, PIL, and AI actors), as well as hosting the rendering and management of the environment or world state (e.g., the road, signs, trees, foliage, sky, sun, lighting, etc.). In some examples, the simulator component(s) 1302 may include a server(s) and associated components (e.g., CPU(s), GPU(s), computers, etc.) that may host a simulator (e.g., NVIDIA's DRIVE™ Constellation AV Simulator).

The vehicle hardware 1301, as described herein, may correspond to the vehicle hardware that may be used in a physical vehicle 1140. However, in the simulation system 1300A, the vehicle hardware 1301 may be incorporated into the vehicle simulator component(s) 1306. As such, because the vehicle hardware 1301 may be configured for installation within the vehicle 1140, the simulation system 1300A may be specifically configured to use the vehicle hardware 1301 within a node (e.g., of a server platform) of the simulation system 1300A. For example, similar interfaces used in the physical vehicle 1140 may need to be used by the vehicle simulator component(s) 1306 to communicate with the vehicle hardware 1301. In some examples, the interfaces may include: (1) CAN interfaces, including a PCAN adapter, (2) Ethernet interfaces, including RAW UDP sockets with IP address, origin, VLA, and/or source IP all preserved, (3) Serial interfaces, with a USB to serial adapter, (4) camera interfaces, (5) InfiniBand (IB) interfaces, and/or other interface types.

In examples, once the sensor data representative of a field(s) of view of the sensor(s) of the vehicle in the simulated environment has been generated and/or processed (e.g., using one or more codecs, as described herein), the sensor data (and/or encoded sensor data) may be used by the software stack(s) 1303 (e.g., the autonomous driving software stack) executed on the vehicle hardware 1301 to perform one or more operations (e.g., generate one or more controls, route planning, detecting objects, identifying drivable free-space, monitoring the environment for obstacle avoidance, etc.). As a result, the identical, or substantially identical, hardware components used by the vehicle 1140 (e.g., a physical vehicle) to execute the autonomous driving software stack in real-world environments may be used to execute the autonomous driving software stack in the simulated environment 1310. The use of the vehicle hardware 1301 in the simulation system 1300A thus provides for a more accurate simulation of how the vehicle 1140 will perform in real-world situations, scenarios, and environments without having to actually find and test the vehicle 1140 in the real-world. This may reduce the amount of driving time required for testing the hardware/software combination used in the physical vehicle 1140 and may reduce safety risks by not requiring actual real-world testing (especially for dangerous situations, such as other vehicles driving erratically or at unsafe speeds, children playing in the street, ice on a bridge, etc.).

In addition to the vehicle hardware 1301, the vehicle simulator component(s) 1306 may manage the simulation of the vehicle (or other object) using additional hardware, such as a computer—e.g., an X86 box. In some examples, additional processing for virtual sensors (e.g., learned sensor models) of the virtual object may be executed using the vehicle simulation component(s) 1306. In such examples, at least some of the processing may be performed by the simulator component(s) 1302, and other of the processing may be executed by the vehicle simulator component(s) 1306 (or 1320, or 1322, as described herein). In other examples, the processing of the virtual sensors may be executed entirely on the vehicle simulator component(s) 1306.

Now referring to FIG. 13B, FIG. 13B is another example illustration of a simulation system 1300B, in accordance with some embodiments of the present disclosure. The simulation system 1300B may include the simulator component(s) 1302 (as one or more compute nodes), the vehicle simulator component(s) 1306 (as one or more compute nodes) for a HIL object(s), the vehicle simulator component(s) 1320 (as one or more compute nodes) for a SIL object(s), the vehicle simulator component(s) 1306 (as one or more compute nodes) for a PIL object(s), and/or additional component(s) (or compute nodes) for AI objects and/or other object types. Each of the PIL, HIL, SIL, AI, and/or other object type compute nodes may communicate with the simulator component(s) 1302 to capture from the global simulation at least data that corresponds to the respective object within the simulate environment 1310.

For example, the vehicle simulator component(s) 1322 may receive (e.g., retrieve, obtain, etc.), from the global simulation (e.g., represented by the simulated environment 1310) hosted by the simulator component(s) 1302, data that corresponds to, is associated with, and/or is required by the vehicle simulator component(s) 1322 to perform one or more operations by the vehicle simulator component(s) 1322 for the PIL object. In such an example, data (e.g., virtual sensor data corresponding to a field(s) of view of virtual camera(s) of the virtual vehicle, virtual LIDAR data, virtual RADAR data, virtual location data, virtual IMU data, etc.) corresponding to each sensor of the PIL object may be received from the simulator component(s) 1302. This data may be used to generate an instance of the simulated environment corresponding to the field of view of a remote operator of the virtual vehicle controlled by the remote operator, and the portion of the simulated environment may be projected on a display (e.g., a display of a VR headset, a computer or television display, etc.) for assisting the remote operator in controlling the virtual vehicle through the simulated environment 1310. The controls generated or input by the remote operator using the vehicle simulator component(s) 1322 may be transmitted to the simulator component(s) 1302 for updating a state of the virtual vehicle within the simulated environment 1310.

As another example, the vehicle simulator component(s) 1320 may receive (e.g., retrieve, obtain, etc.), from the global simulation hosted by the simulator component(s) 1302, data that corresponds to, is associated with, and/or is required by the vehicle simulator component(s) 1320 to perform one or more operations by the vehicle simulator component(s) 1320 for the SIL object. In such an example, data (e.g., virtual sensor data corresponding to a field(s) of view of virtual camera(s) of the virtual vehicle, virtual LIDAR data, virtual RADAR data, virtual location data, virtual IMU data, etc.) corresponding to each sensor of the SIL object may be received from the simulator component(s) 1302. This data may be used to generate an instance of the simulated environment for each sensor (e.g., a first instance from a field of view of a first virtual camera of the virtual vehicle, a second instance from a field of view of a second virtual camera, a third instance from a field of view of a virtual LIDAR sensor, etc.). The instances of the simulated environment may thus be used to generate sensor data for each sensor by the vehicle simulator component(s) 1320. In some examples, the sensor data may be encoded using one or more codecs (e.g., each sensor may use its own codec, or each sensor type may use its own codec) in order to generate encoded sensor data that may be understood or familiar to an autonomous driving software stack simulated or emulated by the vehicle simulator component(s) 1320. For example, a first vehicle manufacturer may use a first type of LIDAR data, a second vehicle manufacturer may use a second type of LIDAR data, etc., and thus the codecs may customize the sensor data to the types of sensor data used by the manufacturers. As a result, the simulation system 1300 may be universal, customizable, and/or useable by any number of different sensor types depending on the types of sensors and the corresponding data types used by different manufacturers. In any example, the sensor data and/or encoded sensor data may be used by an autonomous driving software stack to perform one or more operations (e.g., object detection, path planning, control determinations, actuation types, etc.). For example, the sensor data and/or encoded data may be used as inputs to one or more DNNs of the autonomous driving software stack, and the outputs of the one or more DNNs may be used for updating a state of the virtual vehicle within the simulated environment 1310. As such, the reliability and efficacy of the autonomous driving software stack, including one or more DNNs, may be tested, fine-tuned, verified, and/or validated within the simulated environment.

In yet another example, the vehicle simulator component(s) 1306 may receive (e.g., retrieve, obtain, etc.), from the global simulation hosted by the simulator component(s) 1302, data that corresponds to, is associated with, and/or is required by the vehicle simulator component(s) 1306 to perform one or more operations by the vehicle simulator component(s) 1306 for the HIL object. In such an example, data (e.g., virtual sensor data corresponding to a field(s) of view of virtual camera(s) of the virtual vehicle, virtual LIDAR data, virtual RADAR data, virtual location data, virtual IMU data, etc.) corresponding to each sensor of the HIL object may be received from the simulator component(s) 1302. This data may be used to generate an instance of the simulated environment for each sensor (e.g., a first instance from a field of view of a first virtual camera of the virtual vehicle, a second instance from a field of view of a second virtual camera, a third instance from a field of view of a virtual LIDAR sensor, etc.). The instances of the simulated environment may thus be used to generate sensor data for each sensor by the vehicle simulator component(s) 1320 (e.g., using a corresponding learned sensor model). In some examples, the sensor data may be encoded using one or more codecs (e.g., each sensor may use its own codec, or each sensor type may use its own codec) in order to generate encoded sensor data that may be understood or familiar to an autonomous driving software stack executing on the vehicle hardware 1301 of the vehicle simulator component(s) 1320. Similar to the SIL object described herein, the sensor data and/or encoded sensor data may be used by an autonomous driving software stack to perform one or more operations (e.g., object detection, path planning, control determinations, actuation types, etc.).

Now referring to FIG. 13C, FIG. 13C is another example illustration of a simulation system 1300C, in accordance with some embodiments of the present disclosure. The simulation system 1300C may include distributed shared memory (DSM) system 1324, the simulator component(s) 1302 (as one or more compute nodes), the vehicle simulator component(s) 1306 (as one or more compute nodes) for a HIL object(s), the vehicle simulator component(s) 1320 (as one or more compute nodes) for a SIL object(s), the vehicle simulator component(s) 1306 (as one or more compute nodes) for a PIL object(s), and/or additional component(s) (or compute nodes) for AI objects and/or other object types (not shown). The simulation system 1300C may include any number of HIL objects (e.g., each including its own vehicle simulator component(s) 1306), any number of SIL objects (e.g., each including its own vehicle simulator component(s) 1320), any number of PIL objects (e.g., each including its own vehicle simulator component(s) 1322), and/or any number of AI objects (not shown, but may be hosted by the simulation component(s) 1302 and/or separate compute nodes, depending on the embodiment).

The vehicle simulator component(s) 1306 may include one or more SoC(s) 1305 (or other components) that may be configured for installation and use within a physical vehicle. As such, as described herein, the simulation system 1300C may be configured to use the SoC(s) 1305 and/or other vehicle hardware 1301 by using specific interfaces for communicating with the SoC(s) 1305 and/or other vehicle hardware. The vehicle simulator component(s) 1320 may include one or more software instances 1330 that may be hosted on one or more GPUs and/or CPUs to simulate or emulate the SoC(s) 1305. The vehicle simulator component(s) 1322 may include one or more SoC(s) 1326, one or more CPU(s) 1328 (e.g., X86 boxes), and/or a combination thereof, in addition to the component(s) that may be used by the remote operator (e.g., keyboard, mouse, joystick, monitors, VR systems, steering wheel, pedals, in-vehicle components, such as light switches, blinkers, HMI display(s), etc., and/or other component(s)).

The simulation component(s) 1302 may include any number of CPU(s) 1332 (e.g., X86 boxes), GPU(s), and/or a combination thereof. The CPU(s) 1332 may host the simulation software for maintaining the global simulation, and the GPU(s) 1334 may be used for rendering, physics, and/or other functionality for generating the simulated environment 1310.

As described herein, the simulation system 1300C may include the DSM 1324. The DSM 1324 may use one or more distributed shared memory protocols to maintain the state of the global simulation using the state of each of the objects (e.g., HIL objects, SIL objects, PIL objects, AI objects, etc.). As such, each of the compute nodes corresponding to the vehicle simulator component(s) 1306, 1320, and/or 1322 may be in communication with the simulation component(s) 1302 via the DSM 1324. By using the DSM 1324 and the associated protocols, real-time simulation may be possible. For example, as opposed to how network protocols (e.g., TCP, UDP, etc.) are used in massive multiplayer online (MMO) games, the simulation system 1300 may use a distributed shared memory protocol to maintain the state of the global simulation and each instance of the simulation (e.g., by each vehicle, object, and/or sensor) in real-time.

Now referring to FIG. 13D, FIG. 13D is an example illustration of a hardware-in-the-loop configuration, in accordance with some embodiments of the present disclosure. The vehicle simulator component(s) 1306 may include the vehicle hardware 1301, as described herein, and may include one or more computer(s) 1336, one or more GPU(s) (not shown), and/or one or more CPU(s) (not shown). The computer(s) 1336, GPU(s), and/or CPU(s) may manage or host the simulation software 1338, or instance thereof, executing on the vehicle simulator component(s) 1306. The vehicle hardware 1301 may execute the software stack(s) 1303 (e.g., an autonomous driving software stack, an IX software stack, etc.).

As described herein, by using the vehicle hardware 1301, the other vehicle simulator component(s) 1306 within the simulation environment 1300 may need to be configured for communication with the vehicle hardware 1301. For example, because the vehicle hardware 1301 may be configured for installation within a physical vehicle (e.g., the vehicle 1140), the vehicle hardware 1301 may be configured to communicate over one or more connection types and/or communication protocols that are not standard in computing environments (e.g., in server-based platforms, in general-purpose computers, etc.). For example, a CAN interface, LVDS interface, USB interface, Ethernet interface, InfiniBand (IB) interface, and/or other interfaces may be used by the vehicle hardware 1301 to communicate signals with other components of the physical vehicle. As such, in the simulation system 1300, the vehicle simulator component(s) 1306 (and/or other component(s) of the simulation system 1300 in addition to, or alternative from, the vehicle simulator component(s) 1306) may need to be configured for use with the vehicle hardware 1301. In order to accomplish this, one or more CAN interfaces, LVDS interfaces, USB interfaces, Ethernet interfaces, and/or other interface may be used to provide for communication (e.g., over one or more communication protocols, such as LVDS) between vehicle hardware 1301 and the other component(s) of the simulation system 1300.

In some examples, the virtual vehicle that may correspond to the vehicle simulator component(s) 1306 within the simulation system 1300 may be modeled as a game object within an instance of a game engine. In addition, each of the virtual sensors of the virtual vehicle may be interfaced using sockets within the virtual vehicle's software stack(s) 1303 executed on the vehicle hardware 1301. In some examples, each of the virtual sensors of the virtual vehicle may include an instance of the game engine, in addition to the instance of the game engine associated with the simulation software 1338 for the virtual vehicle. In examples where the vehicle simulator component(s) 1306 include a plurality of GPUs, each of the sensors may be executed on a single GPU. In other examples, multiple sensors may be executed on a single GPU, or at least as many sensors as feasible to ensure real-time generation of the virtual sensor data.

Using HIL objects in the simulator system 1300 may provide for a scalable solution that may simulate or emulate various driving conditions for autonomous software and hardware systems (e.g., NVIDIA's DRIVE AGX Pegasus™ compute platform and/or DRIVE PX Xavier™ compute platform). Some benefits of HIL objects may include the ability to test DNNs faster than real-time, the ability to scale verification with computing resources (e.g., rather than vehicles or test tracks), the ability to perform deterministic regression testing (e.g., the real-world environment is never the same twice, but a simulated environment can be), optimal ground truth labeling (e.g., no hand-labeling required), the ability to test scenarios difficult to produce in the real-world, rapid generation of test permutations, and the ability to test a larger space of permutations in simulation as compared to real-world.

Now referring to FIG. 13E, FIG. 13E is an example illustration of a hardware-in-the-loop configuration, in accordance with some embodiments of the present disclosure. The HIL configuration of FIG. 13E may include vehicle simulator component(s) 1306, including the SoC(s) 1305, a chassis fan(s) 1356 and/or water-cooling system. The HIL configuration may include a two-box solution (e.g., the simulator component(s) 1302 in a first box and the vehicle simulator component(s) 1306 in a second box). Using this approach may reduce the amount of space the system occupies as well as reduce the number of external cables in data centers (e.g., by including multiple components together with the SoC(s) 1305 in the vehicle simulator component(s) 1306—e.g., the first box). The vehicle simulator component(s) 1306 may include one or more GPUs 1352 (e.g., NVIDIA QUADRO GPU(s)) that may provide, in an example, non-limiting embodiment, 8 DP/HDMI video streams that may be synchronized using sync component(s) 1354 (e.g., through a QUADRO Sync II Card). These GPU(s) 1352 (and/or other GPU types) may provide the sensor input to the SoC(s) 1305 (e.g., to the vehicle hardware 1301). In some examples, the vehicle simulator component(s) 1306 may include a network interface (e.g., one or more network interface cards (NICs) 1350) that may simulate or emulate RADAR sensors, LIDAR sensors, and/or IMU sensors (e.g., by providing 8 Gigabit ports with precision time protocol (PTP) support). In addition, the vehicle simulator component(s) 1306 may include an input/output (I/O) analog integrated circuit 1357. Registered Jack (RJ) interfaces (e.g., RJ45), high speed data (HSD) interfaces, USB interfaces, pulse per second (PPS) clocks, Ethernet (e.g., 14 Gb Ethernet (GbE)) interfaces, CAN interfaces, HDMI interfaces, and/or other interface types may be used to effectively transmit and communication data between and among the various component(s) of the system.

Now referring to FIG. 13F, FIG. 13F is an example illustration of a software-in-the-loop configuration, in accordance with some embodiments of the present disclosure. The vehicle simulator component(s) 1320 may include computer(s) 1340, GPU(s) (not shown), CPU(s) (not shown), and/or other components. The computer(s) 1340, GPU(s), and/or CPU(s) may manage or host the simulation software 1338, or instance thereof, executing on the vehicle simulator component(s) 1320, and may host the software stack(s) 1303. For example, the vehicle simulator component(s) 1320 may simulate or emulate, using software, the vehicle hardware 1301 in an effort to execute the software stack(s) 1303 as accurately as possible.

In order to increase accuracy in SIL embodiments, the vehicle simulator component(s) 1320 may be configured to communicate over one or more virtual connection types and/or communication protocols that are not standard in computing environments. For example, a virtual CAN interface, virtual LVDS interface, virtual USB interface, virtual Ethernet interface, and/or other virtual interfaces may be used by the computer(s) 1340, CPU(s), and/or GPU(s) of the vehicle simulator component(s) 1320 to provide for communication (e.g., over one or more communication protocols, such as LVDS) between the software stack(s) 1303 and the simulation software 1338 within the simulation system 1300. For example, the virtual interfaces may include middleware that may be used to provide a continuous feedback loop with the software stack(s) 1303. As such, the virtual interfaces may simulate or emulate the communications between the vehicle hardware 1301 and the physical vehicle using one or more software protocols, hardware (e.g., CPU(s), GPU(s), computer(s) 1340, etc.), or a combination thereof.

The computer(s) 1340 in some examples, may include X86 CPU hardware, and one or more X86 CPUs may execute both the simulation software 1338 and the software stack(s) 1303. In other examples, the computer(s) 1340 may include GPU hardware (e.g., an NVIDIA DGX system and/or cloud-based NVIDIA Tesla servers).

In some examples, the virtual vehicle that may correspond to the vehicle simulator component(s) 1320 within the simulation system 1300 may be modeled as a game object within an instance of a game engine. In addition, each of the virtual sensors of the virtual vehicle may be interfaced using sockets within the virtual vehicle's software stack(s) 1303 executed on the vehicle simulator component(s) 1320. In some examples, each of the virtual sensors of the virtual vehicle may include an instance of the game engine, in addition to the instance of the game engine associated with the simulation software 1338 for the virtual vehicle. In examples where the vehicle simulator component(s) 1306 include a plurality of GPUs, each of the sensors may be executed on a single GPU. In other examples, multiple sensors may be executed on a single GPU, or at least as many sensors as feasible to ensure real-time generation of the virtual sensor data.

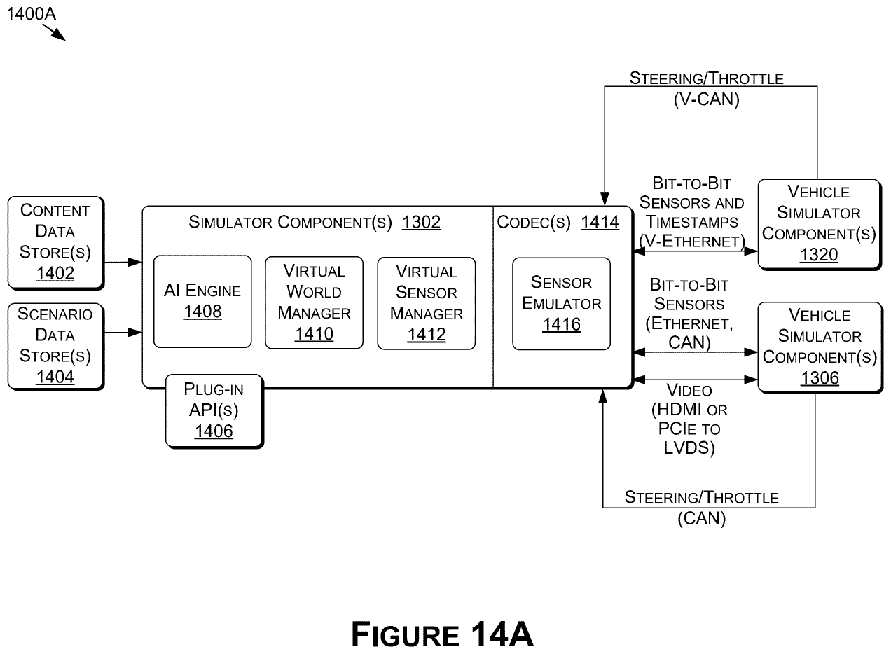

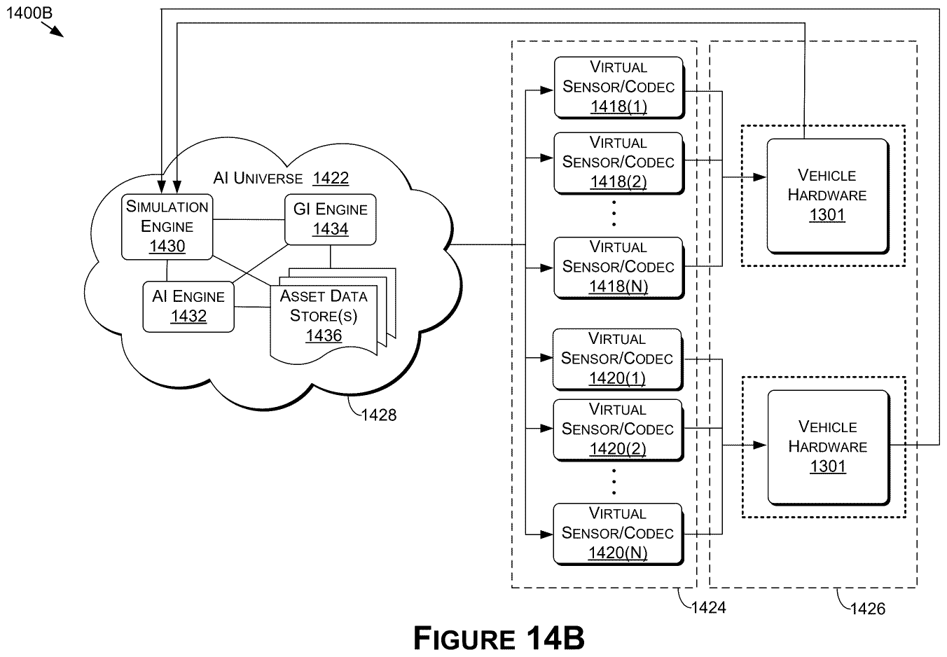

Now referring to FIG. 14A, FIG. 14A is an example illustration of a simulation system 1400 at runtime, in accordance with some embodiments of the present disclosure (e.g., simulated driving platform system 140). Some or all of the components of the simulation system 1400 may be used in the simulation system 1300, and some or all of the components of the simulation system 1300 may be used in the simulation system 1400. As such, components, features, and/or functionality described with respect to the simulation system 1300 may be associated with the simulation system 1400, and vice versa. In addition, each of the simulation systems 1400A and 1400B (FIG. 14B) may include similar and/or shared components, features, and/or functionality.

The simulation system 1400A (e.g., representing one example of simulation system 1400) may include the simulator component(s) 1302, codec(s) 1414, content data store(s) 1402, scenario data store(s) 1404, vehicle simulator component(s) 1320 (e.g., for a SIL object), and vehicle simulator component(s) 1306 (e.g., for a HIL object). The content data store(s) 1402 may include detailed content information for modeling cars, trucks, people, bicyclists, signs, buildings, trees, curbs, and/or other features of the simulated environment. The scenario data store(s) 1404 may include scenario information that may include dangerous scenario information (e.g., that is unsafe to test in the real-world environment), such as a child in an intersection.

The simulator component(s) 1302 may include an AI engine 1408 that simulates traffic, pedestrians, weather, and/or other AI features of the simulated environment. The simulator component(s) 1302 may include a virtual world manager 1410 that manages the world state for the global simulation. The simulator component(s) 1302 may further include a virtual sensor manger 1412 that may mange the virtual sensors (any or all of which may be implemented using a corresponding learned sensor model). The AI engine 1408 may model traffic similar to how traffic is modeled in an automotive video game, and may be done using a game engine, as described herein. In other examples, custom AI may be used to provide the determinism and computational level of detail necessary for large-scale reproducible automotive simulation. In some examples, traffic may be modeled using SIL objects, HIL objects, PIL objects, AI objects, and/or combination thereof. The system 1400 may create a subclass of an AI controller that examines map data, computes a route, and drives the route while avoiding other cars. The AI controller may compute desired steering, acceleration, and/or braking, and may apply those values to the virtual objects. The vehicle properties used may include mass, max RPM, torque curves, and/or other properties. A physics engine may be used to determine states of AI objects. As described herein, for vehicles or other objects that may be far away and may not have an impact on a current sensor(s), the system may choose not to apply physics for those objects and only determine locations and/or instantaneous motion vectors. Ray-casting may be used for each wheel to ensure that the wheels of the vehicles are in contact. In some examples, traffic AI may operate according to a script (e.g., rules-based traffic). Traffic AI maneuvers for virtual objects may include lateral lane changes (e.g., direction, distance, duration, shape, etc.), longitudinal movement (e.g., matching speed, relative target, delta to target, absolute value), route following, and/or path following. The triggers for the traffic AI maneuvers may be time-based (e.g., three seconds), velocity-based (e.g., at sixty mph), proximity-based to map (e.g., within twenty feet of intersection), proximity-based to actor (e.g., within twenty feet of another object), lane clear, and/or others.

The AI engine 1408 may model pedestrian AI similar to traffic AI, described herein, but for pedestrians. The pedestrians may be modeled similar to real pedestrians, and the system 1400 may infer pedestrian conduct based on learned behaviors.

The simulator component(s) 1302 may be used to adjust the time of day such that street lights turn on and off, headlights turn on and off, shadows, glares, and/or sunsets are considered, etc. In some examples, only lights within a threshold distance to the virtual object may be considered to increase efficiency.

Weather may be accounted for by the simulator component(s) 1302 (e.g., by the virtual world manager 1410). The weather may be used to update the coefficients of friction for the driving surfaces, and temperature information may be used to update tire interaction with the driving surfaces. Where rain or snow are present, the system 1400 may generate meshes to describe where rainwater and snow may accumulate based on the structure of the scene, and the meshes may be employed when rain or snow are present in the simulation.

In some examples, as described herein, at least some of the simulator component(s) 1302 may alternatively be included in the vehicle simulator component(s) 1320 and/or 1306. For example, the vehicle simulator component(s) 1320 and/or the vehicle simulator component(s) 1306 may include the virtual sensor manager 1412 for managing each of the sensors of the associated virtual object. In addition, one or more of the codecs 1414 may be included in the vehicle simulator component(s) 1320 and/or the vehicle simulator component(s) 1306. In such examples, the virtual sensor manager 1412 may generate sensor data corresponding to a sensor of the virtual object (e.g., using a learned sensor model), and the sensor data may be used by sensor emulator 1416 of the codec(s) 1414 to encode the sensor data according to the sensor data format or type used by the software stack(s) 1303 (e.g., the software stack(s) 1303 executing on the vehicle simulator component(s) 1320 and/or the vehicle simulator component(s) 1306).

The codec(s) 1414 may provide an interface to the software stack(s) 1303. The codec(s) 1414 (and/or other codec(s) described herein) may include an encoder/decoder framework. The codec(s) 1414 may include CAN steering, throttle requests, and/or may be used to send sensor data to the software stack(s) 1303 in SIL and HIL embodiments. The codec(s) 1414 may be beneficial to the simulation systems described herein (e.g., 1300 and 1400). For example, as data is produced by the simulated driving platform system 140 and the simulation systems 1300 and 1400, the data may be transmitted to the software stack(s) 1303 such that the following standards may be met. The data may be transferred to the software stack(s) 1303 such that minimal impact is introduced to the software stack(s) 1303 and/or the vehicle hardware 1301 (in HIL embodiments). This may result in more accurate simulations as the software stack(s) 1303 and/or the vehicle hardware 1301 may be operating in an environment that closely resembles deployment in a real-world environment. The data may be transmitted to the software stack(s) 1303 such that the simulator and/or re-simulator may be agnostic to the actual hardware configuration of the system under test. This may reduce development overhead due to bugs or separate code paths depending on the simulation configuration. The data may be transmitted to the software stack(s) 1303 such that the data may match (e.g., bit-to-bit) the data sent from a physical sensor of a physical vehicle (e.g., the vehicle 1140). The data may be transmitted to efficiently in both SIL and HIL embodiments.

The sensor emulator 1416 may emulate at least cameras, LIDAR sensors, and/or RADAR sensors, any or all of which may be implemented using a corresponding learned sensor model. Using a learned sensor model may obviate the need to model the sensor using ray-tracing, although in some embodiments, ray-tracing may additionally or alternatively be used. With respect to LIDAR sensors, some LIDAR sensors report tracked objects. As such, for each frame represented by the virtual sensor data, the simulator component(s) 1302 may create a list of all tracked objects (e.g., trees, vehicles, pedestrians, foliage, etc.) within range of the virtual object having the virtual LIDAR sensors, and may cast virtual rays toward the tracked objects. When a significant number of rays strike a tracked object, that object may be added to the report of the LIDAR data. In some examples, the LIDAR sensors may be modeled using simple ray-casting without reflection, adjustable field of view, adjustable noise, and/or adjustable drop-outs. LIDAR with moving parts, limited fields of view, and/or variable resolutions may be simulated. For example, the LIDAR sensors may be modeled as solid state LIDAR and/or as Optix-based LIDAR. In examples, using Optix-based LIDAR, the rays may bounce from water, reflective materials, and/or windows. Texture may be assigned to roads, signs, and/or vehicles to model laser reflection at the wavelengths corresponding to the textures. RADAR may be implemented similarly to LIDAR. As described herein, RADAR and/or LIDAR may be simulated using learned sensors, ray-tracing techniques, and/or otherwise.

In some examples, the vehicle simulator component(s) 1306, 1320, and/or 1322 may include a feedback loop with the simulator component(s) 1302 (and/or the component(s) that generate the virtual sensor data). The feedback loop may be used to provide information for updating the virtual sensor data capture or generation. For example, for virtual cameras, the feedback loop may be based on sensor feedback, such as changes to exposure responsive to lighting conditions (e.g., increase exposure in dim lighting conditions so that the image data may be processed by the DNNs properly). As another example, for virtual LIDAR sensors, the feedback loop may be representative of changes to energy level (e.g., to boost energy to produce more useable or accurate LIDAR data).

GNNS sensors (e.g., GPS sensors) may be simulated within the simulation space to generate real-world coordinates. In order to this, noise functions may be used to approximate inaccuracy. As with any virtual sensors described herein, the virtual sensor data may be generated using a learned sensor model or otherwise, and transmitted to the software stack(s) 1303 using the codec(s) 1414 to be converted to a bit-to-bit correct signal (e.g., corresponding accurately to the signals generated by the physical sensors of the physical vehicles).

One or more plugin application programming interfaces (APIs) 1406 may be used. The plugin APIs 1406 may include first-party and/or third-party plugins. For example, third parties may customize the simulation system 1400B using their own plugin APIs 1406 for providing custom information, such as performance timings, suspension dynamics, tire dynamics, etc.

The plugin APIs 1406 may include an ego-dynamics component(s) (not shown) that may receive information from the simulator component(s) 1302 including position, velocity, car state, and/or other information, and may provide information to the simulator component(s) 1302 including performance timings, suspension dynamics, tire dynamics, and/or other information. For examples, the simulator component(s) 1302 may provide CAN throttle, steering, and the driving surface information to the ego-dynamics component(s). In some examples, the ego-dynamics component(s) may include an off-the-shelf vehicle dynamics package (e.g., IPG CARMAKER or VIRTUAL TEST DRIVE), while in other examples the ego-dynamics component(s) may be customized and/or received (e.g., from a first-party and/or a third-party).

The plugin APIs 1406 may include a key performance indicator (KPI) API. The KPI API may receive CAN data, ground truth, and/or virtual object state information (e.g., from the software stack(s) 1303) from the simulator component(s) 1302 and may generate and/or provide a report (in real-time) that includes KPI's and/or commands to save state, restore state, and/or apply changes.

Now referring to FIG. 14B, FIG. 14B includes a cloud-based architecture for a simulation system 1400B, in accordance with some embodiment of the present disclosure. The simulation system 1400B may, at least partly, reside in the cloud and may communicate over one or more networks, such as but not limited to those described herein (e.g., with respect to network 11130 of FIG. 11D), with one or more GPU platforms 1424 (e.g., that may include GPUs, CPUs, TPUS, and/or other processor types) and/or one or more HIL platforms 1426 (e.g., which may include some or all of the components from the vehicle simulator component(s) 1306, described herein).

A simulated environment 1428 (e.g., which may be similar to the simulated environment 1310 described herein) may be modeled by interconnected components including a simulation engine 1430, an AI engine 1432, a global illumination (GI) engine 1434, an asset data store(s) 1436, and/or other components. In some examples, these component(s) may be used to model a simulated environment (e.g., a virtual world) in a virtualized interactive platform (e.g., similar to a massive multiplayer online (MMO) game environment. The simulated environment may further include physics, traffic simulation, weather simulation, and/or other features and simulations for the simulated environment. GI engine 1434 may calculate GI once and share the calculation with each of the virtual sensors/codecs 1418(1)-1418(N) and 1420(1)-1420(N) (e.g., the calculation of GI may be view independent). The simulated environment 1428 may include an AI universe 1422 that provides data to GPU platforms 1424 (e.g., GPU servers) that may create renderings for each sensor of the vehicle (e.g., at the virtual sensor/codec(s) 1418 for a first virtual object and at the virtual sensor codec(s) 1420 for a second virtual object). For example, the GPU platform 1424 may receive data about the simulated environment 1428 and may create sensor inputs for each of 1418(1)-1418(N), 1420(1)-1420(N), and/or virtual sensor/codec pairs corresponding to other virtual objects (depending on the embodiment). In examples where the virtual objects are simulated using HIL objects, the sensor inputs may be provided to the vehicle hardware 1301 which may use the software stack(s) 1303 to perform one or more operations and/or generate one or more commands, such as those described herein. In some examples, as described herein, the virtual sensor data from each of the virtual sensors may be encoded using a codec prior to being used by (or transmitted to) the software stack(s) 1303. In addition, in some examples, each of the sensors may be executed on its own GPU within the GPU platform 1424, while in other examples, two or more sensors may share the same GPU within the GPU platform 1424.

The one or more operations or commands may be transmitted to the simulation engine 1430 which may update the behavior of one or more of the virtual objects based on the operations and/or commands. For example, the simulation engine 1430 may use the AI engine 1432 to update the behavior of the AI agents as well as the virtual objects in the simulated environment 1428. The simulation engine 1430 may then update the object data and characteristics (e.g., within the asset data store(s) 1436), may update the GI (and/or other aspects such as reflections, shadows, etc.), and then may generate and provide updated sensor inputs to the GPU platform 1424. This process may repeat until a simulation is completed.

### Example Autonomous Vehicle

FIG. 15A is an illustration of an example autonomous vehicle 1500, in accordance with some embodiments of the present disclosure. The autonomous vehicle 1500 (alternatively referred to herein as the “vehicle 1500”) may include, without limitation, a passenger vehicle, such as a car, a truck, a bus, a first responder vehicle, a shuttle, an electric or motorized bicycle, a motorcycle, a fire truck, a police vehicle, an ambulance, a boat, a construction vehicle, an underwater craft, a robotic vehicle, a drone, an airplane, a vehicle coupled to a trailer (e.g., a semi-tractor-trailer truck used for hauling cargo), and/or another type of vehicle (e.g., that is unmanned and/or that accommodates one or more passengers). Autonomous vehicles are generally described in terms of automation levels, defined by the National Highway Traffic Safety Administration (NHTSA), a division of the US Department of Transportation, and the Society of Automotive Engineers (SAE) “Taxonomy and Definitions for Terms Related to Driving Automation Systems for On-Road Motor Vehicles” (Standard No. J3016-201806, published on Jun. 15, 2018, Standard No. J3016-201609, published on Sep. 30, 2016, and previous and future versions of this standard). The vehicle 1500 may be capable of functionality in accordance with one or more of Level 3-Level 5 of the autonomous driving levels. The vehicle 1500 may be capable of functionality in accordance with one or more of Level 1-Level 5 of the autonomous driving levels. For example, the vehicle 1500 may be capable of driver assistance (Level 1), partial automation (Level 2), conditional automation (Level 3), high automation (Level 4), and/or full automation (Level 5), depending on the embodiment. The term “autonomous,” as used herein, may include any and/or all types of autonomy for the vehicle 1500 or other machine, such as being fully autonomous, being highly autonomous, being conditionally autonomous, being partially autonomous, providing assistive autonomy, being semi-autonomous, being primarily autonomous, or other designation.

The vehicle 1500 may include components such as a chassis, a vehicle body, wheels (e.g., 2, 4, 6, 8, 18, etc.), tires, axles, and other components of a vehicle. The vehicle 1500 may include a propulsion system 1550, such as an internal combustion engine, hybrid electric power plant, an all-electric engine, and/or another propulsion system type. The propulsion system 1550 may be connected to a drive train of the vehicle 1500, which may include a transmission, to enable the propulsion of the vehicle 1500. The propulsion system 1550 may be controlled in response to receiving signals from the throttle/accelerator 1552.

A steering system 1554, which may include a steering wheel, may be used to steer the vehicle 1500 (e.g., along a desired path or route) when the propulsion system 1550 is operating (e.g., when the vehicle is in motion). The steering system 1554 may receive signals from a steering actuator 1556. The steering wheel may be optional for full automation (Level 5) functionality.

The brake sensor system 1546 may be used to operate the vehicle brakes in response to receiving signals from the brake actuators 1548 and/or brake sensors.

Controller(s) 1536, which may include one or more system on chips (SoCs) 1504 (FIG. 15C) and/or GPU(s), may provide signals (e.g., representative of commands) to one or more components and/or systems of the vehicle 1500. For example, the controller(s) may send signals to operate the vehicle brakes via one or more brake actuators 1548, to operate the steering system 1554 via one or more steering actuators 1556, to operate the propulsion system 1550 via one or more throttle/accelerators 1552. The controller(s) 1536 may include one or more onboard (e.g., integrated) computing devices (e.g., supercomputers) that process sensor signals, and output operation commands (e.g., signals representing commands) to enable autonomous driving and/or to assist a human driver in driving the vehicle 1500. The controller(s) 1536 may include a first controller 1536 for autonomous driving functions, a second controller 1536 for functional safety functions, a third controller 1536 for artificial intelligence functionality (e.g., computer vision), a fourth controller 1536 for infotainment functionality, a fifth controller 1536 for redundancy in emergency conditions, and/or other controllers. In some examples, a single controller 1536 may handle two or more of the above functionalities, two or more controllers 1536 may handle a single functionality, and/or any combination thereof.

The controller(s) 1536 may provide the signals for controlling one or more components and/or systems of the vehicle 1500 in response to sensor data received from one or more sensors (e.g., sensor inputs). The sensor data may be received from, for example and without limitation, global navigation satellite systems (“GNSS”) sensor(s) 1558 (e.g., Global Positioning System sensor(s)), RADAR sensor(s) 1560, ultrasonic sensor(s) 1562, LIDAR sensor(s) 1564, inertial measurement unit (IMU) sensor(s) 1566 (e.g., accelerometer(s), gyroscope(s), magnetic compass(es), magnetometer(s), etc.), microphone(s) 1596, stereo camera(s) 1568, wide-view camera(s) 1570 (e.g., fisheye cameras), infrared camera(s) 1572, surround camera(s) 1574 (e.g., 360 degree cameras), long-range and/or mid-range camera(s) 1598, speed sensor(s) 1544 (e.g., for measuring the speed of the vehicle 1500), vibration sensor(s) 1542, steering sensor(s) 1540, brake sensor(s) (e.g., as part of the brake sensor system 1546), and/or other sensor types.

One or more of the controller(s) 1536 may receive inputs (e.g., represented by input data) from an instrument cluster 1532 of the vehicle 1500 and provide outputs (e.g., represented by output data, display data, etc.) via a human-machine interface (HMI) display 1534, an audible annunciator, a loudspeaker, and/or via other components of the vehicle 1500. The outputs may include information such as vehicle velocity, speed, time, map data (e.g., the High Definition (“HD”) map 1522 of FIG. 15C), location data (e.g., the vehicle's 1500 location, such as on a map), direction, location of other vehicles (e.g., an occupancy grid), information about objects and status of objects as perceived by the controller(s) 1536, etc. For example, the HMI display 1534 may display information about the presence of one or more objects (e.g., a street sign, caution sign, traffic light changing, etc.), and/or information about driving maneuvers the vehicle has made, is making, or will make (e.g., changing lanes now, taking exit 34B in two miles, etc.).

The vehicle 1500 further includes a network interface 1524 which may use one or more wireless antenna(s) 1526 and/or modem(s) to communicate over one or more networks. For example, the network interface 1524 may be capable of communication over Long-Term Evolution (“LTE”), Wideband Code Division Multiple Access (“WCDMA”), Universal Mobile Telecommunications System (“UMTS”), Global System for Mobile communication (“GSM”), IMT-CDMA Multi-Carrier (“CDMA2000”), etc. The wireless antenna(s) 1526 may also enable communication between objects in the environment (e.g., vehicles, mobile devices, etc.), using local area network(s), such as Bluetooth, Bluetooth Low Energy (“LE”), Z-Wave, ZigBee, etc., and/or low power wide-area network(s) (“LPWANs”), such as LoRaWAN, SigFox, etc.

FIG. 15B is an example of camera locations and fields of view for the example autonomous vehicle 1500 of FIG. 15A, in accordance with some embodiments of the present disclosure. The cameras and respective fields of view are one example embodiment and are not intended to be limiting. For example, additional and/or alternative cameras may be included and/or the cameras may be located at different locations on the vehicle 1500.

The camera types for the cameras may include, but are not limited to, digital cameras that may be adapted for use with the components and/or systems of the vehicle 1500. The camera(s) may operate at automotive safety integrity level (ASIL) B and/or at another ASIL. The camera types may be capable of any image capture rate, such as 60 frames per second (fps), 120 fps, 240 fps, etc., depending on the embodiment. The cameras may be capable of using rolling shutters, global shutters, another type of shutter, or a combination thereof. In some examples, the color filter array may include a red clear clear clear (RCCC) color filter array, a red clear clear blue (RCCB) color filter array, a red blue green clear (RBGC) color filter array, a Foveon X3 color filter array, a Bayer sensors (RGGB) color filter array, a monochrome sensor color filter array, and/or another type of color filter array. In some embodiments, clear pixel cameras, such as cameras with an RCCC, an RCCB, and/or an RBGC color filter array, may be used in an effort to increase light sensitivity.

In some examples, one or more of the camera(s) may be used to perform advanced driver assistance systems (ADAS) functions (e.g., as part of a redundant or fail-safe design). For example, a Multi-Function Mono Camera may be installed to provide functions including lane departure warning, traffic sign assist and intelligent headlamp control. One or more of the camera(s) (e.g., all of the cameras) may record and provide image data (e.g., video) simultaneously.

One or more of the cameras may be mounted in a mounting assembly, such as a custom designed (three dimensional (“3D”) printed) assembly, in order to cut out stray light and reflections from within the car (e.g., reflections from the dashboard reflected in the windshield mirrors) which may interfere with the camera's image data capture abilities. With reference to wing-mirror mounting assemblies, the wing-mirror assemblies may be custom 3D printed so that the camera mounting plate matches the shape of the wing-mirror. In some examples, the camera(s) may be integrated into the wing-mirror. For side-view cameras, the camera(s) may also be integrated within the four pillars at each corner of the cabin.

Cameras with a field of view that include portions of the environment in front of the vehicle 1500 (e.g., front-facing cameras) may be used for surround view, to help identify forward facing paths and obstacles, as well aid in, with the help of one or more controllers 1536 and/or control SoCs, providing information critical to generating an occupancy grid and/or determining the preferred vehicle paths. Front-facing cameras may be used to perform many of the same ADAS functions as LIDAR, including emergency braking, pedestrian detection, and collision avoidance. Front-facing cameras may also be used for ADAS functions and systems including Lane Departure Warnings (“LDW”), Autonomous Cruise Control (“ACC”), and/or other functions such as traffic sign recognition.

A variety of cameras may be used in a front-facing configuration, including, for example, a monocular camera platform that includes a complementary metal oxide semiconductor (“CMOS”) color imager. Another example may be a wide-view camera(s) 1570 that may be used to perceive objects coming into view from the periphery (e.g., pedestrians, crossing traffic or bicycles). Although only one wide-view camera is illustrated in FIG. 15B, there may be any number (including zero) of wide-view cameras 1570 on the vehicle 1500. In addition, any number of long-range camera(s) 1598 (e.g., a long-view stereo camera pair) may be used for depth-based object detection, especially for objects for which a neural network has not yet been trained. The long-range camera(s) 1598 may also be used for object detection and classification, as well as basic object tracking.

Any number of stereo cameras 1568 may also be included in a front-facing configuration. In at least one embodiment, one or more of stereo camera(s) 1568 may include an integrated control unit comprising a scalable processing unit, which may provide a programmable logic (“FPGA”) and a multi-core micro-processor with an integrated Controller Area Network (“CAN”) or Ethernet interface on a single chip. Such a unit may be used to generate a 3D map of the vehicle's environment, including a distance estimate for all the points in the image. An alternative stereo camera(s) 1568 may include a compact stereo vision sensor(s) that may include two camera lenses (one each on the left and right) and an image processing chip that may measure the distance from the vehicle to the target object and use the generated information (e.g., metadata) to activate the autonomous emergency braking and lane departure warning functions. Other types of stereo camera(s) 1568 may be used in addition to, or alternatively from, those described herein.

Cameras with a field of view that include portions of the environment to the side of the vehicle 1500 (e.g., side-view cameras) may be used for surround view, providing information used to create and update the occupancy grid, as well as to generate side impact collision warnings. For example, surround camera(s) 1574 (e.g., four surround cameras 1574 as illustrated in FIG. 15B) may be positioned to on the vehicle 1500. The surround camera(s) 1574 may include wide-view camera(s) 1570, fisheye camera(s), 360 degree camera(s), and/or the like. Four example, four fisheye cameras may be positioned on the vehicle's front, rear, and sides. In an alternative arrangement, the vehicle may use three surround camera(s) 1574 (e.g., left, right, and rear), and may leverage one or more other camera(s) (e.g., a forward-facing camera) as a fourth surround view camera.

Cameras with a field of view that include portions of the environment to the rear of the vehicle 1500 (e.g., rear-view cameras) may be used for park assistance, surround view, rear collision warnings, and creating and updating the occupancy grid. A wide variety of cameras may be used including, but not limited to, cameras that are also suitable as a front-facing camera(s) (e.g., long-range and/or mid-range camera(s) 1598, stereo camera(s) 1568), infrared camera(s) 1572, etc.), as described herein.

FIG. 15C is a block diagram of an example system architecture for the example autonomous vehicle 1500 of FIG. 15A, in accordance with some embodiments of the present disclosure. It should be understood that this and other arrangements described herein are set forth only as examples. Other arrangements and elements (e.g., machines, interfaces, functions, orders, groupings of functions, etc.) may be used in addition to or instead of those shown, and some elements may be omitted altogether. Further, many of the elements described herein are functional entities that may be implemented as discrete or distributed components or in conjunction with other components, and in any suitable combination and location. Various functions described herein as being performed by entities may be carried out by hardware, firmware, and/or software. For instance, various functions may be carried out by a processor executing instructions stored in memory.

Each of the components, features, and systems of the vehicle 1500 in FIG. 15C are illustrated as being connected via bus 1502. The bus 1502 may include a Controller Area Network (CAN) data interface (alternatively referred to herein as a “CAN bus”). A CAN may be a network inside the vehicle 1500 used to aid in control of various features and functionality of the vehicle 1500, such as actuation of brakes, acceleration, braking, steering, windshield wipers, etc. A CAN bus may be configured to have dozens or even hundreds of nodes, each with its own unique identifier (e.g., a CAN ID). The CAN bus may be read to find steering wheel angle, ground speed, engine revolutions per minute (RPMs), button positions, and/or other vehicle status indicators. The CAN bus may be ASIL B compliant.

Although the bus 1502 is described herein as being a CAN bus, this is not intended to be limiting. For example, in addition to, or alternatively from, the CAN bus, FlexRay and/or Ethernet may be used. Additionally, although a single line is used to represent the bus 1502, this is not intended to be limiting. For example, there may be any number of busses 1502, which may include one or more CAN busses, one or more FlexRay busses, one or more Ethernet busses, and/or one or more other types of busses using a different protocol. In some examples, two or more busses 1502 may be used to perform different functions, and/or may be used for redundancy. For example, a first bus 1502 may be used for collision avoidance functionality and a second bus 1502 may be used for actuation control. In any example, each bus 1502 may communicate with any of the components of the vehicle 1500, and two or more busses 1502 may communicate with the same components. In some examples, each SoC 1504, each controller 1536, and/or each computer within the vehicle may have access to the same input data (e.g., inputs from sensors of the vehicle 1500), and may be connected to a common bus, such the CAN bus.

The vehicle 1500 may include one or more controller(s) 1536, such as those described herein with respect to FIG. 15A. The controller(s) 1536 may be used for a variety of functions. The controller(s) 1536 may be coupled to any of the various other components and systems of the vehicle 1500, and may be used for control of the vehicle 1500, artificial intelligence of the vehicle 1500, infotainment for the vehicle 1500, and/or the like.

The vehicle 1500 may include a system(s) on a chip (SoC) 1504. The SoC 1504 may include CPU(s) 1506, GPU(s) 1508, processor(s) 1510, cache(s) 1512, accelerator(s) 1514, data store(s) 1516, and/or other components and features not illustrated. The SoC(s) 1504 may be used to control the vehicle 1500 in a variety of platforms and systems. For example, the SoC(s) 1504 may be combined in a system (e.g., the system of the vehicle 1500) with an HD map 1522 which may obtain map refreshes and/or updates via a network interface 1524 from one or more servers (e.g., server(s) 1578 of FIG. 15D).

The CPU(s) 1506 may include a CPU cluster or CPU complex (alternatively referred to herein as a “CCPLEX”). The CPU(s) 1506 may include multiple cores and/or L2 caches. For example, in some embodiments, the CPU(s) 1506 may include eight cores in a coherent multi-processor configuration. In some embodiments, the CPU(s) 1506 may include four dual-core clusters where each cluster has a dedicated L2 cache (e.g., a 2 MB L2 cache). The CPU(s) 1506 (e.g., the CCPLEX) may be configured to support simultaneous cluster operation enabling any combination of the clusters of the CPU(s) 1506 to be active at any given time.

The CPU(s) 1506 may implement power management capabilities that include one or more of the following features: individual hardware blocks may be clock-gated automatically when idle to save dynamic power; each core clock may be gated when the core is not actively executing instructions due to execution of WFI/WFE instructions; each core may be independently power-gated; each core cluster may be independently clock-gated when all cores are clock-gated or power-gated; and/or each core cluster may be independently power-gated when all cores are power-gated. The CPU(s) 1506 may further implement an enhanced algorithm for managing power states, where allowed power states and expected wakeup times are specified, and the hardware/microcode determines the best power state to enter for the core, cluster, and CCPLEX. The processing cores may support simplified power state entry sequences in software with the work offloaded to microcode.

The GPU(s) 1508 may include an integrated GPU (alternatively referred to herein as an “iGPU”). The GPU(s) 1508 may be programmable and may be efficient for parallel workloads. The GPU(s) 1508, in some examples, may use an enhanced tensor instruction set. The GPU(s) 1508 may include one or more streaming microprocessors, where each streaming microprocessor may include an L1 cache (e.g., an L1 cache with at least 96 KB storage capacity), and two or more of the streaming microprocessors may share an L2 cache (e.g., an L2 cache with a 512 KB storage capacity). In some embodiments, the GPU(s) 1508 may include at least eight streaming microprocessors. The GPU(s) 1508 may use compute application programming interface(s) (API(s)). In addition, the GPU(s) 1508 may use one or more parallel computing platforms and/or programming models (e.g., NVIDIA's CUDA).

The GPU(s) 1508 may be power-optimized for best performance in automotive and embedded use cases. For example, the GPU(s) 1508 may be fabricated on a Fin field-effect transistor (FinFET). However, this is not intended to be limiting and the GPU(s) 1508 may be fabricated using other semiconductor manufacturing processes. Each streaming microprocessor may incorporate a number of mixed-precision processing cores partitioned into multiple blocks. For example, and without limitation, 64 PF32 cores and 32 PF 64 cores may be partitioned into four processing blocks. In such an example, each processing block may be allocated 16 FP32 cores, 8 FP64 cores, 16 INT32 cores, two mixed-precision NVIDIA TENSOR COREs for deep learning matrix arithmetic, an L0 instruction cache, a warp scheduler, a dispatch unit, and/or a 64 KB register file. In addition, the streaming microprocessors may include independent parallel integer and floating-point data paths to provide for efficient execution of workloads with a mix of computation and addressing calculations. The streaming microprocessors may include independent thread scheduling capability to enable finer-grain synchronization and cooperation between parallel threads. The streaming microprocessors may include a combined L1 data cache and shared memory unit in order to improve performance while simplifying programming.

The GPU(s) 1508 may include a high bandwidth memory (HBM) and/or a 16 GB HBM2 memory subsystem to provide, in some examples, about 900 GB/second peak memory bandwidth. In some examples, in addition to, or alternatively from, the HBM memory, a synchronous graphics random-access memory (SGRAM) may be used, such as a graphics double data rate type five synchronous random-access memory (GDDR5).

The GPU(s) 1508 may include unified memory technology including access counters to allow for more accurate migration of memory pages to the processor that accesses them most frequently, thereby improving efficiency for memory ranges shared between processors. In some examples, address translation services (ATS) support may be used to allow the GPU(s) 1508 to access the CPU(s) 1506 page tables directly. In such examples, when the GPU(s) 1508 memory management unit (MMU) experiences a miss, an address translation request may be transmitted to the CPU(s) 1506. In response, the CPU(s) 1506 may look in its page tables for the virtual-to-physical mapping for the address and transmits the translation back to the GPU(s) 1508. As such, unified memory technology may allow a single unified virtual address space for memory of both the CPU(s) 1506 and the GPU(s) 1508, thereby simplifying the GPU(s) 1508 programming and porting of applications to the GPU(s) 1508.

In addition, the GPU(s) 1508 may include an access counter that may keep track of the frequency of access of the GPU(s) 1508 to memory of other processors. The access counter may help ensure that memory pages are moved to the physical memory of the processor that is accessing the pages most frequently.

The SoC(s) 1504 may include any number of cache(s) 1512, including those described herein. For example, the cache(s) 1512 may include an L3 cache that is available to both the CPU(s) 1506 and the GPU(s) 1508 (e.g., that is connected both the CPU(s) 1506 and the GPU(s) 1508). The cache(s) 1512 may include a write-back cache that may keep track of states of lines, such as by using a cache coherence protocol (e.g., MEI, MESI, MSI, etc.). The L3 cache may include 4 MB or more, depending on the embodiment, although smaller cache sizes may be used.

The SoC(s) 1504 may include an arithmetic logic unit(s) (ALU(s)) which may be leveraged in performing processing with respect to any of the variety of tasks or operations of the vehicle 1500—such as processing DNNs. In addition, the SoC(s) 1504 may include a floating point unit(s) (FPU(s))—or other math coprocessor or numeric coprocessor types—for performing mathematical operations within the system. For example, the SoC(s) 1504 may include one or more FPUs integrated as execution units within a CPU(s) 1506 and/or GPU(s) 1508.

The SoC(s) 1504 may include one or more accelerators 1514 (e.g., hardware accelerators, software accelerators, or a combination thereof). For example, the SoC(s) 1504 may include a hardware acceleration cluster that may include optimized hardware accelerators and/or large on-chip memory. The large on-chip memory (e.g., 4 MB of SRAM), may enable the hardware acceleration cluster to accelerate neural networks and other calculations. The hardware acceleration cluster may be used to complement the GPU(s) 1508 and to off-load some of the tasks of the GPU(s) 1508 (e.g., to free up more cycles of the GPU(s) 1508 for performing other tasks). As an example, the accelerator(s) 1514 may be used for targeted workloads (e.g., perception, convolutional neural networks (CNNs), etc.) that are stable enough to be amenable to acceleration. The term “CNN,” as used herein, may include all types of CNNs, including region-based or regional convolutional neural networks (RCNNs) and Fast RCNNs (e.g., as used for object detection).

The accelerator(s) 1514 (e.g., the hardware acceleration cluster) may include a deep learning accelerator(s) (DLA). The DLA(s) may include one or more Tensor processing units (TPUs) that may be configured to provide an additional ten trillion operations per second for deep learning applications and inferencing. The TPUs may be accelerators configured to, and optimized for, performing image processing functions (e.g., for CNNs, RCNNs, etc.). The DLA(s) may further be optimized for a specific set of neural network types and floating point operations, as well as inferencing. The design of the DLA(s) may provide more performance per millimeter than a general-purpose GPU, and vastly exceeds the performance of a CPU. The TPU(s) may perform several functions, including a single-instance convolution function, supporting, for example, INT8, INT16, and FP16 data types for both features and weights, as well as post-processor functions.

The DLA(s) may quickly and efficiently execute neural networks, especially CNNs, on processed or unprocessed data for any of a variety of functions, including, for example and without limitation: a CNN for object identification and detection using data from camera sensors; a CNN for distance estimation using data from camera sensors; a CNN for emergency vehicle detection and identification and detection using data from microphones; a CNN for facial recognition and vehicle owner identification using data from camera sensors; and/or a CNN for security and/or safety related events.

The DLA(s) may perform any function of the GPU(s) 1508, and by using an inference accelerator, for example, a designer may target either the DLA(s) or the GPU(s) 1508 for any function. For example, the designer may focus processing of CNNs and floating point operations on the DLA(s) and leave other functions to the GPU(s) 1508 and/or other accelerator(s) 1514.

The accelerator(s) 1514 (e.g., the hardware acceleration cluster) may include a programmable vision accelerator(s) (PVA), which may alternatively be referred to herein as a computer vision accelerator. The PVA(s) may be designed and configured to accelerate computer vision algorithms for the advanced driver assistance systems (ADAS), autonomous driving, and/or augmented reality (AR) and/or virtual reality (VR) applications. The PVA(s) may provide a balance between performance and flexibility. For example, each PVA(s) may include, for example and without limitation, any number of reduced instruction set computer (RISC) cores, direct memory access (DMA), and/or any number of vector processors.

The RISC cores may interact with image sensors (e.g., the image sensors of any of the cameras described herein), image signal processor(s), and/or the like. Each of the RISC cores may include any amount of memory. The RISC cores may use any of a number of protocols, depending on the embodiment. In some examples, the RISC cores may execute a real-time operating system (RTOS). The RISC cores may be implemented using one or more integrated circuit devices, application specific integrated circuits (ASICs), and/or memory devices. For example, the RISC cores may include an instruction cache and/or a tightly coupled RAM.

The DMA may enable components of the PVA(s) to access the system memory independently of the CPU(s) 1506. The DMA may support any number of features used to provide optimization to the PVA including, but not limited to, supporting multi-dimensional addressing and/or circular addressing. In some examples, the DMA may support up to six or more dimensions of addressing, which may include block width, block height, block depth, horizontal block stepping, vertical block stepping, and/or depth stepping.

The vector processors may be programmable processors that may be designed to efficiently and flexibly execute programming for computer vision algorithms and provide signal processing capabilities. In some examples, the PVA may include a PVA core and two vector processing subsystem partitions. The PVA core may include a processor subsystem, DMA engine(s) (e.g., two DMA engines), and/or other peripherals. The vector processing subsystem may operate as the primary processing engine of the PVA, and may include a vector processing unit (VPU), an instruction cache, and/or vector memory (e.g., VMEM). A VPU core may include a digital signal processor such as, for example, a single instruction, multiple data (SIMD), very long instruction word (VLIW) digital signal processor. The combination of the SIMD and VLIW may enhance throughput and speed.

Each of the vector processors may include an instruction cache and may be coupled to dedicated memory. As a result, in some examples, each of the vector processors may be configured to execute independently of the other vector processors. In other examples, the vector processors that are included in a particular PVA may be configured to employ data parallelism. For example, in some embodiments, the plurality of vector processors included in a single PVA may execute the same computer vision algorithm, but on different regions of an image. In other examples, the vector processors included in a particular PVA may simultaneously execute different computer vision algorithms, on the same image, or even execute different algorithms on sequential images or portions of an image. Among other things, any number of PVAs may be included in the hardware acceleration cluster and any number of vector processors may be included in each of the PVAs. In addition, the PVA(s) may include additional error correcting code (ECC) memory, to enhance overall system safety.

The accelerator(s) 1514 (e.g., the hardware acceleration cluster) may include a computer vision network on-chip and SRAM, for providing a high-bandwidth, low latency SRAM for the accelerator(s) 1514. In some examples, the on-chip memory may include at least 4 MB SRAM, consisting of, for example and without limitation, eight field-configurable memory blocks, that may be accessible by both the PVA and the DLA. Each pair of memory blocks may include an advanced peripheral bus (APB) interface, configuration circuitry, a controller, and a multiplexer. Any type of memory may be used. The PVA and DLA may access the memory via a backbone that provides the PVA and DLA with high-speed access to memory. The backbone may include a computer vision network on-chip that interconnects the PVA and the DLA to the memory (e.g., using the APB).

The computer vision network on-chip may include an interface that determines, before transmission of any control signal/address/data, that both the PVA and the DLA provide ready and valid signals. Such an interface may provide for separate phases and separate channels for transmitting control signals/addresses/data, as well as burst-type communications for continuous data transfer. This type of interface may comply with ISO 26262 or IEC 61508 standards, although other standards and protocols may be used.

In some examples, the SoC(s) 1504 may include a real-time ray-tracing hardware accelerator, such as described in U.S. patent application Ser. No. 16/101,232, filed on Aug. 10, 2018. The real-time ray-tracing hardware accelerator may be used to quickly and efficiently determine the positions and extents of objects (e.g., within a world model), to generate real-time visualization simulations, for RADAR signal interpretation, for sound propagation synthesis and/or analysis, for simulation of SONAR systems, for general wave propagation simulation, for comparison to LIDAR data for purposes of localization and/or other functions, and/or for other uses. In some embodiments, one or more tree traversal units (TTUs) may be used for executing one or more ray-tracing related operations.

The accelerator(s) 1514 (e.g., the hardware accelerator cluster) have a wide array of uses for autonomous driving. The PVA may be a programmable vision accelerator that may be used for key processing stages in ADAS and autonomous vehicles. The PVA's capabilities are a good match for algorithmic domains needing predictable processing, at low power and low latency. In other words, the PVA performs well on semi-dense or dense regular computation, even on small data sets, which need predictable run-times with low latency and low power. Thus, in the context of platforms for autonomous vehicles, the PVAs are designed to run classic computer vision algorithms, as they are efficient at object detection and operating on integer math.

For example, according to one embodiment of the technology, the PVA is used to perform computer stereo vision. A semi-global matching-based algorithm may be used in some examples, although this is not intended to be limiting. Many applications for Level 3-5 autonomous driving require motion estimation/stereo matching on-the-fly (e.g., structure from motion, pedestrian recognition, lane detection, etc.). The PVA may perform computer stereo vision function on inputs from two monocular cameras.

In some examples, the PVA may be used to perform dense optical flow. According to process raw RADAR data (e.g., using a 4D Fast Fourier Transform) to provide Processed RADAR. In other examples, the PVA is used for time of flight depth processing, by processing raw time of flight data to provide processed time of flight data, for example.

The DLA may be used to run any type of network to enhance control and driving safety, including for example, a neural network that outputs a measure of confidence for each object detection. Such a confidence value may be interpreted as a probability, or as providing a relative “weight” of each detection compared to other detections. This confidence value enables the system to make further decisions regarding which detections should be considered as true positive detections rather than false positive detections. For example, the system may set a threshold value for the confidence and consider only the detections exceeding the threshold value as true positive detections. In an automatic emergency braking (AEB) system, false positive detections would cause the vehicle to automatically perform emergency braking, which is obviously undesirable. Therefore, only the most confident detections should be considered as triggers for AEB. The DLA may run a neural network for regressing the confidence value. The neural network may take as its input at least some subset of parameters, such as bounding box dimensions, ground plane estimate obtained (e.g. from another subsystem), inertial measurement unit (IMU) sensor 1566 output that correlates with the vehicle 1500 orientation, distance, 3D location estimates of the object obtained from the neural network and/or other sensors (e.g., LIDAR sensor(s) 1564 or RADAR sensor(s) 1560), among others.

The SoC(s) 1504 may include data store(s) 1516 (e.g., memory). The data store(s) 1516 may be on-chip memory of the SoC(s) 1504, which may store neural networks to be executed on the GPU and/or the DLA. In some examples, the data store(s) 1516 may be large enough in capacity to store multiple instances of neural networks for redundancy and safety. The data store(s) 1512 may comprise L2 or L3 cache(s) 1512. Reference to the data store(s) 1516 may include reference to the memory associated with the PVA, DLA, and/or other accelerator(s) 1514, as described herein.

The SoC(s) 1504 may include one or more processor(s) 1510 (e.g., embedded processors). The processor(s) 1510 may include a boot and power management processor that may be a dedicated processor and subsystem to handle boot power and management functions and related security enforcement. The boot and power management processor may be a part of the SoC(s) 1504 boot sequence and may provide runtime power management services. The boot power and management processor may provide clock and voltage programming, assistance in system low power state transitions, management of SoC(s) 1504 thermals and temperature sensors, and/or management of the SoC(s) 1504 power states. Each temperature sensor may be implemented as a ring-oscillator whose output frequency is proportional to temperature, and the SoC(s) 1504 may use the ring-oscillators to detect temperatures of the CPU(s) 1506, GPU(s) 1508, and/or accelerator(s) 1514. If temperatures are determined to exceed a threshold, the boot and power management processor may enter a temperature fault routine and put the SoC(s) 1504 into a lower power state and/or put the vehicle 1500 into a chauffeur to safe stop mode (e.g., bring the vehicle 1500 to a safe stop).

The processor(s) 1510 may further include a set of embedded processors that may serve as an audio processing engine. The audio processing engine may be an audio subsystem that enables full hardware support for multi-channel audio over multiple interfaces, and a broad and flexible range of audio I/O interfaces. In some examples, the audio processing engine is a dedicated processor core with a digital signal processor with dedicated RAM.

The processor(s) 1510 may further include an always on processor engine that may provide necessary hardware features to support low power sensor management and wake use cases. The always on processor engine may include a processor core, a tightly coupled RAM, supporting peripherals (e.g., timers and interrupt controllers), various I/O controller peripherals, and routing logic.

The processor(s) 1510 may further include a safety cluster engine that includes a dedicated processor subsystem to handle safety management for automotive applications. The safety cluster engine may include two or more processor cores, a tightly coupled RAM, support peripherals (e.g., timers, an interrupt controller, etc.), and/or routing logic. In a safety mode, the two or more cores may operate in a lockstep mode and function as a single core with comparison logic to detect any differences between their operations.

The processor(s) 1510 may further include a real-time camera engine that may include a dedicated processor subsystem for handling real-time camera management.

The processor(s) 1510 may further include a high-dynamic range signal processor that may include an image signal processor that is a hardware engine that is part of the camera processing pipeline.

The processor(s) 1510 may include a video image compositor that may be a processing block (e.g., implemented on a microprocessor) that implements video post-processing functions needed by a video playback application to produce the final image for the player window. The video image compositor may perform lens distortion correction on wide-view camera(s) 1570, surround camera(s) 1574, and/or on in-cabin monitoring camera sensors. In-cabin monitoring camera sensor is preferably monitored by a neural network running on another instance of the Advanced SoC, configured to identify in cabin events and respond accordingly. An in-cabin system may perform lip reading to activate cellular service and place a phone call, dictate emails, change the vehicle's destination, activate or change the vehicle's infotainment system and settings, or provide voice-activated web surfing. Certain functions are available to the driver only when the vehicle is operating in an autonomous mode, and are disabled otherwise.

The video image compositor may include enhanced temporal noise reduction for both spatial and temporal noise reduction. For example, where motion occurs in a video, the noise reduction weights spatial information appropriately, decreasing the weight of information provided by adjacent frames. Where an image or portion of an image does not include motion, the temporal noise reduction performed by the video image compositor may use information from the previous image to reduce noise in the current image.

The video image compositor may also be configured to perform stereo rectification on input stereo lens frames. The video image compositor may further be used for user interface composition when the operating system desktop is in use, and the GPU(s) 1508 is not required to continuously render new surfaces. Even when the GPU(s) 1508 is powered on and active doing 3D rendering, the video image compositor may be used to offload the GPU(s) 1508 to improve performance and responsiveness.

The SoC(s) 1504 may further include a mobile industry processor interface (MIPI) camera serial interface for receiving video and input from cameras, a high-speed interface, and/or a video input block that may be used for camera and related pixel input functions. The SoC(s) 1504 may further include an input/output controller(s) that may be controlled by software and may be used for receiving I/O signals that are uncommitted to a specific role.

The SoC(s) 1504 may further include a broad range of peripheral interfaces to enable communication with peripherals, audio codecs, power management, and/or other devices. The SoC(s) 1504 may be used to process data from cameras (e.g., connected over Gigabit Multimedia Serial Link and Ethernet), sensors (e.g., LIDAR sensor(s) 1564, RADAR sensor(s) 1560, etc. that may be connected over Ethernet), data from bus 1502 (e.g., speed of vehicle 1500, steering wheel position, etc.), data from GNSS sensor(s) 1558 (e.g., connected over Ethernet or CAN bus). The SoC(s) 1504 may further include dedicated high-performance mass storage controllers that may include their own DMA engines, and that may be used to free the CPU(s) 1506 from routine data management tasks.

The SoC(s) 1504 may be an end-to-end platform with a flexible architecture that spans automation levels 3-5, thereby providing a comprehensive functional safety architecture that leverages and makes efficient use of computer vision and ADAS techniques for diversity and redundancy, provides a platform for a flexible, reliable driving software stack, along with deep learning tools. The SoC(s) 1504 may be faster, more reliable, and even more energy-efficient and space-efficient than conventional systems. For example, the accelerator(s) 1514, when combined with the CPU(s) 1506, the GPU(s) 1508, and the data store(s) 1516, may provide for a fast, efficient platform for level 3-5 autonomous vehicles.

The technology thus provides capabilities and functionality that cannot be achieved by conventional systems. For example, computer vision algorithms may be executed on CPUs, which may be configured using high-level programming language, such as the C programming language, to execute a wide variety of processing algorithms across a wide variety of visual data. However, CPUs are oftentimes unable to meet the performance requirements of many computer vision applications, such as those related to execution time and power consumption, for example. In particular, many CPUs are unable to execute complex object detection algorithms in real-time, which is a requirement of in-vehicle ADAS applications, and a requirement for practical Level 3-5 autonomous vehicles.

In contrast to conventional systems, by providing a CPU complex, GPU complex, and a hardware acceleration cluster, the technology described herein allows for multiple neural networks to be performed simultaneously and/or sequentially, and for the results to be combined together to enable Level 3-5 autonomous driving functionality. For example, a CNN executing on the DLA or dGPU (e.g., the GPU(s) 1520) may include a text and word recognition, allowing the supercomputer to read and understand traffic signs, including signs for which the neural network has not been specifically trained. The DLA may further include a neural network that is able to identify, interpret, and provides semantic understanding of the sign, and to pass that semantic understanding to the path planning modules running on the CPU Complex.

As another example, multiple neural networks may be run simultaneously, as is required for Level 3, 4, or 5 driving. For example, a warning sign consisting of “Caution: flashing lights indicate icy conditions,” along with an electric light, may be independently or collectively interpreted by several neural networks. The sign itself may be identified as a traffic sign by a first deployed neural network (e.g., a neural network that has been trained), the text “Flashing lights indicate icy conditions” may be interpreted by a second deployed neural network, which informs the vehicle's path planning software (preferably executing on the CPU Complex) that when flashing lights are detected, icy conditions exist. The flashing light may be identified by operating a third deployed neural network over multiple frames, informing the vehicle's path-planning software of the presence (or absence) of flashing lights. All three neural networks may run simultaneously, such as within the DLA and/or on the GPU(s) 1508.

In some examples, a CNN for facial recognition and vehicle owner identification may use data from camera sensors to identify the presence of an authorized driver and/or owner of the vehicle 1500. The always on sensor processing engine may be used to unlock the vehicle when the owner approaches the driver door and turn on the lights, and, in security mode, to disable the vehicle when the owner leaves the vehicle. In this way, the SoC(s) 1504 provide for security against theft and/or carjacking.

In another example, a CNN for emergency vehicle detection and identification may use data from microphones 1596 to detect and identify emergency vehicle sirens. In contrast to conventional systems, that use general classifiers to detect sirens and manually extract features, the SoC(s) 1504 use the CNN for classifying environmental and urban sounds, as well as classifying visual data. In a preferred embodiment, the CNN running on the DLA is trained to identify the relative closing speed of the emergency vehicle (e.g., by using the Doppler Effect). The CNN may also be trained to identify emergency vehicles specific to the local area in which the vehicle is operating, as identified by GNSS sensor(s) 1558. Thus, for example, when operating in Europe the CNN will seek to detect European sirens, and when in the United States the CNN will seek to identify only North American sirens. Once an emergency vehicle is detected, a control program may be used to execute an emergency vehicle safety routine, slowing the vehicle, pulling over to the side of the road, parking the vehicle, and/or idling the vehicle, with the assistance of ultrasonic sensors 1562, until the emergency vehicle(s) passes.

The vehicle may include a CPU(s) 1518 (e.g., discrete CPU(s), or dCPU(s)), that may be coupled to the SoC(s) 1504 via a high-speed interconnect (e.g., PCIe). The CPU(s) 1518 may include an X86 processor, for example. The CPU(s) 1518 may be used to perform any of a variety of functions, including arbitrating potentially inconsistent results between ADAS sensors and the SoC(s) 1504, and/or monitoring the status and health of the controller(s) 1536 and/or infotainment SoC 1530, for example.

The vehicle 1500 may include a GPU(s) 1520 (e.g., discrete GPU(s), or dGPU(s)), that may be coupled to the SoC(s) 1504 via a high-speed interconnect (e.g., NVIDIA's NVLINK). The GPU(s) 1520 may provide additional artificial intelligence functionality, such as by executing redundant and/or different neural networks, and may be used to train and/or update neural networks based on input (e.g., sensor data) from sensors of the vehicle 1500.

The vehicle 1500 may further include the network interface 1524 which may include one or more wireless antennas 1526 (e.g., one or more wireless antennas for different communication protocols, such as a cellular antenna, a Bluetooth antenna, etc.). The network interface 1524 may be used to enable wireless connectivity over the Internet with the cloud (e.g., with the server(s) 1578 and/or other network devices), with other vehicles, and/or with computing devices (e.g., client devices of passengers). To communicate with other vehicles, a direct link may be established between the two vehicles and/or an indirect link may be established (e.g., across networks and over the Internet). Direct links may be provided using a vehicle-to-vehicle communication link. The vehicle-to-vehicle communication link may provide the vehicle 1500 information about vehicles in proximity to the vehicle 1500 (e.g., vehicles in front of, on the side of, and/or behind the vehicle 1500). This functionality may be part of a cooperative adaptive cruise control functionality of the vehicle 1500.

The network interface 1524 may include a SoC that provides modulation and demodulation functionality and enables the controller(s) 1536 to communicate over wireless networks. The network interface 1524 may include a radio frequency front-end for up-conversion from baseband to radio frequency, and down conversion from radio frequency to baseband. The frequency conversions may be performed through well-known processes, and/or may be performed using super-heterodyne processes. In some examples, the radio frequency front end functionality may be provided by a separate chip. The network interface may include wireless functionality for communicating over LTE, WCDMA, UMTS, GSM, CDMA2000, Bluetooth, Bluetooth LE, Wi-Fi, Z-Wave, ZigBee, LoRaWAN, and/or other wireless protocols.

The vehicle 1500 may further include data store(s) 1528 which may include off-chip (e.g., off the SoC(s) 1504) storage. The data store(s) 1528 may include one or more storage elements including RAM, SRAM, DRAM, VRAM, Flash, hard disks, and/or other components and/or devices that may store at least one bit of data.

The vehicle 1500 may further include GNSS sensor(s) 1558. The GNSS sensor(s) 1558 (e.g., GPS, assisted GPS sensors, differential GPS (DGPS) sensors, etc.), to assist in mapping, perception, occupancy grid generation, and/or path planning functions. Any number of GNSS sensor(s) 1558 may be used, including, for example and without limitation, a GPS using a USB connector with an Ethernet to Serial (RS-232) bridge.

The vehicle 1500 may further include RADAR sensor(s) 1560. The RADAR sensor(s) 1560 may be used by the vehicle 1500 for long-range vehicle detection, even in darkness and/or severe weather conditions. RADAR functional safety levels may be ASIL B. The RADAR sensor(s) 1560 may use the CAN and/or the bus 1502 (e.g., to transmit data generated by the RADAR sensor(s) 1560) for control and to access object tracking data, with access to Ethernet to access raw data in some examples. A wide variety of RADAR sensor types may be used. For example, and without limitation, the RADAR sensor(s) 1560 may be suitable for front, rear, and side RADAR use. In some example, Pulse Doppler RADAR sensor(s) are used.

The RADAR sensor(s) 1560 may include different configurations, such as long range with narrow field of view, short range with wide field of view, short range side coverage, etc. In some examples, long-range RADAR may be used for adaptive cruise control functionality. The long-range RADAR systems may provide a broad field of view realized by two or more independent scans, such as within a 250 m range. The RADAR sensor(s) 1560 may help in distinguishing between static and moving objects, and may be used by ADAS systems for emergency brake assist and forward collision warning. Long-range RADAR sensors may include monostatic multimodal RADAR with multiple (e.g., six or more) fixed RADAR antennae and a high-speed CAN and FlexRay interface. In an example with six antennae, the central four antennae may create a focused beam pattern, designed to record the vehicle's 1500 surroundings at higher speeds with minimal interference from traffic in adjacent lanes. The other two antennae may expand the field of view, making it possible to quickly detect vehicles entering or leaving the vehicle's 1500 lane.

Mid-range RADAR systems may include, as an example, a range of up to 1560 m (front) or 80 m (rear), and a field of view of up to 42 degrees (front) or 1550 degrees (rear). Short-range RADAR systems may include, without limitation, RADAR sensors designed to be installed at both ends of the rear bumper. When installed at both ends of the rear bumper, such a RADAR sensor systems may create two beams that constantly monitor the blind spot in the rear and next to the vehicle.

Short-range RADAR systems may be used in an ADAS system for blind spot detection and/or lane change assist.

The vehicle 1500 may further include ultrasonic sensor(s) 1562. The ultrasonic sensor(s) 1562, which may be positioned at the front, back, and/or the sides of the vehicle 1500, may be used for park assist and/or to create and update an occupancy grid. A wide variety of ultrasonic sensor(s) 1562 may be used, and different ultrasonic sensor(s) 1562 may be used for different ranges of detection (e.g., 2.5 m, 4 m). The ultrasonic sensor(s) 1562 may operate at functional safety levels of ASIL B.

The vehicle 1500 may include LIDAR sensor(s) 1564. The LIDAR sensor(s) 1564 may be used for object and pedestrian detection, emergency braking, collision avoidance, and/or other functions. The LIDAR sensor(s) 1564 may be functional safety level ASIL B. In some examples, the vehicle 1500 may include multiple LIDAR sensors 1564 (e.g., two, four, six, etc.) that may use Ethernet (e.g., to provide data to a Gigabit Ethernet switch).

In some examples, the LIDAR sensor(s) 1564 may be capable of providing a list of objects and their distances for a 360-degree field of view. Commercially available LIDAR sensor(s) 1564 may have an advertised range of approximately 1500 m, with an accuracy of 2 cm-3 cm, and with support for a 1500 Mbps Ethernet connection, for example. In some examples, one or more non-protruding LIDAR sensors 1564 may be used. In such examples, the LIDAR sensor(s) 1564 may be implemented as a small device that may be embedded into the front, rear, sides, and/or corners of the vehicle 1500. The LIDAR sensor(s) 1564, in such examples, may provide up to a 120-degree horizontal and 35-degree vertical field-of-view, with a 200 m range even for low-reflectivity objects. Front-mounted LIDAR sensor(s) 1564 may be configured for a horizontal field of view between 45 degrees and 135 degrees.

In some examples, LIDAR technologies, such as 3D flash LIDAR, may also be used. 3D Flash LIDAR uses a flash of a laser as a transmission source, to illuminate vehicle surroundings up to approximately 200 m. A flash LIDAR unit includes a receptor, which records the laser pulse transit time and the reflected light on each pixel, which in turn corresponds to the range from the vehicle to the objects. Flash LIDAR may allow for highly accurate and distortion-free images of the surroundings to be generated with every laser flash. In some examples, four flash LIDAR sensors may be deployed, one at each side of the vehicle 1500. Available 3D flash LIDAR systems include a solid-state 3D staring array LIDAR camera with no moving parts other than a fan (e.g., a non-scanning LIDAR device). The flash LIDAR device may use a 5 nanosecond class I (eye-safe) laser pulse per frame and may capture the reflected laser light in the form of 3D range point clouds and co-registered intensity data. By using flash LIDAR, and because flash LIDAR is a solid-state device with no moving parts, the LIDAR sensor(s) 1564 may be less susceptible to motion blur, vibration, and/or shock.

The vehicle may further include IMU sensor(s) 1566. The IMU sensor(s) 1566 may be located at a center of the rear axle of the vehicle 1500, in some examples. The IMU sensor(s) 1566 may include, for example and without limitation, an accelerometer(s), a magnetometer(s), a gyroscope(s), a magnetic compass(es), and/or other sensor types. In some examples, such as in six-axis applications, the IMU sensor(s) 1566 may include accelerometers and gyroscopes, while in nine-axis applications, the IMU sensor(s) 1566 may include accelerometers, gyroscopes, and magnetometers.

In some embodiments, the IMU sensor(s) 1566 may be implemented as a miniature, high performance GPS-Aided Inertial Navigation System (GPS/INS) that combines micro-electro-mechanical systems (MEMS) inertial sensors, a high-sensitivity GPS receiver, and advanced Kalman filtering algorithms to provide estimates of position, velocity, and attitude. As such, in some examples, the IMU sensor(s) 1566 may enable the vehicle 1500 to estimate heading without requiring input from a magnetic sensor by directly observing and correlating the changes in velocity from GPS to the IMU sensor(s) 1566. In some examples, the IMU sensor(s) 1566 and the GNSS sensor(s) 1558 may be combined in a single integrated unit.

The vehicle may include microphone(s) 1596 placed in and/or around the vehicle 1500. The microphone(s) 1596 may be used for emergency vehicle detection and identification, among other things.

The vehicle may further include any number of camera types, including stereo camera(s) 1568, wide-view camera(s) 1570, infrared camera(s) 1572, surround camera(s) 1574, long-range and/or mid-range camera(s) 1598, and/or other camera types. The cameras may be used to capture image data around an entire periphery of the vehicle 1500. The types of cameras used depends on the embodiments and requirements for the vehicle 1500, and any combination of camera types may be used to provide the necessary coverage around the vehicle 1500. In addition, the number of cameras may differ depending on the embodiment. For example, the vehicle may include six cameras, seven cameras, ten cameras, twelve cameras, and/or another number of cameras. The cameras may support, as an example and without limitation, Gigabit Multimedia Serial Link (GMSL) and/or Gigabit Ethernet. Each of the camera(s) is described with more detail herein with respect to FIG. 15A and FIG. 15B.

The vehicle 1500 may further include vibration sensor(s) 1542. The vibration sensor(s) 1542 may measure vibrations of components of the vehicle, such as the axle(s). For example, changes in vibrations may indicate a change in road surfaces. In another example, when two or more vibration sensors 1542 are used, the differences between the vibrations may be used to determine friction or slippage of the road surface (e.g., when the difference in vibration is between a power-driven axle and a freely rotating axle).

The vehicle 1500 may include an ADAS system 1538. The ADAS system 1538 may include a SoC, in some examples. The ADAS system 1538 may include autonomous/adaptive/automatic cruise control (ACC), cooperative adaptive cruise control (CACC), forward crash warning (FCW), automatic emergency braking (AEB), lane departure warnings (LDW), lane keep assist (LKA), blind spot warning (BSW), rear cross-traffic warning (RCTW), collision warning systems (CWS), lane centering (LC), and/or other features and functionality.

The ACC systems may use RADAR sensor(s) 1560, LIDAR sensor(s) 1564, and/or a camera(s). The ACC systems may include longitudinal ACC and/or lateral ACC. Longitudinal ACC monitors and controls the distance to the vehicle immediately ahead of the vehicle 1500 and automatically adjust the vehicle speed to maintain a safe distance from vehicles ahead. Lateral ACC performs distance keeping, and advises the vehicle 1500 to change lanes when necessary. Lateral ACC is related to other ADAS applications such as LCA and CWS.

CACC uses information from other vehicles that may be received via the network interface 1524 and/or the wireless antenna(s) 1526 from other vehicles via a wireless link, or indirectly, over a network connection (e.g., over the Internet). Direct links may be provided by a vehicle-to-vehicle (V2V) communication link, while indirect links may be infrastructure-to-vehicle (I2V) communication link. In general, the V2V communication concept provides information about the immediately preceding vehicles (e.g., vehicles immediately ahead of and in the same lane as the vehicle 1500), while the I2V communication concept provides information about traffic further ahead. CACC systems may include either or both I2V and V2V information sources. Given the information of the vehicles ahead of the vehicle 1500, CACC may be more reliable and it has potential to improve traffic flow smoothness and reduce congestion on the road.

FCW systems are designed to alert the driver to a hazard, so that the driver may take corrective action. FCW systems use a front-facing camera and/or RADAR sensor(s) 1560, coupled to a dedicated processor, DSP, FPGA, and/or ASIC, that is electrically coupled to driver feedback, such as a display, speaker, and/or vibrating component. FCW systems may provide a warning, such as in the form of a sound, visual warning, vibration and/or a quick brake pulse.

AEB systems detect an impending forward collision with another vehicle or other object, and may automatically apply the brakes if the driver does not take corrective action within a specified time or distance parameter. AEB systems may use front-facing camera(s) and/or RADAR sensor(s) 1560, coupled to a dedicated processor, DSP, FPGA, and/or ASIC. When the AEB system detects a hazard, it typically first alerts the driver to take corrective action to avoid the collision and, if the driver does not take corrective action, the AEB system may automatically apply the brakes in an effort to prevent, or at least mitigate, the impact of the predicted collision. AEB systems, may include techniques such as dynamic brake support and/or crash imminent braking.

LDW systems provide visual, audible, and/or tactile warnings, such as steering wheel or seat vibrations, to alert the driver when the vehicle 1500 crosses lane markings. A LDW system does not activate when the driver indicates an intentional lane departure, by activating a turn signal. LDW systems may use front-side facing cameras, coupled to a dedicated processor, DSP, FPGA, and/or ASIC, that is electrically coupled to driver feedback, such as a display, speaker, and/or vibrating component.

LKA systems are a variation of LDW systems. LKA systems provide steering input or braking to correct the vehicle 1500 if the vehicle 1500 starts to exit the lane.

BSW systems detects and warn the driver of vehicles in an automobile's blind spot. BSW systems may provide a visual, audible, and/or tactile alert to indicate that merging or changing lanes is unsafe. The system may provide an additional warning when the driver uses a turn signal. BSW systems may use rear-side facing camera(s) and/or RADAR sensor(s) 1560, coupled to a dedicated processor, DSP, FPGA, and/or ASIC, that is electrically coupled to driver feedback, such as a display, speaker, and/or vibrating component.

RCTW systems may provide visual, audible, and/or tactile notification when an object is detected outside the rear-camera range when the vehicle 1500 is backing up. Some RCTW systems include AEB to ensure that the vehicle brakes are applied to avoid a crash. RCTW systems may use one or more rear-facing RADAR sensor(s) 1560, coupled to a dedicated processor, DSP, FPGA, and/or ASIC, that is electrically coupled to driver feedback, such as a display, speaker, and/or vibrating component.

Conventional ADAS systems may be prone to false positive results which may be annoying and distracting to a driver, but typically are not catastrophic, because the ADAS systems alert the driver and allow the driver to decide whether a safety condition truly exists and act accordingly. However, in an autonomous vehicle 1500, the vehicle 1500 itself must, in the case of conflicting results, decide whether to heed the result from a primary computer or a secondary computer (e.g., a first controller 1536 or a second controller 1536). For example, in some embodiments, the ADAS system 1538 may be a backup and/or secondary computer for providing perception information to a backup computer rationality module. The backup computer rationality monitor may run a redundant diverse software on hardware components to detect faults in perception and dynamic driving tasks. Outputs from the ADAS system 1538 may be provided to a supervisory MCU. If outputs from the primary computer and the secondary computer conflict, the supervisory MCU must determine how to reconcile the conflict to ensure safe operation.

In some examples, the primary computer may be configured to provide the supervisory MCU with a confidence score, indicating the primary computer's confidence in the chosen result. If the confidence score exceeds a threshold, the supervisory MCU may follow the primary computer's direction, regardless of whether the secondary computer provides a conflicting or inconsistent result. Where the confidence score does not meet the threshold, and where the primary and secondary computer indicate different results (e.g., the conflict), the supervisory MCU may arbitrate between the computers to determine the appropriate outcome.

The supervisory MCU may be configured to run a neural network(s) that is trained and configured to determine, based on outputs from the primary computer and the secondary computer, conditions under which the secondary computer provides false alarms. Thus, the neural network(s) in the supervisory MCU may learn when the secondary computer's output may be trusted, and when it cannot. For example, when the secondary computer is a RADAR-based FCW system, a neural network(s) in the supervisory MCU may learn when the FCW system is identifying metallic objects that are not, in fact, hazards, such as a drainage grate or manhole cover that triggers an alarm. Similarly, when the secondary computer is a camera-based LDW system, a neural network in the supervisory MCU may learn to override the LDW when bicyclists or pedestrians are present and a lane departure is, in fact, the safest maneuver. In embodiments that include a neural network(s) running on the supervisory MCU, the supervisory MCU may include at least one of a DLA or GPU suitable for running the neural network(s) with associated memory. In preferred embodiments, the supervisory MCU may comprise and/or be included as a component of the SoC(s) 1504.

In other examples, ADAS system 1538 may include a secondary computer that performs ADAS functionality using traditional rules of computer vision. As such, the secondary computer may use classic computer vision rules (if-then), and the presence of a neural network(s) in the supervisory MCU may improve reliability, safety and performance. For example, the diverse implementation and intentional non-identity makes the overall system more fault-tolerant, especially to faults caused by software (or software-hardware interface) functionality. For example, if there is a software bug or error in the software running on the primary computer, and the non-identical software code running on the secondary computer provides the same overall result, the supervisory MCU may have greater confidence that the overall result is correct, and the bug in software or hardware on primary computer is not causing material error.

In some examples, the output of the ADAS system 1538 may be fed into the primary computer's perception block and/or the primary computer's dynamic driving task block. For example, if the ADAS system 1538 indicates a forward crash warning due to an object immediately ahead, the perception block may use this information when identifying objects. In other examples, the secondary computer may have its own neural network which is trained and thus reduces the risk of false positives, as described herein.

The vehicle 1500 may further include the infotainment SoC 1530 (e.g., an in-vehicle infotainment system (IVI)). Although illustrated and described as a SoC, the infotainment system may not be a SoC, and may include two or more discrete components. The infotainment SoC 1530 may include a combination of hardware and software that may be used to provide audio (e.g., music, a personal digital assistant, navigational instructions, news, radio, etc.), video (e.g., TV, movies, streaming, etc.), phone (e.g., hands-free calling), network connectivity (e.g., LTE, Wi-Fi, etc.), and/or information services (e.g., navigation systems, rear-parking assistance, a radio data system, vehicle related information such as fuel level, total distance covered, brake fuel level, oil level, door open/close, air filter information, etc.) to the vehicle 1500. For example, the infotainment SoC 1530 may radios, disk players, navigation systems, video players, USB and Bluetooth connectivity, carputers, in-car entertainment, Wi-Fi, steering wheel audio controls, hands free voice control, a heads-up display (HUD), an HMI display 1534, a telematics device, a control panel (e.g., for controlling and/or interacting with various components, features, and/or systems), and/or other components. The infotainment SoC 1530 may further be used to provide information (e.g., visual and/or audible) to a user(s) of the vehicle, such as information from the ADAS system 1538, autonomous driving information such as planned vehicle maneuvers, trajectories, surrounding environment information (e.g., intersection information, vehicle information, road information, etc.), and/or other information.

The infotainment SoC 1530 may include GPU functionality. The infotainment SoC 1530 may communicate over the bus 1502 (e.g., CAN bus, Ethernet, etc.) with other devices, systems, and/or components of the vehicle 1500. In some examples, the infotainment SoC 1530 may be coupled to a supervisory MCU such that the GPU of the infotainment system may perform some self-driving functions in the event that the primary controller(s) 1536 (e.g., the primary and/or backup computers of the vehicle 1500) fail. In such an example, the infotainment SoC 1530 may put the vehicle 1500 into a chauffeur to safe stop mode, as described herein.

The vehicle 1500 may further include an instrument cluster 1532 (e.g., a digital dash, an electronic instrument cluster, a digital instrument panel, etc.). The instrument cluster 1532 may include a controller and/or supercomputer (e.g., a discrete controller or supercomputer). The instrument cluster 1532 may include a set of instrumentation such as a speedometer, fuel level, oil pressure, tachometer, odometer, turn indicators, gearshift position indicator, seat belt warning light(s), parking-brake warning light(s), engine-malfunction light(s), airbag (SRS) system information, lighting controls, safety system controls, navigation information, etc. In some examples, information may be displayed and/or shared among the infotainment SoC 1530 and the instrument cluster 1532. In other words, the instrument cluster 1532 may be included as part of the infotainment SoC 1530, or vice versa.

FIG. 15D is a system diagram for communication between cloud-based server(s) and the example autonomous vehicle 1500 of FIG. 15A, in accordance with some embodiments of the present disclosure. The system 1576 may include server(s) 1578, network(s) 1590, and vehicles, including the vehicle 1500. The server(s) 1578 may include a plurality of GPUs 1584(A)-1584(H) (collectively referred to herein as GPUs 1584), PCIe switches 1582(A)-1582(H) (collectively referred to herein as PCIe switches 1582), and/or CPUs 1580(A)-1580(B) (collectively referred to herein as CPUs 1580). The GPUs 1584, the CPUs 1580, and the PCIe switches may be interconnected with high-speed interconnects such as, for example and without limitation, NVLink interfaces 1588 developed by NVIDIA and/or PCIe connections 1586. In some examples, the GPUs 1584 are connected via NVLink and/or NVSwitch SoC and the GPUs 1584 and the PCIe switches 1582 are connected via PCIe interconnects. Although eight GPUs 1584, two CPUs 1580, and two PCIe switches are illustrated, this is not intended to be limiting. Depending on the embodiment, each of the server(s) 1578 may include any number of GPUs 1584, CPUs 1580, and/or PCIe switches. For example, the server(s) 1578 may each include eight, sixteen, thirty-two, and/or more GPUs 1584.

The server(s) 1578 may receive, over the network(s) 1590 and from the vehicles, image data representative of images showing unexpected or changed road conditions, such as recently commenced road-work. The server(s) 1578 may transmit, over the network(s) 1590 and to the vehicles, neural networks 1592, updated neural networks 1592, and/or map information 1594, including information regarding traffic and road conditions. The updates to the map information 1594 may include updates for the HD map 1522, such as information regarding construction sites, potholes, detours, flooding, and/or other obstructions. In some examples, the neural networks 1592, the updated neural networks 1592, and/or the map information 1594 may have resulted from new training and/or experiences represented in data received from any number of vehicles in the environment, and/or based on training performed at a datacenter (e.g., using the server(s) 1578 and/or other servers).

The server(s) 1578 may be used to train machine learning models (e.g., neural networks) based on training data. The training data may be generated by the vehicles, and/or may be generated in a simulation (e.g., using a game engine). In some examples, the training data is tagged (e.g., where the neural network benefits from supervised learning) and/or undergoes other pre-processing, while in other examples the training data is not tagged and/or pre-processed (e.g., where the neural network does not require supervised learning). Training may be executed according to any one or more classes of machine learning techniques, including, without limitation, classes such as: supervised training, semi-supervised training, unsupervised training, self-learning, reinforcement learning, federated learning, transfer learning, feature learning (including principal component and cluster analyses), multi-linear subspace learning, manifold learning, representation learning (including spare dictionary learning), rule-based machine learning, anomaly detection, and any variants or combinations therefor. Once the machine learning models are trained, the machine learning models may be used by the vehicles (e.g., transmitted to the vehicles over the network(s) 1590, and/or the machine learning models may be used by the server(s) 1578 to remotely monitor the vehicles.

In some examples, the server(s) 1578 may receive data from the vehicles and apply the data to up-to-date real-time neural networks for real-time intelligent inferencing. The server(s) 1578 may include deep-learning supercomputers and/or dedicated AI computers powered by GPU(s) 1584, such as a DGX and DGX Station machines developed by NVIDIA. However, in some examples, the server(s) 1578 may include deep learning infrastructure that use only CPU-powered datacenters.

The deep-learning infrastructure of the server(s) 1578 may be capable of fast, real-time inferencing, and may use that capability to evaluate and verify the health of the processors, software, and/or associated hardware in the vehicle 1500. For example, the deep-learning infrastructure may receive periodic updates from the vehicle 1500, such as a sequence of images and/or objects that the vehicle 1500 has located in that sequence of images (e.g., via computer vision and/or other machine learning object classification techniques). The deep-learning infrastructure may run its own neural network to identify the objects and compare them with the objects identified by the vehicle 1500 and, if the results do not match and the infrastructure concludes that the AI in the vehicle 1500 is malfunctioning, the server(s) 1578 may transmit a signal to the vehicle 1500 instructing a fail-safe computer of the vehicle 1500 to assume control, notify the passengers, and complete a safe parking maneuver.

For inferencing, the server(s) 1578 may include the GPU(s) 1584 and one or more programmable inference accelerators (e.g., NVIDIA's TensorRT). The combination of GPU-powered servers and inference acceleration may make real-time responsiveness possible. In other examples, such as where performance is less critical, servers powered by CPUs, FPGAs, and other processors may be used for inferencing.

### Example Computing Device

FIG. 16 is a block diagram of an example computing device(s) 1600 suitable for use in implementing some embodiments of the present disclosure. Computing device 1600 may include an interconnect system 1602 that directly or indirectly couples the following devices: memory 1604, one or more central processing units (CPUs) 1606, one or more graphics processing units (GPUs) 1608, a communication interface 1610, input/output (I/O) ports 1612, input/output components 1614, a power supply 1616, one or more presentation components 1618 (e.g., display(s)), and one or more logic units 1620. In at least one embodiment, the computing device(s) 1600 may comprise one or more virtual machines (VMs), and/or any of the components thereof may comprise virtual components (e.g., virtual hardware components). For non-limiting examples, one or more of the GPUs 1608 may comprise one or more vGPUs, one or more of the CPUs 1606 may comprise one or more vCPUs, and/or one or more of the logic units 1620 may comprise one or more virtual logic units. As such, a computing device(s) 1600 may include discrete components (e.g., a full GPU dedicated to the computing device 1600), virtual components (e.g., a portion of a GPU dedicated to the computing device 1600), or a combination thereof.

Although the various blocks of FIG. 16 are shown as connected via the interconnect system 1602 with lines, this is not intended to be limiting and is for clarity only. For example, in some embodiments, a presentation component 1618, such as a display device, may be considered an I/O component 1614 (e.g., if the display is a touch screen). As another example, the CPUs 1606 and/or GPUs 1608 may include memory (e.g., the memory 1604 may be representative of a storage device in addition to the memory of the GPUs 1608, the CPUs 1606, and/or other components). In other words, the computing device of FIG. 16 is merely illustrative. Distinction is not made between such categories as “workstation,” “server,” “laptop,” “desktop,” “tablet,” “client device,” “mobile device,” “hand-held device,” “game console,” “electronic control unit (ECU),” “virtual reality system,” and/or other device or system types, as all are contemplated within the scope of the computing device of FIG. 16.

The interconnect system 1602 may represent one or more links or busses, such as an address bus, a data bus, a control bus, or a combination thereof. The interconnect system 1602 may include one or more bus or link types, such as an industry standard architecture (ISA) bus, an extended industry standard architecture (EISA) bus, a video electronics standards association (VESA) bus, a peripheral component interconnect (PCI) bus, a peripheral component interconnect express (PCIe) bus, and/or another type of bus or link. In some embodiments, there are direct connections between components. As an example, the CPU 1606 may be directly connected to the memory 1604. Further, the CPU 1606 may be directly connected to the GPU 1608. Where there is direct, or point-to-point connection between components, the interconnect system 1602 may include a PCIe link to carry out the connection. In these examples, a PCI bus need not be included in the computing device 1600.

The memory 1604 may include any of a variety of computer-readable media. The computer-readable media may be any available media that may be accessed by the computing device 1600. The computer-readable media may include both volatile and nonvolatile media, and removable and non-removable media. By way of example, and not limitation, the computer-readable media may comprise computer-storage media and communication media.

The computer-storage media may include both volatile and nonvolatile media and/or removable and non-removable media implemented in any method or technology for storage of information such as computer-readable instructions, data structures, program modules, and/or other data types. For example, the memory 1604 may store computer-readable instructions (e.g., that represent a program(s) and/or a program element(s), such as an operating system. Computer-storage media may include, but is not limited to, RAM, ROM, EEPROM, flash memory or other memory technology, CD-ROM, digital versatile disks (DVD) or other optical disk storage, magnetic cassettes, magnetic tape, magnetic disk storage or other magnetic storage devices, or any other medium which may be used to store the desired information and which may be accessed by computing device 1600. As used herein, computer storage media does not comprise signals per se.

The computer storage media may embody computer-readable instructions, data structures, program modules, and/or other data types in a modulated data signal such as a carrier wave or other transport mechanism and includes any information delivery media. The term “modulated data signal” may refer to a signal that has one or more of its characteristics set or changed in such a manner as to encode information in the signal. By way of example, and not limitation, the computer storage media may include wired media such as a wired network or direct-wired connection, and wireless media such as acoustic, RF, infrared and other wireless media. Combinations of any of the above should also be included within the scope of computer-readable media.

The CPU(s) 1606 may be configured to execute at least some of the computer-readable instructions to control one or more components of the computing device 1600 to perform one or more of the methods and/or processes described herein. The CPU(s) 1606 may each include one or more cores (e.g., one, two, four, eight, twenty-eight, seventy-two, etc.) that are capable of handling a multitude of software threads simultaneously. The CPU(s) 1606 may include any type of processor, and may include different types of processors depending on the type of computing device 1600 implemented (e.g., processors with fewer cores for mobile devices and processors with more cores for servers). For example, depending on the type of computing device 1600, the processor may be an Advanced RISC Machines (ARM) processor implemented using Reduced Instruction Set Computing (RISC) or an x86 processor implemented using Complex Instruction Set Computing (CISC). The computing device 1600 may include one or more CPUs 1606 in addition to one or more microprocessors or supplementary co-processors, such as math co-processors.

In addition to or alternatively from the CPU(s) 1606, the GPU(s) 1608 may be configured to execute at least some of the computer-readable instructions to control one or more components of the computing device 1600 to perform one or more of the methods and/or processes described herein. One or more of the GPU(s) 1608 may be an integrated GPU (e.g., with one or more of the CPU(s) 1606 and/or one or more of the GPU(s) 1608 may be a discrete GPU. In embodiments, one or more of the GPU(s) 1608 may be a coprocessor of one or more of the CPU(s) 1606. The GPU(s) 1608 may be used by the computing device 1600 to render graphics (e.g., 3D graphics) or perform general purpose computations. For example, the GPU(s) 1608 may be used for General-Purpose computing on GPUs (GPGPU). The GPU(s) 1608 may include hundreds or thousands of cores that are capable of handling hundreds or thousands of software threads simultaneously. The GPU(s) 1608 may generate pixel data for output images in response to rendering commands (e.g., rendering commands from the CPU(s) 1606 received via a host interface). The GPU(s) 1608 may include graphics memory, such as display memory, for storing pixel data or any other suitable data, such as GPGPU data. The display memory may be included as part of the memory 1604. The GPU(s) 1608 may include two or more GPUs operating in parallel (e.g., via a link). The link may directly connect the GPUs (e.g., using NVLINK) or may connect the GPUs through a switch (e.g., using NVSwitch). When combined together, each GPU 1608 may generate pixel data or GPGPU data for different portions of an output or for different outputs (e.g., a first GPU for a first image and a second GPU for a second image). Each GPU may include its own memory, or may share memory with other GPUs.

In addition to or alternatively from the CPU(s) 1606 and/or the GPU(s) 1608, the logic unit(s) 1620 may be configured to execute at least some of the computer-readable instructions to control one or more components of the computing device 1600 to perform one or more of the methods and/or processes described herein. In embodiments, the CPU(s) 1606, the GPU(s) 1608, and/or the logic unit(s) 1620 may discretely or jointly perform any combination of the methods, processes and/or portions thereof. One or more of the logic units 1620 may be part of and/or integrated in one or more of the CPU(s) 1606 and/or the GPU(s) 1608 and/or one or more of the logic units 1620 may be discrete components or otherwise external to the CPU(s) 1606 and/or the GPU(s) 1608. In embodiments, one or more of the logic units 1620 may be a coprocessor of one or more of the CPU(s) 1606 and/or one or more of the GPU(s) 1608.

Examples of the logic unit(s) 1620 include one or more processing cores and/or components thereof, such as Data Processing Units (DPUs), Tensor Cores (TCs), Tensor Processing Units(TPUs), Pixel Visual Cores (PVCs), Vision Processing Units (VPUs), Graphics Processing Clusters (GPCs), Texture Processing Clusters (TPCs), Streaming Multiprocessors (SMs), Tree Traversal Units (TTUs), Artificial Intelligence Accelerators (AIAs), Deep Learning Accelerators (DLAs), Arithmetic-Logic Units (ALUs), Application-Specific Integrated Circuits (ASICs), Floating Point Units (FPUs), input/output (I/O) elements, peripheral component interconnect (PCI) or peripheral component interconnect express (PCIe) elements, and/or the like.

The communication interface 1610 may include one or more receivers, transmitters, and/or transceivers that enable the computing device 1600 to communicate with other computing devices via an electronic communication network, included wired and/or wireless communications. The communication interface 1610 may include components and functionality to enable communication over any of a number of different networks, such as wireless networks (e.g., Wi-Fi, Z-Wave, Bluetooth, Bluetooth LE, ZigBee, etc.), wired networks (e.g., communicating over Ethernet or InfiniBand), low-power wide-area networks (e.g., LoRaWAN, SigFox, etc.), and/or the Internet. In one or more embodiments, logic unit(s) 1620 and/or communication interface 1610 may include one or more data processing units (DPUs) to transmit data received over a network and/or through interconnect system 1602 directly to (e.g., a memory of) one or more GPU(s) 1608.

The I/O ports 1612 may enable the computing device 1600 to be logically coupled to other devices including the I/O components 1614, the presentation component(s) 1618, and/or other components, some of which may be built in to (e.g., integrated in) the computing device 1600. Illustrative I/O components 1614 include a microphone, mouse, keyboard, joystick, game pad, game controller, satellite dish, scanner, printer, wireless device, etc. The I/O components 1614 may provide a natural user interface (NUI) that processes air gestures, voice, or other physiological inputs generated by a user. In some instances, inputs may be transmitted to an appropriate network element for further processing. An NUI may implement any combination of speech recognition, stylus recognition, facial recognition, biometric recognition, gesture recognition both on screen and adjacent to the screen, air gestures, head and eye tracking, and touch recognition (as described in more detail below) associated with a display of the computing device 1600. The computing device 1600 may be include depth cameras, such as stereoscopic camera systems, infrared camera systems, RGB camera systems, touchscreen technology, and combinations of these, for gesture detection and recognition. Additionally, the computing device 1600 may include accelerometers or gyroscopes (e.g., as part of an inertia measurement unit (IMU)) that enable detection of motion. In some examples, the output of the accelerometers or gyroscopes may be used by the computing device 1600 to render immersive augmented reality or virtual reality.

The power supply 1616 may include a hard-wired power supply, a battery power supply, or a combination thereof. The power supply 1616 may provide power to the computing device 1600 to enable the components of the computing device 1600 to operate.

The presentation component(s) 1618 may include a display (e.g., a monitor, a touch screen, a television screen, a heads-up-display (HUD), other display types, or a combination thereof), speakers, and/or other presentation components. The presentation component(s) 1618 may receive data from other components (e.g., the GPU(s) 1608, the CPU(s) 1606, DPUs, etc.), and output the data (e.g., as an image, video, sound, etc.).

### Example Data Center

FIG. 17 illustrates an example data center 1700 that may be used in at least one embodiments of the present disclosure. The data center 1700 may include a data center infrastructure layer 1710, a framework layer 1720, a software layer 1730, and/or an application layer 1740.

As shown in FIG. 17, the data center infrastructure layer 1710 may include a resource orchestrator 1712, grouped computing resources 1714, and node computing resources (“node C.R.s”) 1716(1)-1716(N), where “N” represents any whole, positive integer. In at least one embodiment, node C.R.s 1716(1)-1716(N) may include, but are not limited to, any number of central processing units (CPUs) or other processors (including DPUs, accelerators, field programmable gate arrays (FPGAs), graphics processors or graphics processing units (GPUs), etc.), memory devices (e.g., dynamic read-only memory), storage devices (e.g., solid state or disk drives), network input/output (NW I/O) devices, network switches, virtual machines (VMs), power modules, and/or cooling modules, etc. In some embodiments, one or more node C.R.s from among node C.R.s 1716(1)-1716(N) may correspond to a server having one or more of the above-mentioned computing resources. In addition, in some embodiments, the node C.R.s 1716(1)-17161(N) may include one or more virtual components, such as vGPUs, vCPUs, and/or the like, and/or one or more of the node C.R.s 1716(1)-1716(N) may correspond to a virtual machine (VM).

In at least one embodiment, grouped computing resources 1714 may include separate groupings of node C.R.s 1716 housed within one or more racks (not shown), or many racks housed in data centers at various geographical locations (also not shown). Separate groupings of node C.R.s 1716 within grouped computing resources 1714 may include grouped compute, network, memory or storage resources that may be configured or allocated to support one or more workloads. In at least one embodiment, several node C.R.s 1716 including CPUs, GPUs, DPUs, and/or other processors may be grouped within one or more racks to provide compute resources to support one or more workloads. The one or more racks may also include any number of power modules, cooling modules, and/or network switches, in any combination.

The resource orchestrator 1712 may configure or otherwise control one or more node C.R.s 1716(1)-1716(N) and/or grouped computing resources 1714. In at least one embodiment, resource orchestrator 1712 may include a software design infrastructure (SDI) management entity for the data center 1700. The resource orchestrator 1712 may include hardware, software, or some combination thereof.

In at least one embodiment, as shown in FIG. 17, framework layer 1720 may include a job scheduler 1733, a configuration manager 1734, a resource manager 1736, and/or a distributed file system 1738. The framework layer 1720 may include a framework to support software 1732 of software layer 1730 and/or one or more application(s) 1742 of application layer 1740. The software 1732 or application(s) 1742 may respectively include web-based service software or applications, such as those provided by Amazon Web Services, Google Cloud and Microsoft Azure. The framework layer 1720 may be, but is not limited to, a type of free and open-source software web application framework such as Apache Spark™ (hereinafter “Spark”) that may utilize distributed file system 1738 for large-scale data processing (e.g., “big data”). In at least one embodiment, job scheduler 1733 may include a Spark driver to facilitate scheduling of workloads supported by various layers of data center 1700. The configuration manager 1734 may be capable of configuring different layers such as software layer 1730 and framework layer 1720 including Spark and distributed file system 1738 for supporting large-scale data processing. The resource manager 1736 may be capable of managing clustered or grouped computing resources mapped to or allocated for support of distributed file system 1738 and job scheduler 1733. In at least one embodiment, clustered or grouped computing resources may include grouped computing resource 1714 at data center infrastructure layer 1710. The resource manager 1736 may coordinate with resource orchestrator 1712 to manage these mapped or allocated computing resources.

In at least one embodiment, software 1732 included in software layer 1730 may include software used by at least portions of node C.R.s 1716(1)-1716(N), grouped computing resources 1714, and/or distributed file system 1738 of framework layer 1720. One or more types of software may include, but are not limited to, Internet web page search software, e-mail virus scan software, database software, and streaming video content software.

In at least one embodiment, application(s) 1742 included in application layer 1740 may include one or more types of applications used by at least portions of node C.R.s 1716(1)-1716(N), grouped computing resources 1714, and/or distributed file system 1738 of framework layer 1720. One or more types of applications may include, but are not limited to, any number of a genomics application, a cognitive compute, and a machine learning application, including training or inferencing software, machine learning framework software (e.g., PyTorch, TensorFlow, Caffe, etc.), and/or other machine learning applications used in conjunction with one or more embodiments.

In at least one embodiment, any of configuration manager 1734, resource manager 1736, and resource orchestrator 1712 may implement any number and type of self-modifying actions based on any amount and type of data acquired in any technically feasible fashion. Self-modifying actions may relieve a data center operator of data center 1700 from making possibly bad configuration decisions and possibly avoiding underutilized and/or poor performing portions of a data center.

The data center 1700 may include tools, services, software or other resources to train one or more machine learning models or predict or infer information using one or more machine learning models according to one or more embodiments described herein. For example, a machine learning model(s) may be trained by calculating weight parameters according to a neural network architecture using software and/or computing resources described above with respect to the data center 1700. In at least one embodiment, trained or deployed machine learning models corresponding to one or more neural networks may be used to infer or predict information using resources described above with respect to the data center 1700 by using weight parameters calculated through one or more training techniques, such as but not limited to those described herein.

In at least one embodiment, the data center 1700 may use CPUs, application-specific integrated circuits (ASICs), GPUs, FPGAs, and/or other hardware (or virtual compute resources corresponding thereto) to perform training and/or inferencing using above-described resources. Moreover, one or more software and/or hardware resources described above may be configured as a service to allow users to train or performing inferencing of information, such as image recognition, speech recognition, or other artificial intelligence services.

### Example Network Environments

Network environments suitable for use in implementing embodiments of the disclosure may include one or more client devices, servers, network attached storage (NAS), other backend devices, and/or other device types. The client devices, servers, and/or other device types (e.g., each device) may be implemented on one or more instances of the computing device(s) 1600 of FIG. 16—e.g., each device may include similar components, features, and/or functionality of the computing device(s) 1600. In addition, where backend devices (e.g., servers, NAS, etc.) are implemented, the backend devices may be included as part of a data center 1700, an example of which is described in more detail herein with respect to FIG. 17.

Components of a network environment may communicate with each other via a network(s), which may be wired, wireless, or both. The network may include multiple networks, or a network of networks. By way of example, the network may include one or more Wide Area Networks (WANs), one or more Local Area Networks (LANs), one or more public networks such as the Internet and/or a public switched telephone network (PSTN), and/or one or more private networks. Where the network includes a wireless telecommunications network, components such as a base station, a communications tower, or even access points (as well as other components) may provide wireless connectivity.

Compatible network environments may include one or more peer-to-peer network environments—in which case a server may not be included in a network environment—and one or more client-server network environments—in which case one or more servers may be included in a network environment. In peer-to-peer network environments, functionality described herein with respect to a server(s) may be implemented on any number of client devices.

In at least one embodiment, a network environment may include one or more cloud-based network environments, a distributed computing environment, a combination thereof, etc. A cloud-based network environment may include a framework layer, a job scheduler, a resource manager, and a distributed file system implemented on one or more of servers, which may include one or more core network servers and/or edge servers. A framework layer may include a framework to support software of a software layer and/or one or more application(s) of an application layer. The software or application(s) may respectively include web-based service software or applications. In embodiments, one or more of the client devices may use the web-based service software or applications (e.g., by accessing the service software and/or applications via one or more application programming interfaces (APIs)). The framework layer may be, but is not limited to, a type of free and open-source software web application framework such as that may use a distributed file system for large-scale data processing (e.g., “big data”).

A cloud-based network environment may provide cloud computing and/or cloud storage that carries out any combination of computing and/or data storage functions described herein (or one or more portions thereof). Any of these various functions may be distributed over multiple locations from central or core servers (e.g., of one or more data centers that may be distributed across a state, a region, a country, the globe, etc.). If a connection to a user (e.g., a client device) is relatively close to an edge server(s), a core server(s) may designate at least a portion of the functionality to the edge server(s). A cloud-based network environment may be private (e.g., limited to a single organization), may be public (e.g., available to many organizations), and/or a combination thereof (e.g., a hybrid cloud environment).

The client device(s) may include at least some of the components, features, and functionality of the example computing device(s) 1600 described herein with respect to FIG. 16. By way of example and not limitation, a client device may be embodied as a Personal Computer (PC), a laptop computer, a mobile device, a smartphone, a tablet computer, a smart watch, a wearable computer, a Personal Digital Assistant (PDA), an MP3 player, a virtual reality headset, a Global Positioning System (GPS) or device, a video player, a video camera, a surveillance device or system, a vehicle, a boat, a flying vessel, a virtual machine, a drone, a robot, a handheld communications device, a hospital device, a gaming device or system, an entertainment system, a vehicle computer system, an embedded system controller, a remote control, an appliance, a consumer electronic device, a workstation, an edge device, any combination of these delineated devices, or any other suitable device.

The disclosure may be described in the general context of computer code or machine-useable instructions, including computer-executable instructions such as program modules, being executed by a computer or other machine, such as a personal data assistant or other handheld device. Generally, program modules including routines, programs, objects, components, data structures, etc., refer to code that perform particular tasks or implement particular abstract data types. The disclosure may be practiced in a variety of system configurations, including hand-held devices, consumer electronics, general-purpose computers, more specialty computing devices, etc. The disclosure may also be practiced in distributed computing environments where tasks are performed by remote-processing devices that are linked through a communications network.

As used herein, a recitation of “and/or” with respect to two or more elements should be interpreted to mean only one element, or a combination of elements. For example, “element A, element B, and/or element C” may include only element A, only element B, only element C, element A and element B, element A and element C, element B and element C, or elements A, B, and C. In addition, “at least one of element A or element B” may include at least one of element A, at least one of element B, or at least one of element A and at least one of element B. Further, “at least one of element A and element B” may include at least one of element A, at least one of element B, or at least one of element A and at least one of element B.

The subject matter of the present disclosure is described with specificity herein to meet statutory requirements. However, the description itself is not intended to limit the scope of this disclosure. Rather, the inventors have contemplated that the claimed subject matter might also be embodied in other ways, to include different steps or combinations of steps similar to the ones described in this document, in conjunction with other present or future technologies. Moreover, although the terms “step” and/or “block” may be used herein to connote different elements of methods employed, the terms should not be interpreted as implying any particular order among or between various steps herein disclosed unless and except when the order of individual steps is explicitly described.

### Example Paragraphs

A. A method comprising: obtaining a mesh data structure including a plurality of instanced mesh tiles representative of a terrain surface; determining that one or more portions of one or more mesh tiles of the plurality of mesh tiles are located within one or more threshold distances of one or more features to be rendered in a simulation environment, the one or more features having one or more levels of detail that are greater than a level of detail corresponding to the one or more mesh tiles; and based at least on the one or more portions being located within the one or more threshold distances of the one or more features, updating one or more parameters associated with the one or more mesh tiles to omit data corresponding to the one or more portions of the one or more mesh tiles from being rendered.
B. The method of paragraph A, further comprising: determining, based at least on the one or more portions being located with the one or more threshold distances of the one or more features, one or more polygons of the one or more mesh tiles to be omitted from being rendered; and wherein the one or more portions of the one or more mesh tiles include the one or more polygons.
C. The method of any one of paragraphs A-B, further comprising: determining one or more distances between one or more edges of the one or more features and one or more polygons associated with the one or more mesh tiles, wherein the determining that the one or more portions are located within the one or more threshold distances of the one or more features is based at least on the one or more distances meeting or exceeding the one or more threshold distances.
D. The method of any one of paragraphs A-C, further comprising: determining, subsequent to the updating, one or more first geometries associated with the one or more portions of the one or more mesh tiles; generating a second mesh data structure including one or more second portions having one or more second geometries corresponding to the one or more first geometries; and rendering at least the terrain surface and the one or more features in the simulation environment using a combination of the mesh data structure and the second mesh data structure.
E. The method of any one of paragraphs A-D, further comprising rendering the terrain surface in the simulation environment using one or more second portions of the one or more mesh tiles that are distinguishable from the one or more portions.
F. The method of any one of paragraphs A-E, wherein the determining that the one or more portions of the one or more mesh tiles are located within the one or more threshold distances of the one or more features comprises, at least: determining whether one or more first portions of one or more first mesh tiles of the plurality of mesh tiles are located within a first threshold distance of the one or more features; and determining whether one or more second portions of one or more second mesh tiles of the plurality of mesh tiles are located within a second threshold distance of the one or more features, wherein a difference between the first threshold distance and the second threshold distance is based at least on differences in levels of detail between the one or more first mesh tiles and the one or more second mesh tiles.
G. The method of any one of paragraphs A-F, further comprising: applying one or more shaders to the one or more portions of the one or more mesh tiles to omit the data corresponding to the one or more portions from being rendered, wherein the applying of the one or more shaders is based at least on the updating of the one or more parameters.
H. The method of any one of paragraphs A-G, wherein the one or more portions of the one or more mesh tiles correspond to one or more polygons associated with the one or more mesh tiles.
I. A system comprising: one or more processors to: obtain one or more mesh tiles corresponding to a surface; determine that one or more distances between one or more portions of the one or more mesh tiles and one or more features to be rendered in a virtual environment are less than one or more thresholds; and based at least on the one or more distances being less than the one or more thresholds, update the one or more mesh tiles to prevent data corresponding to the one or more portions from being used to render the surface.
J. The system of paragraph I, the one or more processors further to render at least the surface in the virtual environment using one or more second portions of the one or more mesh tiles that are distinguishable from the one or more portions.
K. The system of any one of paragraphs I-J, the one or more processors further to: determine one or more levels of detail associated with the one or more mesh tiles; and determine, based at least on the one or more levels of detail, the one or more thresholds for the one or more distances between the one or more portions and the one or more features.
L. The system of any one of paragraphs I-K, wherein the one or more portions of the one or more mesh tiles correspond to at least one of: one or more polygons associated with the one or more mesh tiles; one or more vertices associated with the one or more mesh tiles; one or more edges associated with the one or more mesh tiles; or one or more faces associated with the one or more mesh tiles.
M. The system of any one of paragraphs I-L, the one or more processors further to: determine one or more first locations corresponding to the one or more portions; and determine one or more second locations corresponding to one or more edges of the one or more features, determine the one or more distances between the one or more portions of the one or more mesh tiles and one or more features based at least on the one or more first location and the one or more second locations.
N. The system of any one of paragraphs I-M, the one or more processors further to: based at least on the update of the one or more mesh tiles, generate one or more mesh data structures for replacing the one or more portions; and render at least the surface and the one or more features in the virtual environment using a combination of the one or more mesh data structures and the one or more mesh tiles.
O. The system of any one of paragraphs I-N, the one or more processors further to: determine that a first level of detail associated with the one or more features is greater than a second level of detail associated with the one or more mesh tiles, wherein the update of the one or more mesh tiles to prevent the data corresponding to the one or more portions from being used to render the surface is further based at least on the first level of detail being greater than the second level of detail.
P. The system of any one of paragraphs I-O, the one or more processors further to: apply one or more shaders to the one or more portions of the one or more mesh tiles to prevent the data corresponding to the one or more portions from being used to render the surface, wherein the application of the one or more shaders is based at least on the updating of the one or more mesh tiles.
Q. The system of any one of paragraphs I-P, wherein the one or more features correspond to one or more hardtop surfaces cut out of the surface of the virtual environment, the one or more hardtop surfaces corresponding to one or more pathways.
R. The system of any one of paragraphs I-Q, wherein the system is comprised in at least one of: a control system for an autonomous or semi-autonomous machine; a perception system for an autonomous or semi-autonomous machine; a system for performing one or more simulation operations; a system for performing one or more digital twin operations; a system for performing light transport simulation; a system for performing collaborative content creation for 3D assets; a system for performing one or more deep learning operations; a system implemented using an edge device; a system implemented using a robot; a system for performing one or more generative AI operations; a system for performing operations using a large language model; a system for performing operations using one or more vision language models (VLMs); a system for performing operations using one or more multi-modal language models; a system for performing one or more conversational AI operations; a system for generating synthetic data; a system for presenting at least one of virtual reality content, augmented reality content, or mixed reality content; a system incorporating one or more virtual machines (VMs); a system implemented at least partially in a data center; a system implemented at least partially using cloud computing resources; systems using or deploying one or more inference microservices; or systems that incorporate one or more machine learning models deployed in a service or microservice along with an OS-level virtualization package.
S. One or more processors comprising: processing circuitry to update one or more renderings of one or more mesh tiles corresponding to a surface, at least in part, by causing data corresponding to one or more polygons of the one or more mesh tiles to be omitted from being rendered based at least on a determination that the one or more polygons are located within a threshold distance of one or more edges of one or more features to be rendered in a virtual environment, the one or more features having a higher resolution than the one or more mesh tiles.
T. The one or more processors of paragraph S, wherein the one or more processors are comprised in at least one of: a control system for an autonomous or semi-autonomous machine; a perception system for an autonomous or semi-autonomous machine; a system for performing one or more simulation operations; a system for performing one or more digital twin operations; a system for performing light transport simulation; a system for performing collaborative content creation for 3D assets; a system for performing one or more deep learning operations; a system implemented using an edge device; a system implemented using a robot; a system for performing one or more generative AI operations; a system for performing operations using a large language model; a system for performing operations using one or more vision language models (VLMs); a system for performing operations using one or more multi-modal language models; a system for performing one or more conversational AI operations; a system for generating synthetic data; a system for presenting at least one of virtual reality content, augmented reality content, or mixed reality content; a system incorporating one or more virtual machines (VMs); a system implemented at least partially in a data center; a system implemented at least partially using cloud computing resources; systems using or deploying one or more inference microservices; or systems that incorporate one or more machine learning models deployed in a service or microservice along with an OS-level virtualization package.

Here is the structured example paragraph conversion for the claims provided, starting with “U.” and continuing with “AA.” after “Z.”:
U. A method comprising: determining one or more first geometries associated with one or more portions of a first mesh data structure including a plurality of instanced mesh tiles corresponding to one or more first portions of a terrain surface; generating one or more second mesh data structures having one or more second geometries corresponding to the one or more first geometries, the one or more second mesh data structures corresponding to one or more second portions of the terrain surface; and rendering the terrain surface in a simulation environment using the one or more second mesh data structures at least partially in place of the one or more portions of the first mesh data structure.
V. The method of paragraph U, wherein: the plurality of instanced mesh tiles of the first mesh data structure define at least a three-dimensional (3D) topography of the terrain surface in the simulation environment, and the one or more second mesh data structures define at least one or more 3D characteristics associated with one or more features associated with the terrain surface.
W. The method of any one of paragraphs U-V, further comprising: determining one or more polygons associated with the first mesh data structure that are located within a threshold distance of one or more locations associated with one or more features to be rendered in the simulation environment; and preventing data corresponding to the one or more polygons from being included in rendering one or more mesh tiles of the plurality of instanced mesh tiles, wherein the one or more portions of the first mesh data structure correspond to the one or more polygons.
X. The method of any one of paragraphs U-W, wherein: the one or more first portions of the terrain surface correspond to one or more base layers of the terrain surface; and the one or more second portions of the terrain surface correspond to one or more hardtop surfaces of the terrain surface to be rendered on top of the one or more base layers.
Y. The method of any one of paragraphs U-X, further comprising: determining one or more edges of one or more features to be rendered with respect to the one or more second portions of the terrain surface, wherein the generating of the one or more second mesh data structures comprises generating one or more polygons of the one or more second mesh data structures based at least on the one or more edges.
Z. The method of any one of paragraphs U-Y, further comprising merging one or more second portions of the first mesh data structure and the one or more second mesh data structures based at least on the one or more second geometries corresponding to the one or more first geometries, wherein the rendering of the terrain surface is based at least on the merging.
AA. The method of any one of paragraphs U-Z, wherein the one or more second mesh data structures are associated with one or more different types of topology than the plurality of instanced mesh tiles.
BB. A system comprising: one or more processors to: generate, for a three-dimensional (3D) virtual environment, one or more first mesh data structures to replace one or more first portions of one or more instanced mesh tiles of one or more second mesh data structures that are obscured from a position in the virtual environment corresponding to a rendered viewpoint; merge, as a combination of mesh data structures, the one or more first mesh data structures and one or more second portions of the one or more instanced mesh tiles of the one or more second mesh data structures that are visible from the position corresponding to the rendered viewpoint; and render a texture elevation mesh of a surface in a virtual environment using the combination of mesh data structures.
CC. The system of paragraph BB, wherein the one or more first portions comprise a plurality of hidden polygons of the one or more instanced mesh tiles, the one or more processors further to: generate, for at least one hidden polygon of the plurality of hidden polygons, one or more replacement polygons of the one or more first mesh data structures, wherein the combination of the mesh data structures includes the one or more replacement polygons and one or more visible polygons of the one or more instanced mesh tiles.
DD. The system of any one of paragraphs BB-CC, the one or more processors further to generate one or more portions of the one or more first mesh data structures to replace the one or more first portions of the one or more instanced mesh tiles, the one or more portions having one or more levels of detail that are based at least on one or more sizes associated with the one or more first portions.
EE. The system of any one of paragraphs BB-DD, wherein the one or more first mesh data structures include one or more polygons defining one or more geometries corresponding to the one or more first portions of the one or more instanced mesh tiles.
FF. The system of any one of paragraphs BB-EE, wherein the surface includes at least: a base portion rendered using the one or more instanced mesh tiles of the one or more second mesh data structures; and one or more hardtop features representing one or more pathways in the simulation environment rendered using the one or more first mesh data structures.
GG. The system of any one of paragraphs BB-FF, wherein: the one or more instanced mesh tiles of the one or more second mesh data structures define at least a three-dimensional (3D) topography of the surface in the simulation environment, and the one or more first mesh data structures define at least one or more 3D characteristics corresponding to one or more features associated with the surface.
HH. The system of any one of paragraphs BB-GG, the one or more processors further to: determine one or more polygons associated with the one or more instanced mesh tiles that are located within a threshold distance of one or more locations associated with one or more features to be rendered in the simulation environment; and prevent data corresponding to the one or more polygons from being included in rendering of the one or more instanced mesh tiles based at least on the one or more polygons being located within the threshold distance of the one or more locations, wherein the one or more first portions of the one or more instanced mesh tiles correspond to the one or more polygons.
II. The system of any one of paragraphs BB-HH, wherein: the one or more first mesh data structures are associated with one or more different types of topology than the one or more instanced mesh tiles, and the one or more first mesh data structures seamlessly integrate with the one or more instanced mesh tiles based at least on the one or more first mesh data structures including one or more polygons having one or more edges that correspond to one or more boundaries of one or more features to be rendered in the simulation environment.
JJ. The system of any one of paragraphs BB-II, wherein the generation of the one or more first mesh data structures comprises: generating one or more first polygons of the one or more first mesh data structures to replace one or more first hidden polygons of the one or more instanced mesh tiles, the one or more first polygons having one or more first sizes based at least on one or more first resolutions associated with the one or more first hidden polygons; and generating one or more second polygons of the one or more first mesh data structures to replace one or more second hidden polygons of the one or more instanced mesh tiles, the one or more second polygons having one or more second sizes based at least on one or more second resolutions associated with the one or more second hidden polygons, wherein the one or more first sizes are different from the one or more second sizes.
KK. The system of any one of paragraphs BB-JJ, wherein the system is comprised in at least one of: a control system for an autonomous or semi-autonomous machine; a perception system for an autonomous or semi-autonomous machine; a system for performing one or more simulation operations; a system for performing one or more digital twin operations; a system for performing light transport simulation; a system for performing collaborative content creation for 3D assets; a system for performing one or more deep learning operations; a system implemented using an edge device; a system implemented using a robot; a system for performing one or more generative AI operations; a system for performing operations using a large language model; a system for performing operations using one or more vision language models (VLMs); a system for performing operations using one or more multi-modal language models; a system for performing one or more conversational AI operations; a system for generating synthetic data; a system for presenting at least one of virtual reality content, augmented reality content, or mixed reality content; a system incorporating one or more virtual machines (VMs); a system implemented at least partially in a data center; a system implemented at least partially using cloud computing resources; systems using or deploying one or more inference microservices; or systems that incorporate one or more machine learning models deployed in a service or microservice along with an OS-level virtualization package.
LL. One or more processors comprising: processing circuitry to generate one or more mesh data structures to replace one or more portions of one or more instanced mesh tiles representative of a surface in a virtual environment, the one or more mesh data structures including one or more polygons having one or more sizes based at least on one or more levels of detail associated with the one or more instanced mesh tiles.
MM. The one or more processors of paragraph LL, the processing circuitry further to render the surface in the virtual environment using a combination of the one or more mesh data structures and one or more second portions of the one or more instanced mesh tiles.
NN. The one or more processors of paragraph LL or MM, wherein the one or more processors are comprised in at least one of: a control system for an autonomous or semi-autonomous machine; a perception system for an autonomous or semi-autonomous machine; a system for performing one or more simulation operations; a system for performing one or more digital twin operations; a system for performing light transport simulation; a system for performing collaborative content creation for 3D assets; a system for performing one or more deep learning operations; a system implemented using an edge device; a system implemented using a robot; a system for performing one or more generative AI operations; a system for performing operations using a large language model; a system for performing operations using one or more vision language models (VLMs); a system for performing operations using one or more multi-modal language models; a system for performing one or more conversational AI operations; a system for generating synthetic data; a system for presenting at least one of virtual reality content, augmented reality content, or mixed reality content; a system incorporating one or more virtual machines (VMs); a system implemented at least partially in a data center; a system implemented at least partially using cloud computing resources; systems using or deploying one or more inference microservices; or systems that incorporate one or more machine learning models deployed in a service or microservice along with an OS-level virtualization package.

What is claimed is:

1. A method comprising:
determining one or more first geometries associated with one or more portions of a first mesh data structure including a plurality of instanced mesh tiles corresponding to one or more first portions of a terrain surface;
generating one or more second mesh data structures having one or more second geometries corresponding to the one or more first geometries, the one or more second mesh data structures corresponding to one or more second portions of the terrain surface; and
rendering the terrain surface in a simulation environment using the one or more second mesh data structures at least partially in place of the one or more portions of the first mesh data structure.

2. The method of claim 1, wherein:
the plurality of instanced mesh tiles of the first mesh data structure define at least a three-dimensional (3D) topography of the terrain surface in the simulation environment, and
the one or more second mesh data structures define at least one or more 3D characteristics associated with one or more features associated with the terrain surface.

3. The method of claim 1, further comprising:
determining one or more polygons associated with the first mesh data structure that are located within a threshold distance of one or more locations associated with one or more features to be rendered in the simulation environment; and
preventing data corresponding to the one or more polygons to from being included in rendering one or more mesh tiles of the plurality of instanced mesh tiles,
wherein the one or more portions of the first mesh data structure correspond to the one or more polygons.

4. The method of claim 1, wherein:
the one or more first portions of the terrain surface correspond to one or more base layers of the terrain surface; and
the one or more second portions of the terrain surface correspond to one or more hardtop surfaces of the terrain surface to be rendered on top of the one or more base layers.

5. The method of claim 1, further comprising:
determining one or more edges of one or more features to be rendered with respect to the one or more second portions of the terrain surface,
wherein the generating of the one or more second mesh data structures comprises generating one or more polygons of the one or more second mesh data structures based at least on the one or more edges.

6. The method of claim 1, further comprising merging one or more second portions of the first mesh data structure and the one or more second mesh data structures based at least on the one or more second geometries corresponding to the one or more first geometries, wherein the rendering of the terrain surface is based at least on the merging.

7. The method of claim 1, wherein the one or more second mesh data structures are associated with one or more different types of topology than the plurality of instanced mesh tiles.

8. A system comprising:
one or more processors to:
generate, for a three-dimensional (3D) virtual environment, one or more first mesh data structures to replace one or more first portions of one or more instanced mesh tiles of one or more second mesh data structures that are obscured from a position in the virtual environment corresponding to a rendered viewpoint;
merge, as a combination of mesh data structures, the one or more first mesh data structures and one or more second portions of the one or more instanced mesh tiles of the one or more second mesh data structures that are visible from the position corresponding to the rendered viewpoint; and
render a texture elevation mesh of a surface in a virtual environment using the combination of mesh data structures.

9. The system of claim 8, wherein the one or more first portions comprise a plurality of hidden polygons of the one or more instanced mesh tiles, the one or more processors further to:
generate, for at least one hidden polygon of the plurality of hidden polygons, one or more replacement polygons of the one or more first mesh data structures,
wherein the combination of the mesh data structures includes the one or more replacement polygons and one or more visible polygons of the one or more instanced mesh tiles.

10. The system of claim 8, the one or more processors further to generate one or more portions of the one or more first mesh data structures to replace the one or more first portions of the one or more instanced mesh tiles, the one or more portions having one or more levels of detail that are based at least on one or more sizes associated with the one or more first portions.

11. The system of claim 8, wherein the one or more first mesh data structures include one or more polygons defining one or more geometries corresponding to the one or more first portions of the one or more instanced mesh tiles.

12. The system of claim 8, wherein the surface includes at least:
a base portion rendered using the one or more instanced mesh tiles of the one or more second mesh data structures; and
one or more hardtop features representing one or more pathways in the simulation environment rendered using the one or more first mesh data structures.

13. The system of claim 8, wherein:
the one or more instanced mesh tiles of the one or more second mesh data structures define at least a three-dimensional (3D) topography of the surface in the simulation environment, and
the one or more first mesh data structures define at least one or more 3D characteristics corresponding to one or more features associated with the surface.

14. The system of claim 8, the one or more processors further to:
determine one or more polygons associated with the one or more instanced mesh tiles that are located within a threshold distance of one or more locations associated with one or more features to be rendered in the simulation environment; and
prevent data corresponding to the one or more polygons from being included in rendering of the one or more instanced mesh tiles based at least on the one or more polygons being located within the threshold distance of the one or more locations,
wherein the one or more first portions of the one or more instanced mesh tiles correspond to the one or more polygons.

15. The system of claim 8, wherein:
the one or more first mesh data structures are associated with one or more different types of topology than the one or more instanced mesh tiles, and
the one or more first mesh data structures seamlessly integrate with the one or more instanced mesh tiles based at least on the one or more first mesh data structures including one or more polygons having one or more edges that correspond to one or more boundaries of one or features to be rendered in the simulation environment.

16. The system of claim 8, wherein the generation of the one or more first mesh data structures comprises:
generating one or more first polygons of the one or more first mesh data structures to replace one or more first hidden polygons of the one or more instanced mesh tiles, the one or more first polygons having one or more first sizes based at least on one or more first resolutions associated with the one or more first hidden polygons; and
generating one or more second polygons of the one or more first mesh data structures to replace one or more second hidden polygons of the one or more instanced mesh tiles, the one or more second polygons having one or more second sizes based at least on one or more second resolutions associated with the one or more second hidden polygons,
wherein the one or more first sizes are different from the one or more second sizes.

17. The system of claim 8, wherein the system is comprised in at least one of:
a control system for an autonomous or semi-autonomous machine;
a perception system for an autonomous or semi-autonomous machine;
a system for performing one or more simulation operations;
a system for performing one or more digital twin operations;
a system for performing light transport simulation;
a system for performing collaborative content creation for 3D assets;
a system for performing one or more deep learning operations;
a system implemented using an edge device;
a system implemented using a robot;
a system for performing one or more generative AI operations;
a system for performing operations using a large language model;
a system for performing operations using one or more vision language models (VLMs);
a system for performing operations using one or more multi-modal language models;
a system for performing one or more conversational AI operations;
a system for generating synthetic data;
a system for presenting at least one of virtual reality content, augmented reality content, or mixed reality content;
a system incorporating one or more virtual machines (VMs);
a system implemented at least partially in a data center;
a system implemented at least partially using cloud computing resources;
systems using or deploying one or more inference microservices; or
systems that incorporate one or more machine learning models deployed in a service or microservice along with an OS-level virtualization package.

18. One or more processors comprising:
processing circuitry to generate one or more mesh data structures to replace one or more portions of one or more instanced mesh tiles representative of a surface in a virtual environment, the one or more mesh data structures including one or more polygons having one or more sizes based at least on one or more levels of detail associated with the one or more instanced mesh tiles.

19. The one or more processors of claim 18, the processing circuitry further to render the surface in the virtual environment using a combination of the one or more mesh data structures and one or more second portions of the one or more instanced mesh tiles.

20. The one or more processors of claim 18, wherein the one or more processors are comprised in at least one of:
a control system for an autonomous or semi-autonomous machine;
a perception system for an autonomous or semi-autonomous machine;
a system for performing one or more simulation operations;
a system for performing one or more digital twin operations;
a system for performing light transport simulation;
a system for performing collaborative content creation for 3D assets;
a system for performing one or more deep learning operations;
a system implemented using an edge device;
a system implemented using a robot;
a system for performing one or more generative AI operations;
a system for performing operations using a large language model;
a system for performing operations using one or more vision language models (VLMs);
a system for performing operations using one or more multi-modal language models;
a system for performing one or more conversational AI operations;
a system for generating synthetic data;
a system for presenting at least one of virtual reality content, augmented reality content, or mixed reality content;
a system incorporating one or more virtual machines (VMs);
a system implemented at least partially in a data center;
a system implemented at least partially using cloud computing resources;
systems using or deploying one or more inference microservices; or
systems that incorporate one or more machine learning models deployed in a service or microservice along with an OS-level virtualization package.
